(19) United States
(12) Patent Application Publication
(10) Pub. No.: US 2026/0211324 A1
(43) Pub. Date: Jul. 23, 2026

(54) RADIATION-SENSITIVE COMPOSITION, AND METHOD FOR FORMING PATTERN

(71) Applicant: JSR CORPORATION, Tokyo (JP)

(72) Inventors: Ryuichi NEMOTO, Tokyo (JP); Kensuke MIYAO, Tokyo (JP); Satoshi OKAZAKI, Tokyo (JP); Hajime INAMI, Tokyo (JP); Fuyuki EGAWA, Tokyo (JP)

(73) Assignee: JSR CORPORATION, Tokyo (JP)

(21) Appl. No.: 19/569,143

(22) Filed: Mar. 17, 2026

Related U.S. Application Data
(63) Continuation-in-part of application No. PCT/JP2024/032896, filed on Sep. 13, 2024.

(30) Foreign Application Priority Data
Sep. 26, 2023 (JP) 2023-162939

(51) Int. Cl. G03F 7/004; G03F 7/038; G03F 7/039; G03F 7/20

(52) U.S. Cl. CPC G03F 7/0045; G03F 7/038; G03F 7/039; G03F 7/2004

(57) ABSTRACT

A radiation-sensitive composition includes: a first onium salt compound represented by formula (1); a second onium salt compound represented by formula (2); a polymer including an acid-dissociable group. A is a (1+n)-valent organic group having 1 to 40 carbon atoms; R^{f1} and R^{f2} are each independently a hydrogen atom, a monovalent organic group having 1 to 20 carbon atoms, a fluorine atom, or a monovalent fluorinated hydrocarbon group; provided that at least one of R^{f1} and R^{f2} is a fluorine atom or a monovalent fluorinated hydrocarbon group; and R¹ and R² are each independently a hydrogen atom, a fluorine atom or a monovalent organic group having 1 to 20 carbon atoms. R⁴ is a monovalent organic group having 1 to 40 carbon atoms in which neither a fluorine atom nor a fluorinated hydrocarbon group is bonded to an atom adjacent to a sulfur atom in SO₃⁻.

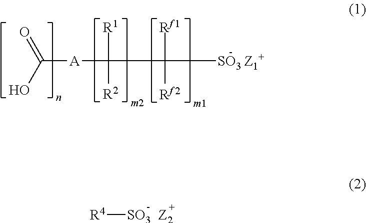

### CROSS-REFERENCE TO RELATED APPLICATIONS

The present application is a continuation-in-part application of International Patent Application No. PCT/JP2024/032896 filed Sep. 13, 2024, which claims priority to Japanese Patent Application No. 2023-162939 filed Sep. 26, 2023. The contents of these applications are incorporated herein by reference in their entirety.

### BACKGROUND OF THE DISCLOSURE

### Technical Field

The present disclosure relates to a radiation-sensitive composition, and a method for forming a pattern.

### Background Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a polymer into a developer such as an alkaline or organic solvent between an exposed part and a non-exposed part.

In the photolithography technique, pattern miniaturization is promoted by using short-wavelength radiation such as ArF excimer laser, or by combining such radiation with an immersion exposure method (liquid immersion lithography). As a next-generation technology, lithography using shorter wavelength radiation such as electron beams, X-rays and EUV (extreme ultraviolet rays) is also being studied.

On a photoacid generator, which is a main component of a resist composition, an acid generator in which a specific functional group is introduced into an anion has been studied from the viewpoint of pattern uniformity (see JP-A-2021-005100).

### SUMMARY

According to an aspect of the present disclosure, a radiation-sensitive composition includes: a first onium salt compound represented by formula (1); a second onium salt compound represented by formula (2); a polymer including a structural unit which includes an acid-dissociable group; and a solvent.

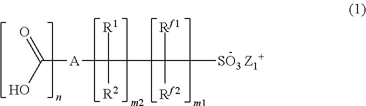

In the formula (1), A is a (1+n)-valent organic group having 1 to 40 carbon atoms; R^{f1} and R^{f2} are each independently a hydrogen atom, a monovalent organic group having 1 to 20 carbon atoms, a fluorine atom, or a monovalent fluorinated hydrocarbon group; when there is a plurality of R^{f1}s and R^{f2}s, the plurality of R^{f1}s and R^{f2}s are the same or different from each other, provided that at least one of R^{f1} and R^{f2} is a fluorine atom or a monovalent fluorinated hydrocarbon group; R¹ and R² are each independently a hydrogen atom, a fluorine atom or a monovalent organic group having 1 to 20 carbon atoms; when there are a plurality of R¹s and R²s, the plurality of R¹s and R²s are the same or different from each other; m1 is an integer of 1 to 4; m2 is an integer of 0 to 4; n is an integer of 1 to 3; and Z₁⁺ represents a monovalent radiation-sensitive onium cation, provided that a fluorine atom number in Z₁⁺ is 8 or less.

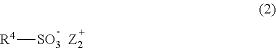

In the formula (2), R⁴ is a monovalent organic group having 1 to 40 carbon atoms in which neither a fluorine atom nor a fluorinated hydrocarbon group is bonded to an atom adjacent to a sulfur atom in SO₃⁻; and Z₂⁺ represents a monovalent organic cation.

According to another aspect of the present disclosure, a method for forming a pattern includes: applying the above-described radiation-sensitive composition directly or indirectly to a substrate to form a resist film; exposing the resist film to light; and developing the exposed resist film with a developer.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed.

Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Among such efforts for next-generation technologies, the resist composition is required to have various resist performances equal to or higher than conventional ones in terms of sensitivity, line width roughness (LWR) performance indicating variation in line width of a resist pattern, pattern rectangularity indicating the rectangularity of the sectional shape of a resist pattern, critical dimension uniformity (CDU) performance, which is an index of uniformity of line width and hole diameter, pattern circularity indicating the circularity of a hole shape, mask error enhancement factor (MEEF), exposure latitude, and the like. However, existing radiation-sensitive compositions do not provide sufficient levels of these properties.

Since the radiation-sensitive composition of the present disclosure contains a first onium salt compound as a radiation-sensitive acid generator and a second onium salt compound as a quencher (acid diffusion controlling agent) or a radiation-sensitive acid generator in combination, the radiation-sensitive composition can demonstrate sufficient levels of sensitivity, LWR performance, pattern rectangularity, CDU performance, pattern circularity, MEEF, and exposure latitude when a pattern is formed. Although not bound by any theory, the reason for this can be presumed as follows.

Since the anion of the first onium salt compound has a carboxy group, solubility in an alkaline developer is higher than that of a previously developed onium salt compound containing a polar group such as a hydroxyl group, a lactone structure, and a sultone structure. In addition, the diffusion length of the generated acid is shortened by the interaction between the carboxy group and other components such as a polymer in the radiation-sensitive composition. By these actions, it is possible to suppress the occurrence of roughness such as variations in pattern shape and irregularities.

The second onium salt compound exhibits moderate acid trapping performance, and can efficiently trap the acid generated from the first onium salt compound in an unexposed portion. Further, when the second onium salt compound functions as a radiation-sensitive acid generator, the second onium salt compound exhibits moderately weak acidity, so that only an acid-dissociable group having low activation energy of the base polymer can be selectively dissociated. Furthermore, since both the second onium salt compound and the first onium salt compound have a sulfonate anion, their compatibility is improved, and in particular, aggregation of the first onium salt compound can be eliminated to improve dispersibility.

By using the properties of each of the first onium salt compound and the second onium salt compound in combination, it is possible to impart an acid diffusion length, homogeneity, and acidity optimal for various pattern shapes and sizes. As a result, it is presumed that given resist properties can be exhibited. The organic group refers to a group containing at least one carbon atom.

In the method for forming a pattern of the present disclosure, a high-quality resist pattern can be efficiently formed because of the use of the radiation-sensitive composition that can demonstrate sufficient levels of sensitivity, LWR performance, pattern rectangularity, CDU performance, pattern circularity, MEEF, and exposure latitude when a pattern is formed.

Hereinbelow, embodiments of the present disclosure will be described in detail, but the present disclosure is not limited to these embodiments. Combinations of suitable embodiments are also preferable.

### <Radiation-Sensitive Composition>

The radiation-sensitive composition (hereinafter also simply referred to as “composition”) according to the present embodiment includes a first onium salt compound, a second onium salt compound, a polymer containing a structural unit having an acid-dissociable group (hereinafter, also referred to as a “base polymer”), and a solvent. The composition may contain other optional components as long as the effects of the present disclosure are not impaired.

### (First Onium Salt Compound)

The first onium salt compound is represented by the formula (1), and is a component that generates an acid upon irradiation with radiation. The acid generated by exposure to light has a function of dissociating the acid-dissociable group of the base polymer to generate a carboxy group or the like. The composition may contain one type or two or more types of the first onium salt compound.

Examples of the (1+n)-valent organic group having 1 to 40 carbon atoms represented by A include a group obtained by removing n hydrogen atoms from a monovalent organic group having 1 to 40 carbon atoms. The monovalent organic group having 1 to 40 carbon atoms is not particularly limited, and may have a chain structure, a cyclic structure, or a combination thereof. Examples of the chain structure include a chain hydrocarbon group that may be saturated or unsaturated and may be linear or branched. Examples of the cyclic structure include a cyclic hydrocarbon group that may be alicyclic, aromatic, or heterocyclic. When the cyclic structure includes a plurality of rings, the plurality of rings may form any of a fused ring, a spiro ring, and a ring assembly (a structure in which adjacent rings are bonded by a single bond). The cyclic structure is preferably an alicyclic structure having 3 to 20 carbon atoms, an aromatic ring structure having 6 to 20 carbon atoms, or a combination thereof. Among these examples, the monovalent organic group is preferably a substituted or unsubstituted monovalent chain hydrocarbon group having 1 to 20 carbon atoms, a substituted or unsubstituted monovalent alicyclic hydrocarbon group having 3 to 20 carbon atoms, a substituted or unsubstituted monovalent aromatic hydrocarbon group having 6 to 20 carbon atoms, or a combination thereof. Other examples of the organic group include a group obtained by substituting, with a substituent, some or all of the hydrogen atoms contained in a group having a chain structure or a group having a cyclic structure, and such a group but further containing a divalent heteroatom-containing linking group, between carbon atoms or at the terminal of the group, CO, CS, O, S, SO₂, NR′, or a combination of two or more thereof. R′ is a hydrogen atom or a monovalent hydrocarbon group having 1 to 10 carbon atoms.

Examples of the substituent that substitutes some or all of the hydrogen atoms of the organic group include a halogen atom such as a fluorine atom, a chlorine atom, a bromine atom, or an iodine atom; a hydroxy group; a cyano group; a nitro group; an alkyl group; an alkoxy group; an alkoxycarbonyl group; an alkoxycarbonyloxy group; an acyl group; an acyloxy group, an aryloxy group, an aryloxyalkyl group, or groups obtained by substituting a hydrogen atom on these groups with a halogen atom; and an oxo group (═O).

Examples of the monovalent chain hydrocarbon group having 1 to 20 carbon atoms may include a linear or branched saturated chain hydrocarbon group having 1 to 20 carbon atoms or a linear or branched unsaturated chain hydrocarbon group having 1 to 20 carbon atoms.

Examples of alicyclic structures include a monovalent alicyclic hydrocarbon group having 3 to 20 carbon atoms. Examples of the monovalent alicyclic hydrocarbon group having 3 to 20 carbon atoms include monovalent monocyclic or polycyclic saturated hydrocarbon groups and monocyclic or polycyclic unsaturated hydrocarbon groups. As the monocyclic saturated hydrocarbon groups, a cyclopentyl group, a cyclohexyl group, a cycloheptyl group, and a cyclooctyl group are preferable. As the polycyclic cycloalkyl group, bridged alicyclic hydrocarbon groups such as a norbornyl group, an adamantyl group, a tricyclodecyl group, and a tetracyclododecyl group are preferable. Examples of the monocyclic unsaturated hydrocarbon group include monocyclic cycloalkenyl groups such as a cyclopropenyl group, a cyclobutenyl group, a cyclopentenyl group, and a cyclohexenyl group. Examples of the polycyclic unsaturated hydrocarbon group include polycyclic cycloalkenyl groups such as a norbornenyl group, a tricyclodecenyl group, and a tetracyclododecenyl group.

Examples of the monovalent aromatic hydrocarbon group having 6 to 20 carbon atoms include: aryl groups such as a phenyl group, a tolyl group, a xylyl group, a naphthyl group, and an anthryl group; and aralkyl groups such as a benzyl group, a phenethyl group, and a naphthylmethyl group.

Examples of the heterocyclic hydrocarbon group include a group obtained by removing one hydrogen atom from an aromatic heterocyclic structure and a group obtained by removing one hydrogen atom from an aliphatic heterocyclic structure. A 5-membered aromatic structure having aromaticity due to introduction of a hetero atom is also included in the heterocyclic structure. Examples of the hetero atom include an oxygen atom, a nitrogen atom, and a sulfur atom.

Examples of the aromatic heterocyclic structure include:
oxygen atom-containing aromatic heterocyclic structures such as furan, pyran, benzofuran, and benzopyran;
nitrogen atom-containing aromatic heterocyclic structures such as pyrrole, imidazole, pyridine, pyrimidine, pyrazine, indole, quinoline, isoquinoline, acridine, phenazine, and carbazole;
sulfur atom-containing aromatic heterocyclic structures such as thiophene; and
aromatic heterocyclic structures containing a plurality of hetero atoms such as thiazole, benzothiazole, thiazine, and oxazine.

Examples of the aliphatic heterocyclic structure include:
oxygen atom-containing aliphatic heterocyclic structures such as oxirane, tetrahydrofuran, tetrahydropyran, dioxolane, and dioxane;
nitrogen atom-containing aliphatic heterocyclic structures such as aziridine, pyrrolidine, piperidine, and piperazine;
sulfur atom-containing aliphatic heterocyclic structures such as thietane, thiolane, and thiane; and
aliphatic heterocyclic structures containing a plurality of hetero atoms such as morpholine, 1,2-oxathiolane, and 1,3-oxathiolane.

Examples of the cyclic structure also include a lactone structure, a cyclic carbonate structure, a sultone structure, and a structure containing a cyclic acetal. Examples of such structures include structures represented by formulas (H-1) to (H-11) below.

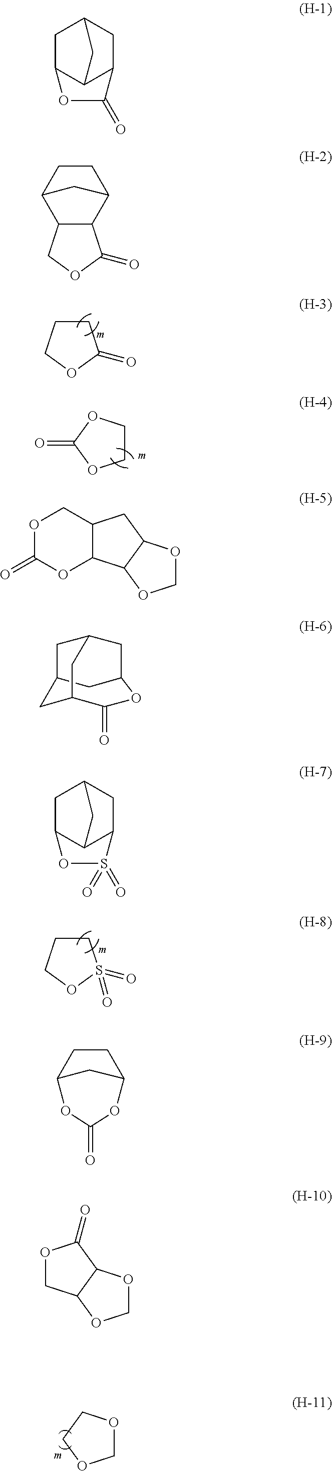

In the formulas, m's are each an integer of 1 to 3.

In the formula (1), A preferably includes at least one structure selected from the group consisting of a first cyclic structure, an ester bond, and an ether bond. In addition, the first cyclic structure is preferably at least one selected from the group consisting of an alicyclic hydrocarbon structure, an aromatic hydrocarbon structure, a lactone structure, a cyclic acetal structure, and a cyclic ether structure. The alicyclic hydrocarbon structure is preferably an alicyclic polycyclic structure, and more preferably an adamantane structure or a norbornane structure. When A has these structures, the diffusion length of the acid generated by exposure can be appropriately controlled, and the composition can exhibit various resist properties at a high level.

As the monovalent organic groups having 1 to 20 carbon atoms represented by R^{f1} and R^{f2}, groups corresponding to 1 to 20 carbon atoms among the monovalent organic groups having 1 to 40 carbon atoms shown in A in the formula (1) can be suitably employed.

Examples of the monovalent fluorinated hydrocarbon groups represented by R^{f1} and R^{f2} include a monovalent fluorinated chain hydrocarbon group having 1 to 20 carbon atoms and a monovalent fluorinated alicyclic hydrocarbon group having 3 to 20 carbon atoms.

Examples of the monovalent fluorinated chain hydrocarbon group having 1 to 20 carbon atoms include:
fluorinated alkyl groups such as a trifluoromethyl group, a difluoromethyl group, a 2,2,2-trifluoroethyl group, a pentafluoroethyl group, a 2,2,3,3,3-pentafluoropropyl group, a 1,1,1,3,3,3-hexafluoropropyl group, a heptafluoro-n-propyl group, a heptafluoro-i-propyl group, a nonafluoro-n-butyl group, a nonafluoro-i-butyl group, a nonafluoro-t-butyl group, a 2,2,3,3,4,4,5,5-octafluoro-n-pentyl group, a tridecafluoro-n-hexyl group, and a 5,5,5-trifluoro-1,1-diethylpentyl group;
fluorinated alkenyl groups such as a trifluoroethenyl group and a pentafluoropropenyl group; and
fluorinated alkynyl groups such as a fluoroethynyl group and a trifluoropropynyl group.

Examples of the monovalent fluorinated alicyclic hydrocarbon group having 3 to 20 carbon atoms include:
fluorinated cycloalkyl groups such as a fluorocyclopentyl group, a difluorocyclopentyl group, a nonafluorocyclopentyl group, a fluorocyclohexyl group, a difluorocyclohexyl group, an undecafluorocyclohexylmethyl group, a fluoronorbornyl group, a fluoroadamantyl group, a fluorobornyl group, a fluoroisobornyl group, and a fluorotricyclodecyl group; and
fluorinated cycloalkenyl groups such as a fluorocyclopentenyl group and a nonafluorocyclohexenyl group.

As the fluorinated hydrocarbon group, a monovalent fluorinated chain hydrocarbon group having 1 to 8 carbon atoms is preferable, and a monovalent fluorinated linear hydrocarbon group having 1 to 5 carbon atoms is more preferable.

At least one of R^{f1} and R^{f2} is a fluorine atom or a monovalent fluorinated hydrocarbon group. R^{f1} and R^{f2} are preferably each independently a fluorine atom or a trifluoromethyl group. R^{f1} and R^{f2} on the carbon atom bonded to —SO₃⁻ in the formula (1) are preferably fluorine atoms.

As the monovalent organic groups having 1 to 20 carbon atoms represented by R¹ and R², groups corresponding to 1 to 20 carbon atoms among the monovalent organic groups having 1 to 40 carbon atoms shown in the A can be suitably employed. R¹ and R² may have a carboxy group in addition to a substituent that can be possessed by the A.

R¹ and R² are preferably hydrogen atoms.

m1 is preferably an integer of 1 to 3, and more preferably 1 or 2.

m2 is preferably an integer of 0 to 3, and more preferably an integer of 0 to 2.

n is more preferably 1 or 2, and more preferably 1.

Furthermore, from the viewpoint of appropriately adjusting the acid diffusion length, the first onium salt compound is preferably a compound represented by any one of formulas (1-1) to (1-3).

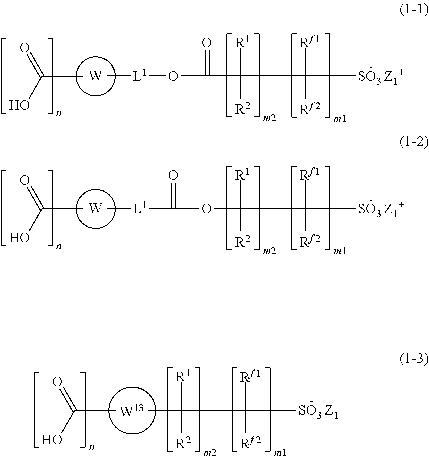

wherein in the formulas (1-1) to (1-3), W's are each independently a substituted or unsubstituted (1+n)-valent cyclic structure, W¹³ is a substituted or unsubstituted (1+n)-valent cyclic structure including a cyclic acetal structure, L¹'s are each independently a single bond or a divalent linking group, and R^{f1}, R^{f2}, R¹, R², m1, m2, n, and Z₁⁺ have the same meaning as in the formula (1).

In the formulas (1-1) to (1-3), as the cyclic structure in W, the first cyclic structure shown in A in the formula (1) can be suitably employed. As the cyclic structure in W¹³, a group in which a cyclic acetal structure is incorporated in A in the formula (1) can be suitably employed. As the substituent that can be possessed by the cyclic structure in W and W¹³, a substituent that can be possessed by the organic group of A in the formula (1) can be suitably employed.

Examples of the divalent linking group represented by L¹ include a divalent chain hydrocarbon group having 1 to 10 carbon atoms, a divalent alicyclic hydrocarbon group having 4 to 12 carbon atoms, at least one group among —CO—, —O—, —NH—, and —S—, and a group composed of one or more of the divalent hydrocarbon groups and at least one group among —CO—, —O—, —NH—, and —S—.

As the divalent chain hydrocarbon group having 1 to 10 carbon atoms in L¹, a group obtained by removing one hydrogen atom from a group corresponding to 1 to 10 carbon atoms of the monovalent chain hydrocarbon group having 1 to 20 carbon atoms shown in A in the formula (1) can be suitably employed.

As the divalent alicyclic hydrocarbon group having 4 to 12 carbon atoms in L¹, a group obtained by removing one hydrogen atom from a group corresponding to 4 to 12 carbon atoms of the monovalent alicyclic hydrocarbon group having 3 to 20 carbon atoms shown in A in the formula (1) can be suitably employed.

Specific examples of the anion moiety of the first onium salt compound include, but are not limited to, the structures represented by formulas (1-1-1) to (1-1-84) below.

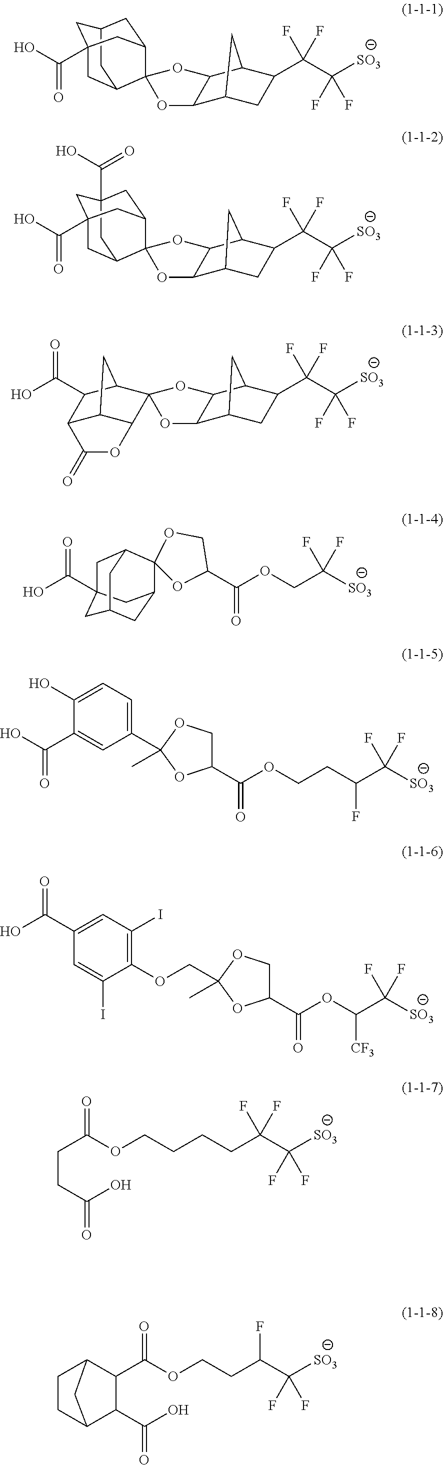

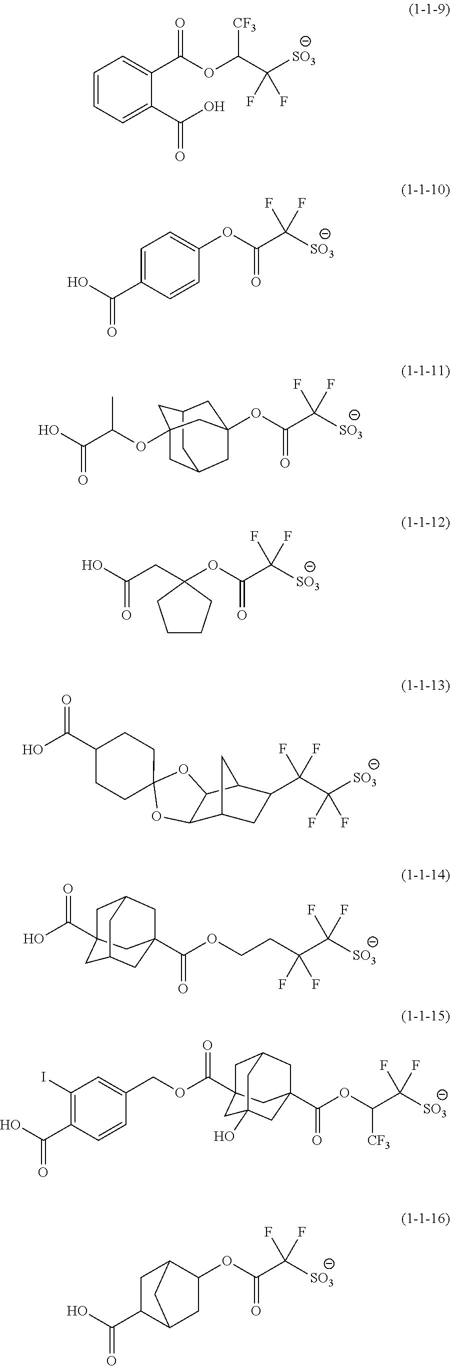

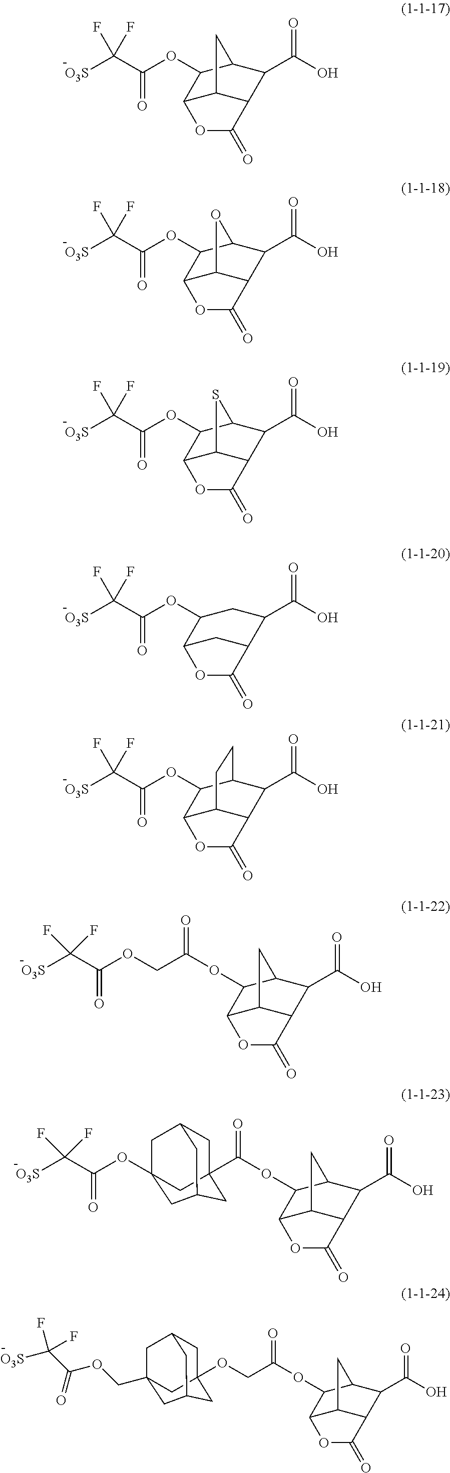

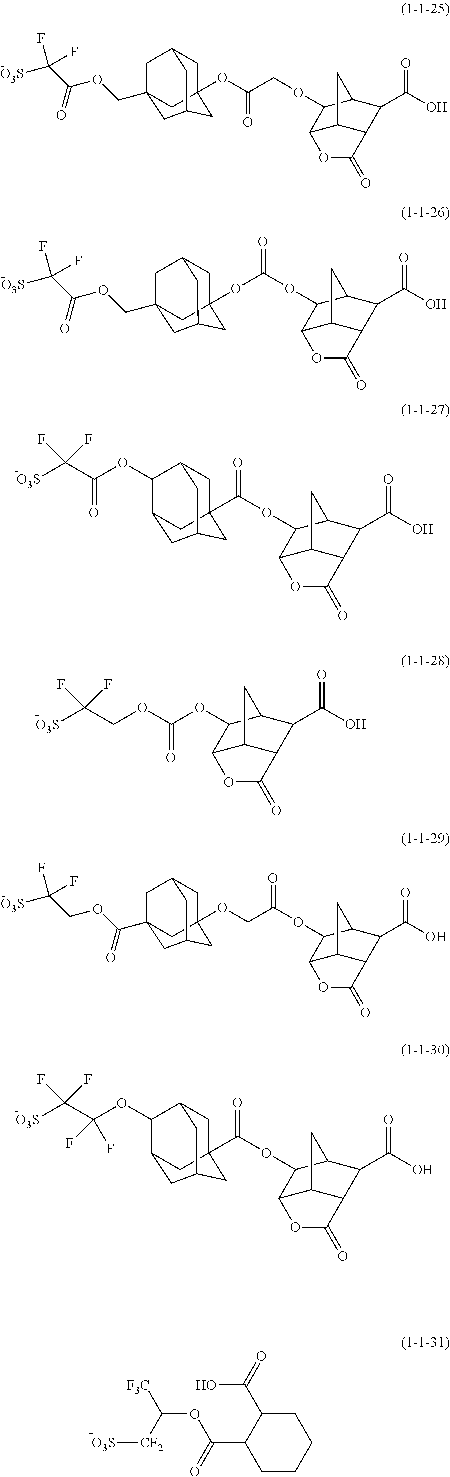

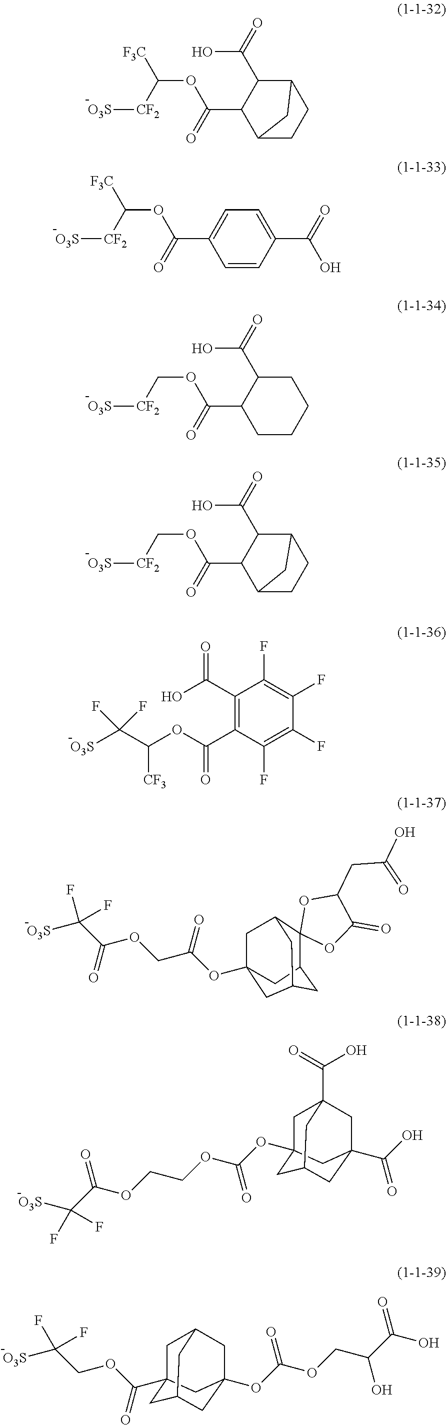

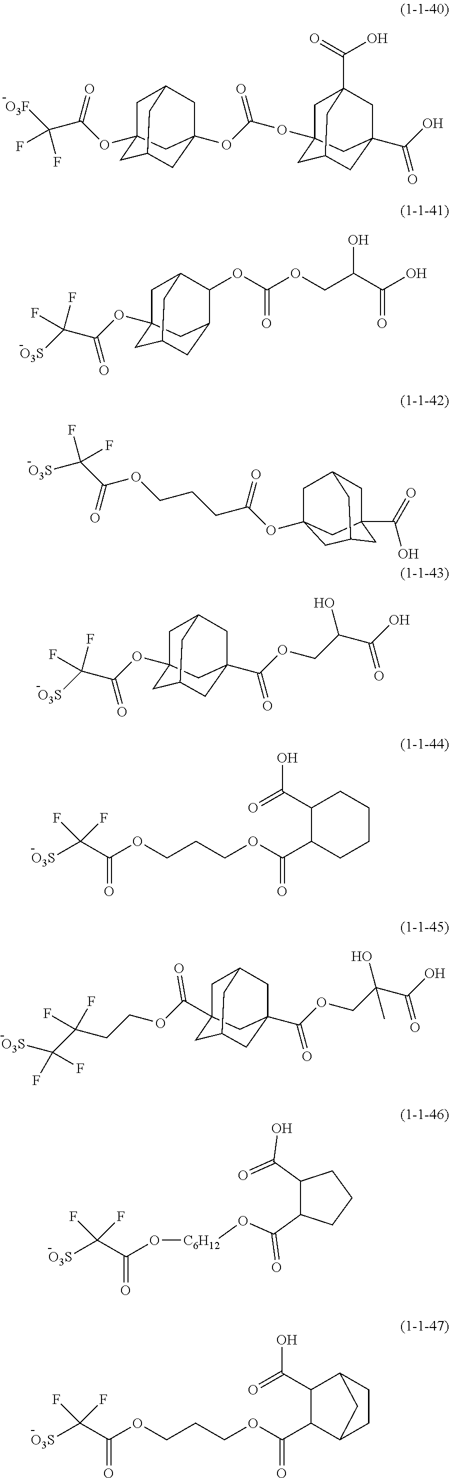

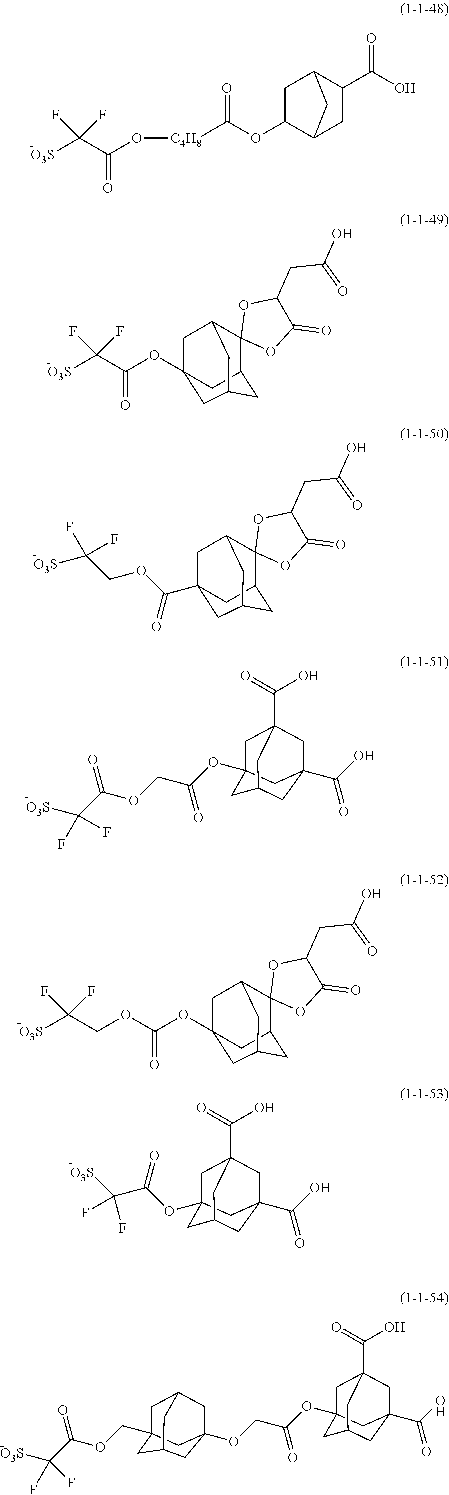

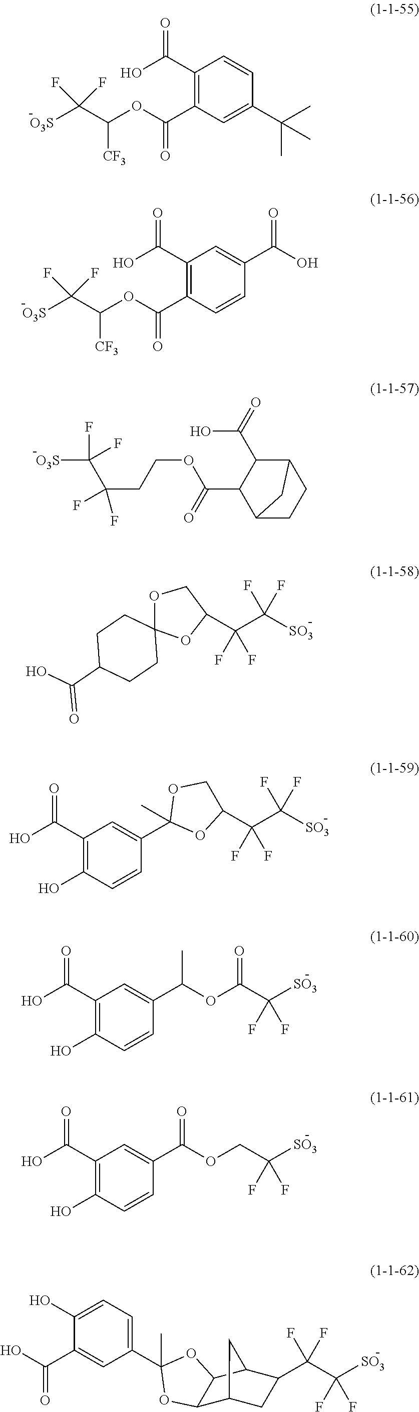

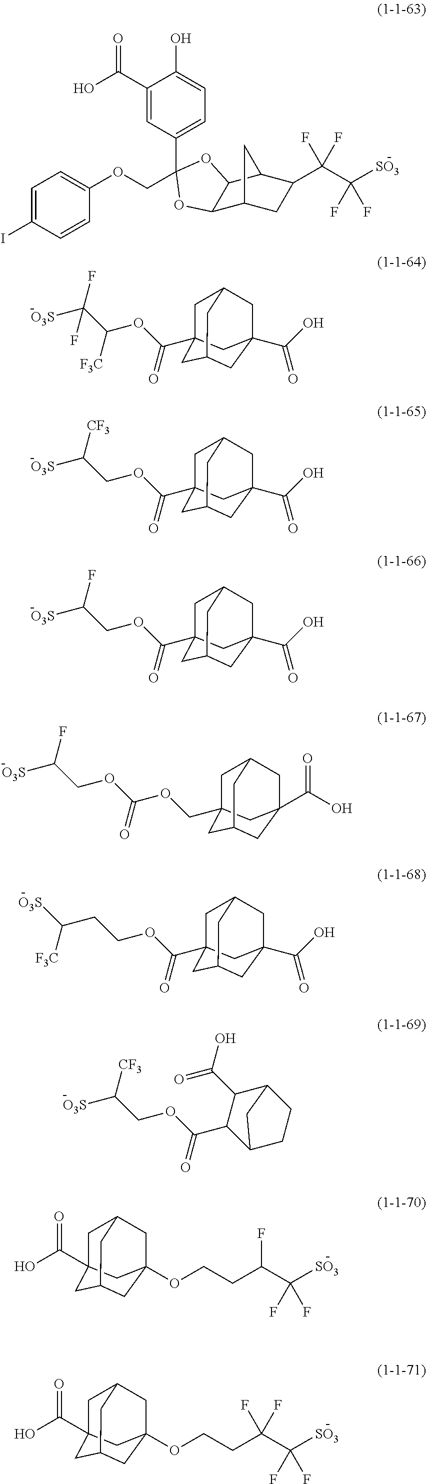

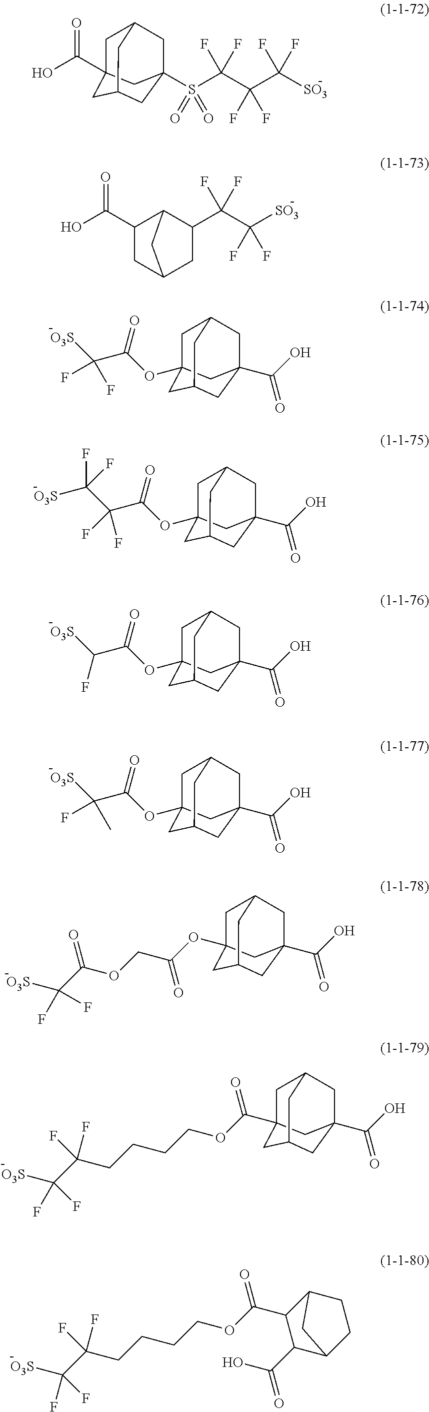

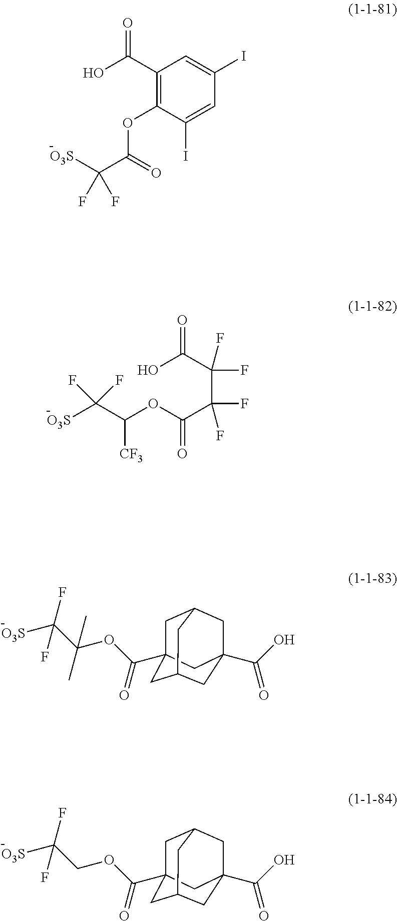

An example of the monovalent radiation-sensitive onium cation represented by Z₁⁺ of the formula (1) is a radioactive ray-degradable onium cation containing an element such as S, I, O, N, P, Cl, Br, F, As, Se, Sn, Sb, Te, or Bi. Examples of such a radioactive ray-degradable onium cation include a sulfonium cation, a tetrahydrothiophenium cation, an iodonium cation, a phosphonium cation, a diazonium cation, and a pyridinium cation. Among them, a sulfonium cation or an iodonium cation is preferred. The number of fluorine atoms in Z₁⁺ is 8 or less from the viewpoint of developer solubility, dispersibility, permeability, and acid generation efficiency. When the number of fluorine atoms is 9 or more, compatibility with the base polymer is reduced and aggregation is likely to occur, which may cause a decrease in solubility and an increase in roughness. The sulfonium cation or the iodonium cation is preferably represented by any of formulas (X-1) to (X-6) below.

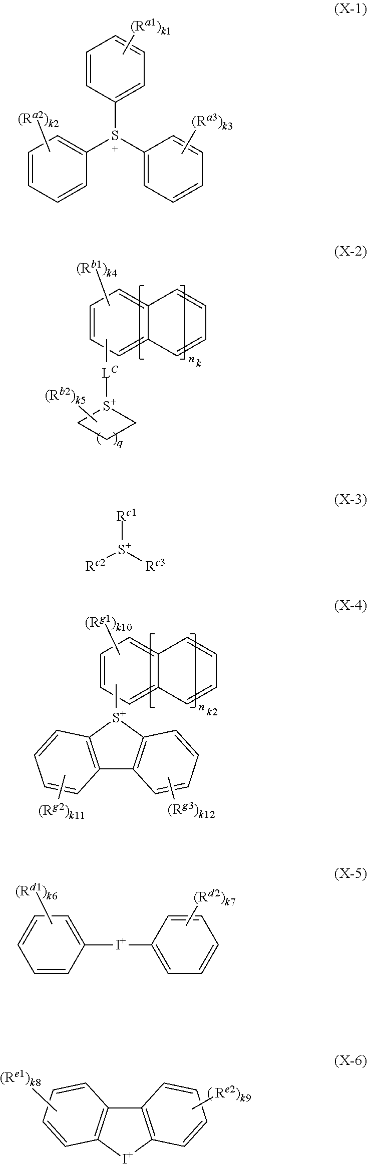

In the formula (X-1), R^{a1}, R^{a2} and R^{a3} are each independently a substituted or unsubstituted, straight or branched chain alkyl group, alkoxy group, alkoxycarbonyloxy group, or (cyclo)alkoxycarbonylalkoxy group having 1 to 12 carbon atoms; a substituted or unsubstituted, monocyclic or polycyclic cycloalkyl group having 3 to 12 carbon atoms; a substituted or unsubstituted aromatic hydrocarbon group having 6 to 12 carbon atoms; a hydroxy group, a halogen atom, —OSO₂—R^{P}, —SO₂—R^{Q}, —S—R^{T}, —O—, —CO— or a combination thereof; or a ring structure obtained by combining two or more of these groups. The ring structure may contain heteroatoms such as O and S between the carbon-carbon bonds forming the skeleton. R^{P}, R^{Q} and R^{T} are each independently a substituted or unsubstituted, straight or branched chain alkyl group having 1 to 12 carbon atoms; a substituted or unsubstituted alicyclic hydrocarbon group having 5 to 25 carbon atoms; or a substituted or unsubstituted aromatic hydrocarbon group having 6 to 12 carbon atoms. k1, k2 and k3 are each independently an integer of 0 to 5. When there are a plurality of R^{a1} to R^{a3} and a plurality of R^{P}, R^{Q} and R^{T}, a plurality of R^{a1} to R^{a3} and a plurality of R^{P}, R^{Q} and R^{T} may be each identical or different. In addition, from the viewpoint of developer solubility, dispersibility, permeability, and acid generation efficiency, the number of halogen atoms contained in R^{a1} to R^{a3} is preferably 8 or less. The present embodiment also includes a case where the number of halogen atoms contained in R^{a1} to R^{a3} is zero (a case where no halogen atom is contained).

In the formula (X-2), R^{b1} is a substituted or unsubstituted, straight chain or branched alkyl group or alkoxy group, or an alkoxyalkoxy group having 1 to 20 carbon atoms; a substituted or unsubstituted acyl group having 2 to 8 carbon atoms; or a substituted or unsubstituted aromatic hydrocarbon group having 6 to 8 carbon atoms; a hydroxy group; or a halogen atom. nₖ is 0 or 1. When nₖ is 0, k4 is an integer of 0 to 4. When nₖ is 1, k4 is an integer of 0 to 7. When there are a plurality of R^{b1}, a plurality of R^{b1} may be each identical or different. A plurality of R^{b1} may represent a ring structure obtained by combining them. R^{b2} is a substituted or unsubstituted, straight chain or branched alkyl group having 1 to 7 carbon atoms; or a substituted or unsubstituted aromatic hydrocarbon group having 6 or 7 carbon atoms. L^{C} is a single bond or divalent linking group. k5 is an integer of 0 to 4. When there are a plurality of R^{b2}, a plurality of R^{b2} may be each identical or different. A plurality of R^{b2} may represent a ring structure obtained by combining them. q is an integer of 0 to 3. In the formula, the ring structure containing S⁺ may contain a heteroatom such as O or S between the carbon-carbon bonds forming the skeleton.

In the formula (X-3), R^{c1}, R^{c2} and R^{c3} are each independently a substituted or unsubstituted, straight or branched chain alkyl group having 1 to 12 carbon atoms.

In the formula (X-4), R^{g1} is a substituted or unsubstituted linear or branched alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ₂ is 0 or 1. When nₖ₂ is 0, k10 is an integer of 0 to 4, and when nₖ₂ is 1, k10 is an integer of 0 to 7. When there are two or more R^{g1}s, the two or more R^{g1}s are the same or different from each other, and may represent a cyclic structure formed by combining them together. R^{g2} and R^{g3} are each independently a substituted or unsubstituted linear or branched alkyl, alkoxy, or alkoxycarbonyloxy group having 1 to 12 carbon atoms, a substituted or unsubstituted monocyclic or polycyclic cycloalkyl group having 3 to 12 carbon atoms, a substituted or unsubstituted aromatic hydrocarbon group having 6 to 12 carbon atoms, a hydroxyl group, a halogen atom, or a ring structure formed by combining two or more of these groups together. K11 and k12 are each independently an integer of 0 to 4. When there are two or more R^{g2}s and two or more R^{g3}s, the two or more R^{g2}s may be the same or different from each other, and the two or more R^{g3}s may be the same or different from each other.

In the formula (X-5), R^{d1} and R^{d2} are each independently a substituted or unsubstituted, straight or branched chain alkyl group, alkoxy group or alkoxycarbonyl group having 1 to 12 carbon atoms; a substituted or unsubstituted aromatic hydrocarbon group having 6 to 12 carbon atoms; a halogen atom; a halogenated alkyl group having 1 to 4 carbon atoms; a nitro group; or a ring structure obtained by combining two or more of these groups. k6 and k7 are each independently an integer of 0 to 5. When there are a plurality of R^{d1} and a plurality of R^{d2}, a plurality of R^{d1} and a plurality of R^{d2} may be each identical or different.

In the formula (X-6), R^{e1} and R^{e2} are each independently a halogen atom; a substituted or unsubstituted straight or branched chain alkyl group having 1 to 12 carbon atoms; or a substituted or unsubstituted aromatic hydrocarbon group having 6 to 12 carbon atoms. k8 and k9 are each independently an integer of 0 to 4.

Specific examples of the radiation-sensitive onium cation include, but not limited thereto, the structures represented by the formulas (1-2-1) to (1-2-54).

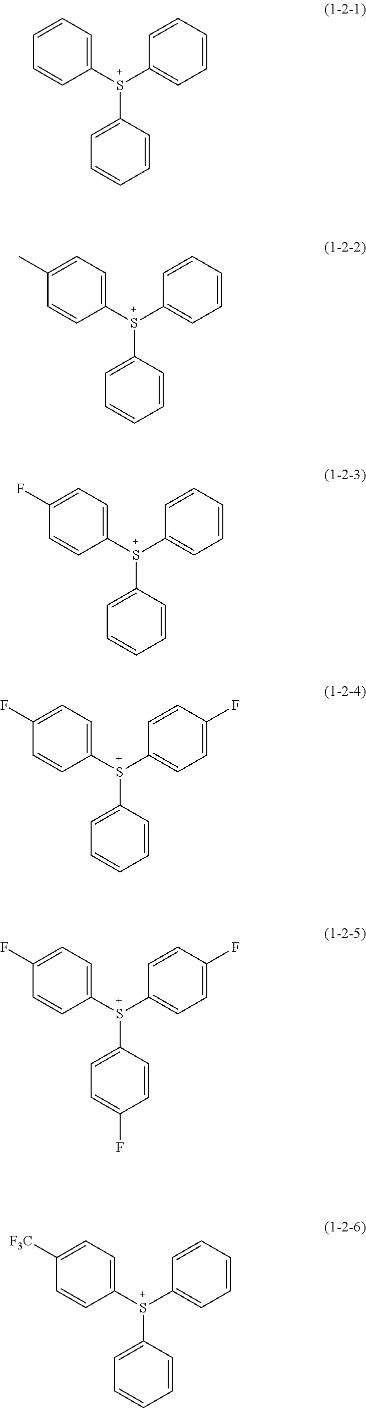

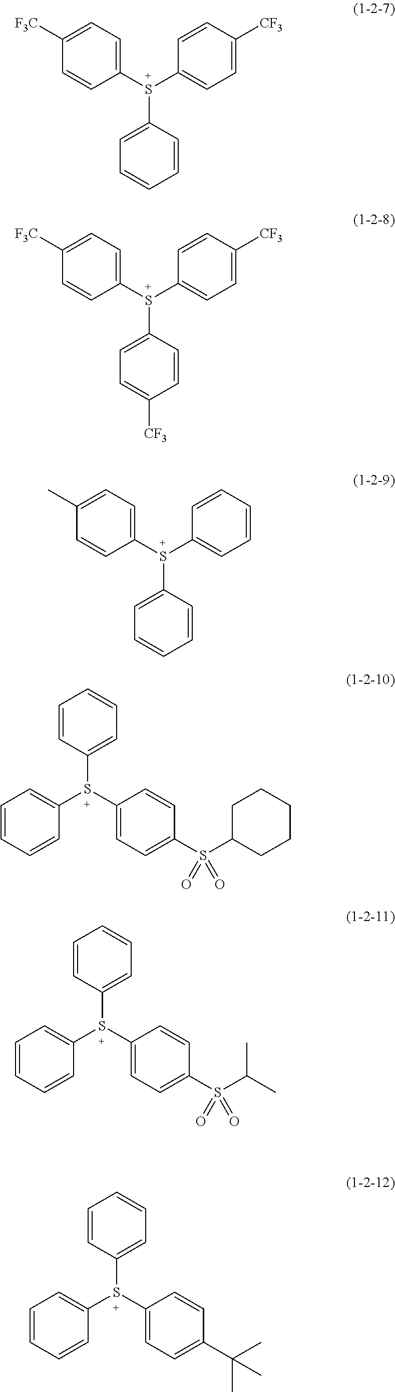

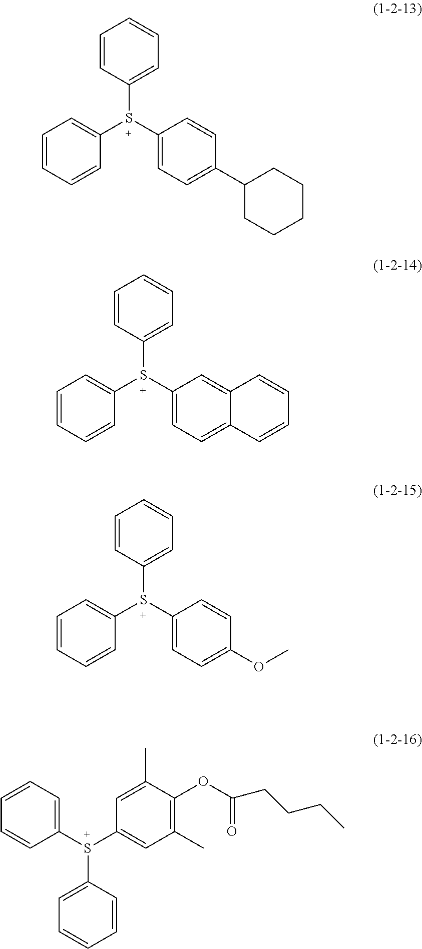

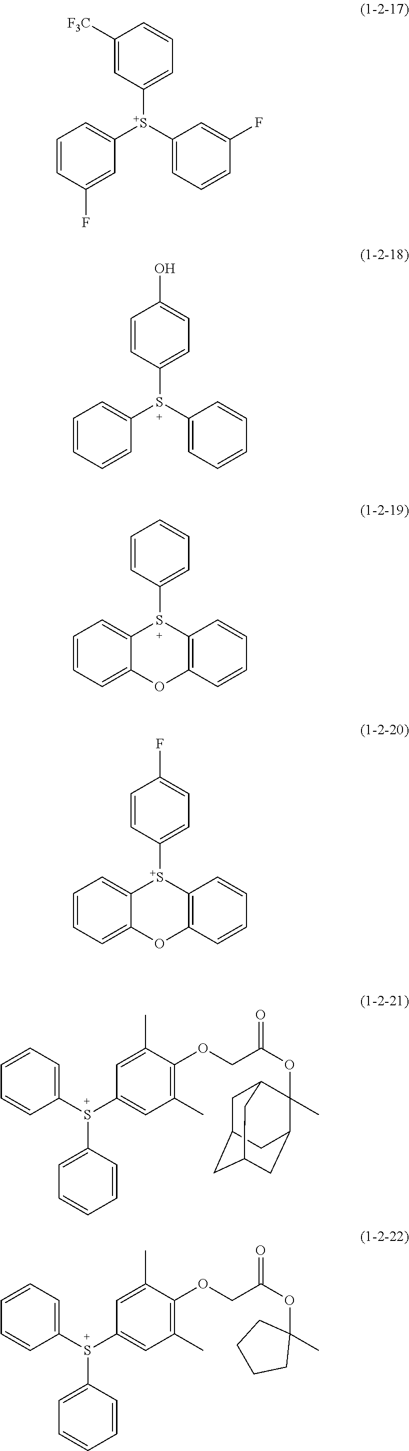

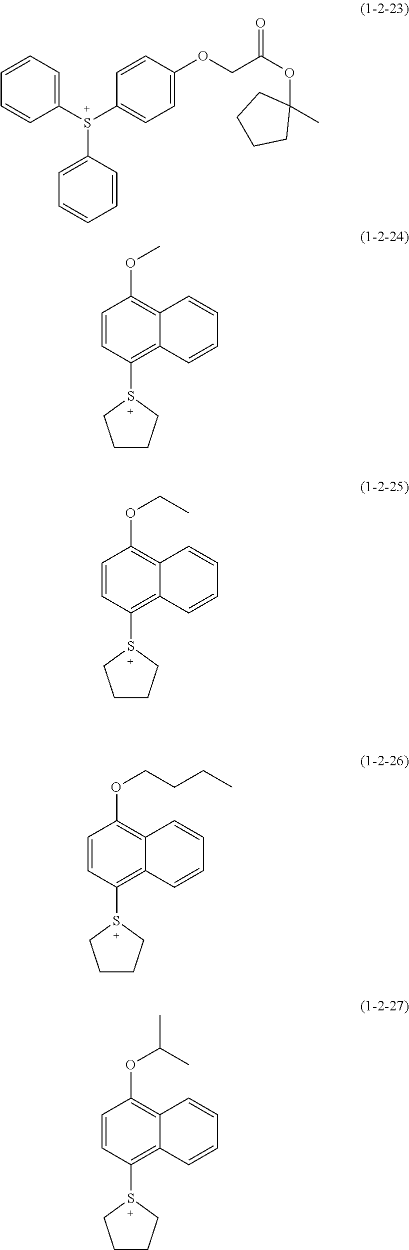

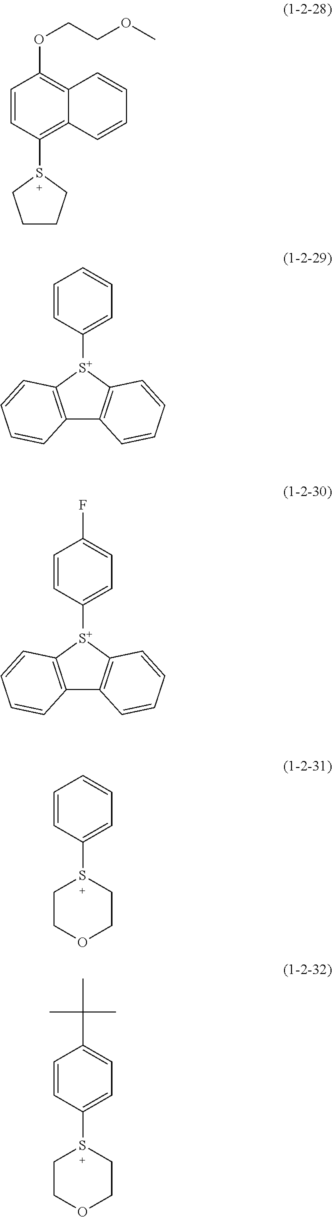

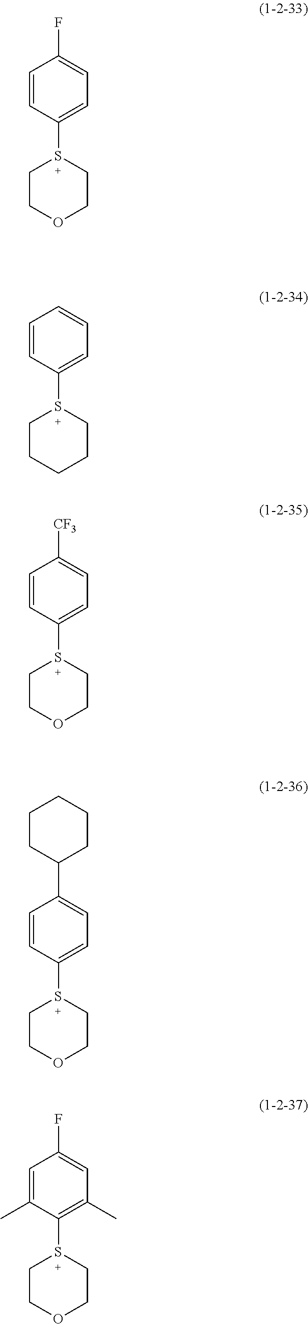

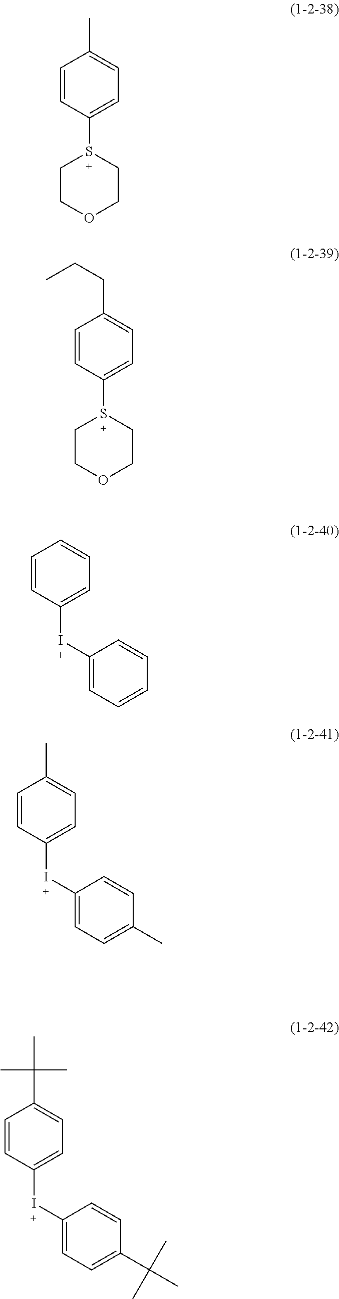

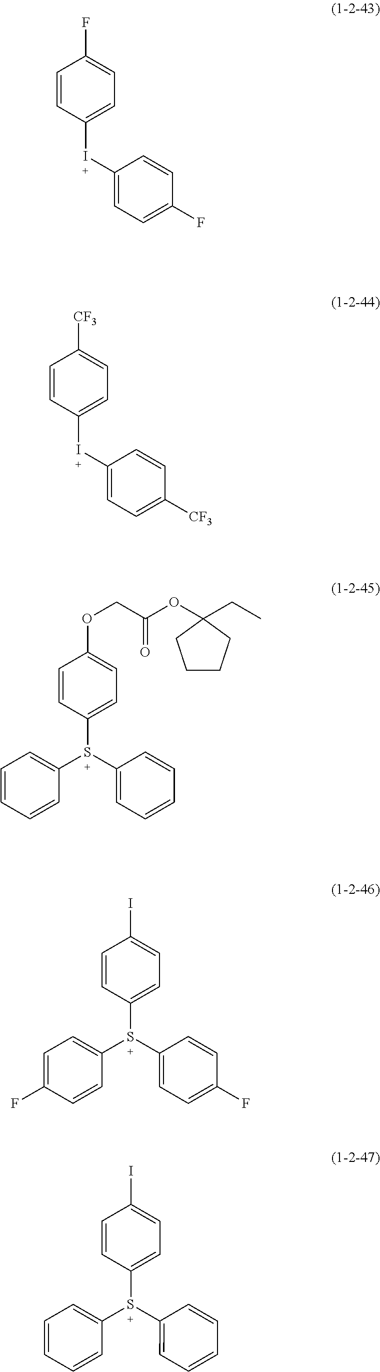

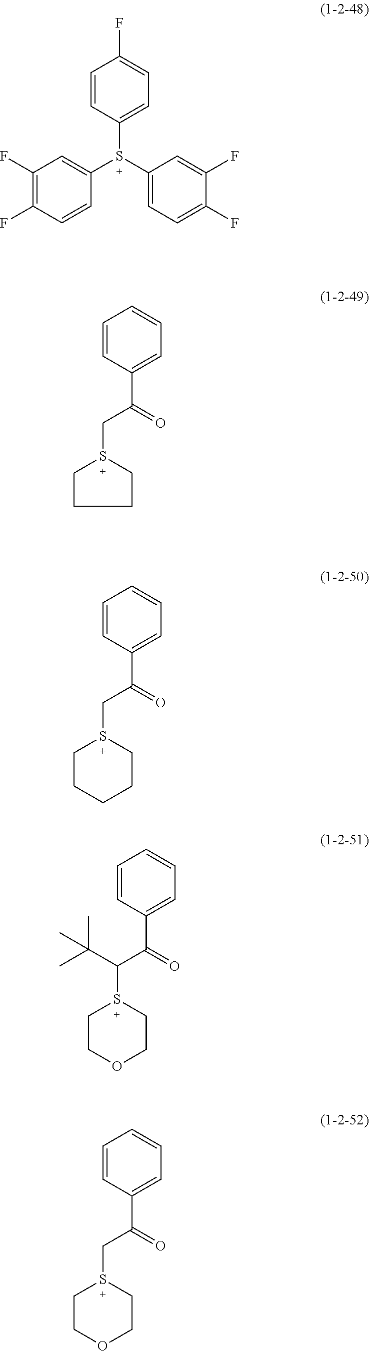

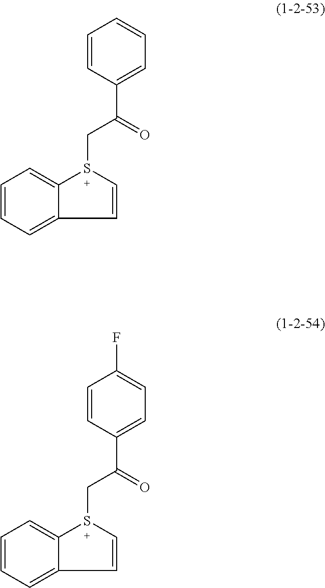

The first onium salt compound is obtained by appropriately combining the aforementioned anion moieties and the aforementioned radiation-sensitive onium cations. Specific examples thereof include, but are not particularly limited to, structures represented by formulae (1-1) to (1-34).

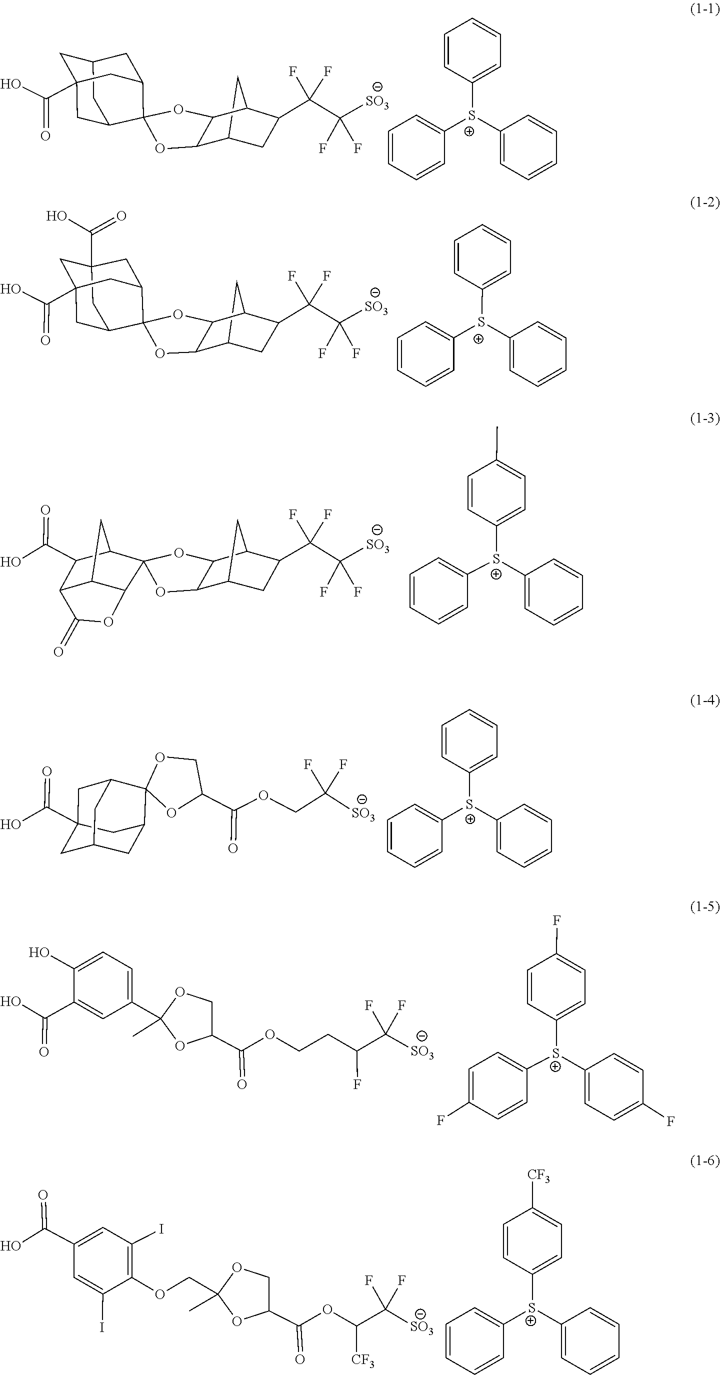

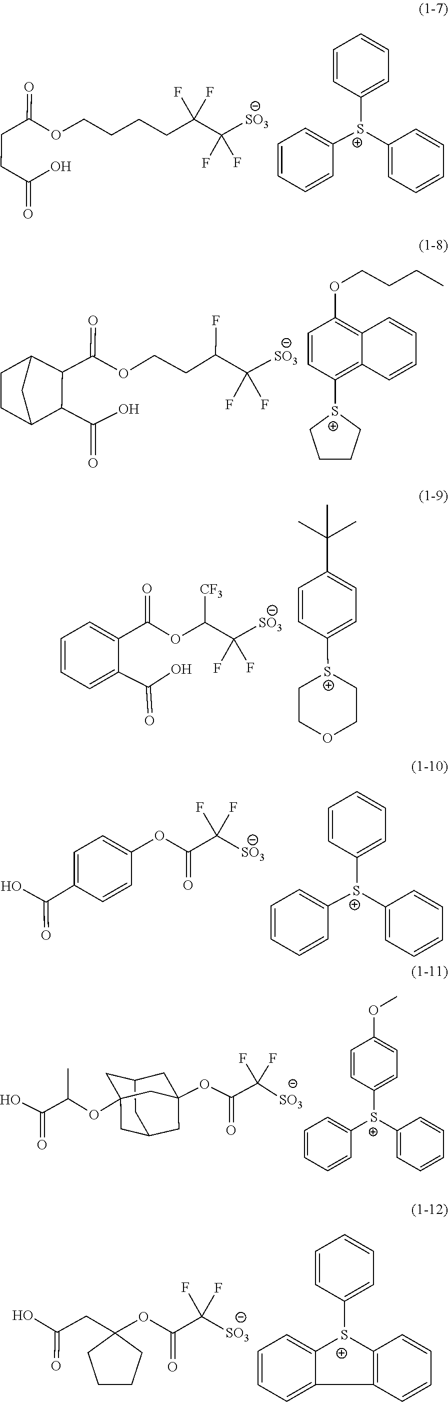

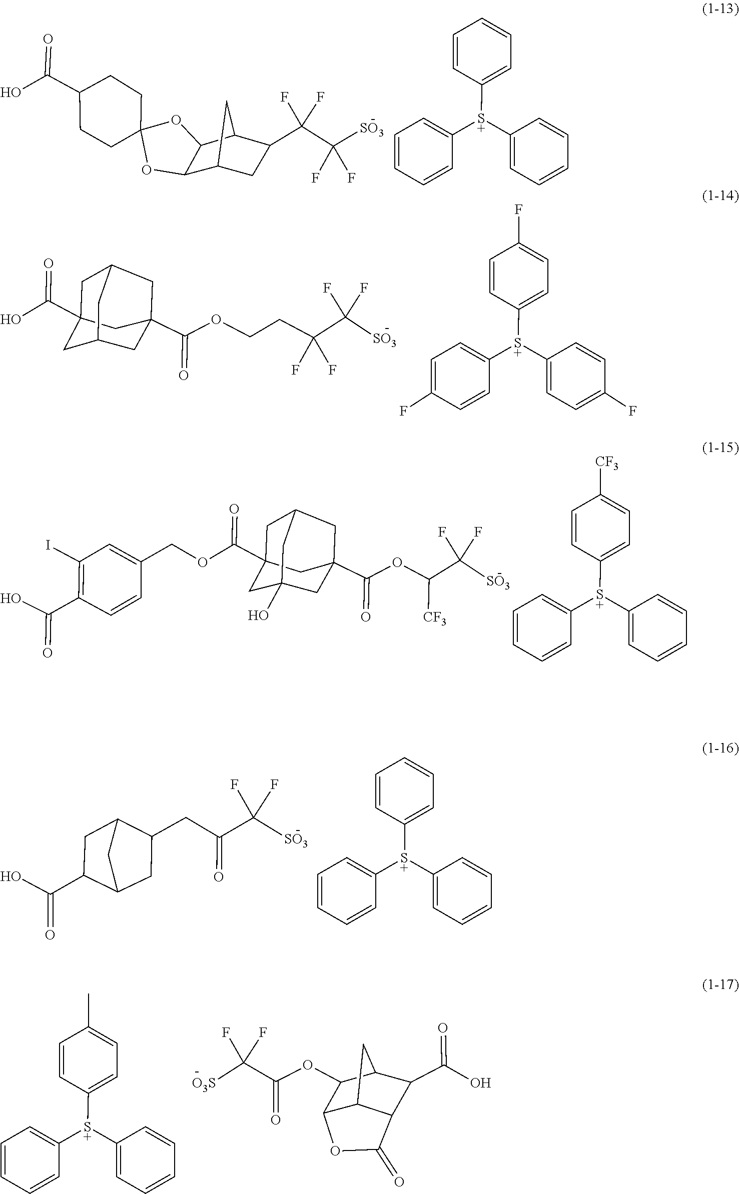

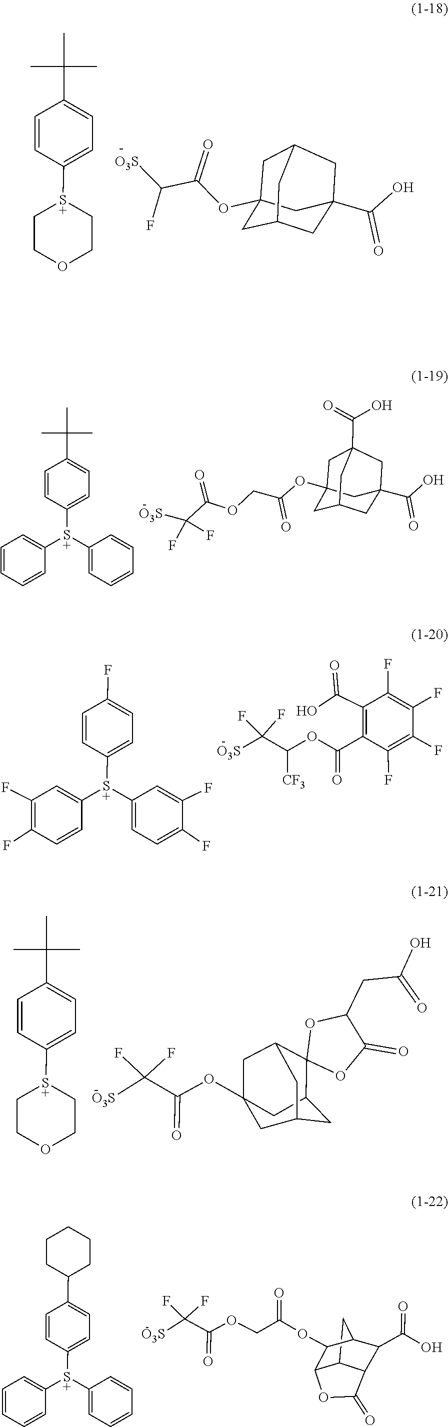

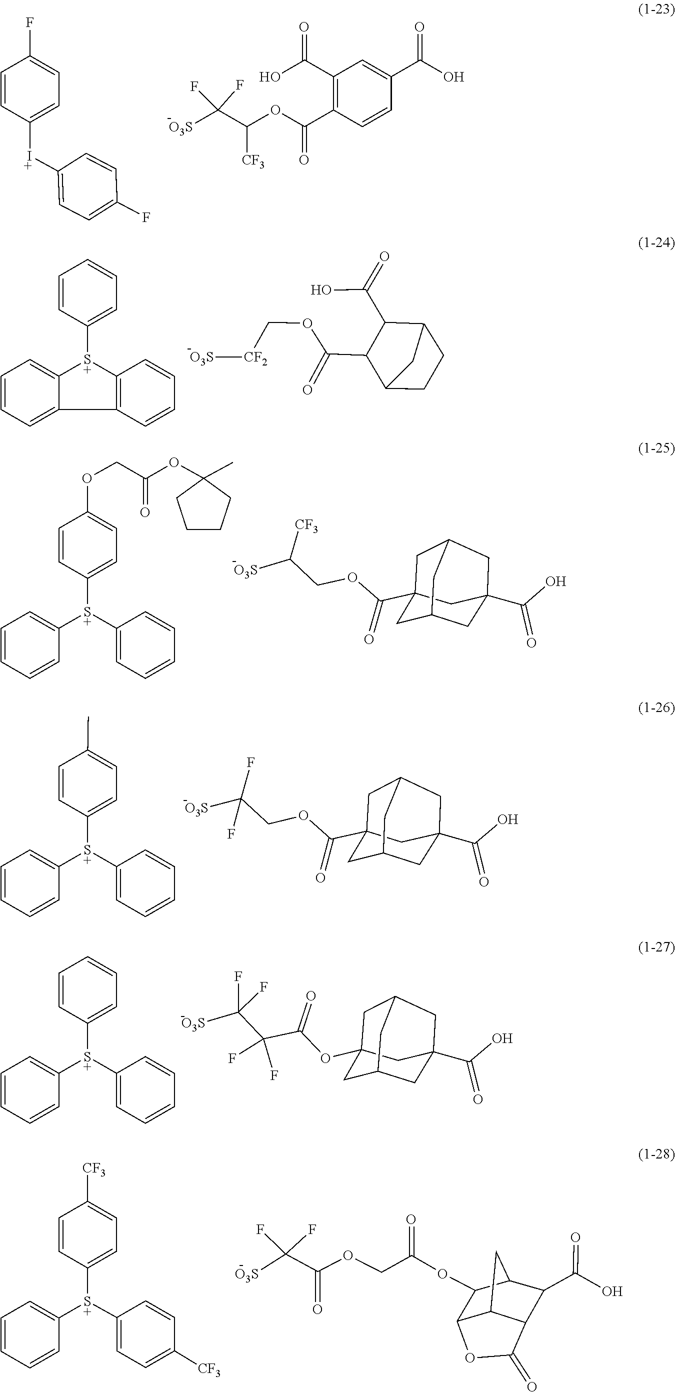

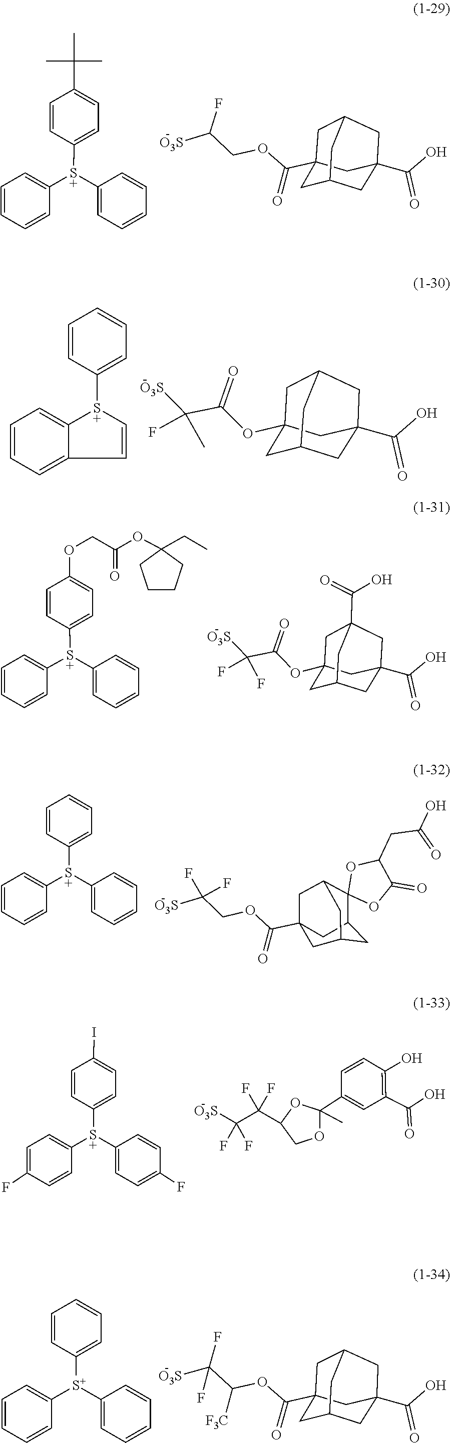

The lower limit of the content of the first onium salt compound (when plural kinds of first onium salt compounds are contained, the total content thereof) is preferably 1 part by mass, more preferably 2 parts by mass, and still more preferably 3 parts by mass based on 100 parts by mass of the polymer described later. The upper limit of the content is preferably 40 parts by mass, more preferably 35 parts by mass, and still more preferably 30 parts by mass. The content of the first onium salt compound is appropriately selected depending on the type of a polymer to be used, exposure conditions, required sensitivity, and the like. This makes it possible to exhibit superior sensitivity, LWR performance, pattern rectangularity, CDU performance, pattern circularity, MEEF, and exposure latitude when forming a resist pattern.

### (Method for Synthesizing First Onium Salt Compound)

As a method for synthesizing the first onium salt compound, a target first onium salt compound can be synthesized by performing skeleton formation of an organic acid anion, an introduction reaction of a sulfonate structure between a sulfite and an alkyl halide, and salt exchange for introduction of an onium cation in an appropriate order. Known reactions such as an esterification reaction, an acetalization reaction between a diol and a ketone, and an addition cyclization reaction between a conjugated diene and an alkene can be used for skeleton formation of the organic acid anion. Various first onium salt compounds can be synthesized by appropriately selecting starting materials and precursors corresponding to the organic acid anion and the onium cation.

### (Second Onium Salt Compound)

The second onium salt compound can function as an acid diffusion controlling agent represented by the formula (2), and generates an acid having a higher pKa than that of the acid generated from the first onium salt compound which is the radiation-sensitive acid generator upon irradiation with radiation. That is, the second onium salt compound has a function of suppressing, by salt exchange, the diffusion of an acid generated from the radiation-sensitive acid generator in the unexposed portion without generating an acid that substantially dissociates the acid-dissociable group of the base polymer under a pattern forming condition using the radiation-sensitive composition. Alternatively, the second onium salt compound can function as the acid generator represented by the formula (2), and can improve the roughness performance while appropriately adjusting the sensitivity by generating a weak acid capable of selectively dissociating only the acid-dissociable group having low activation energy of the base polymer. Owing to the inclusion of the second onium salt compound, the storage stability of the resulting radiation-sensitive composition is improved. Further, the resolution of a resist pattern is further improved, and it is possible to suppress a change in the line width of a resist pattern caused by variation in post-exposure time delay between exposure and a development process. That is, a radiation-sensitive composition having excellent process stability can be obtained. The composition may contain one type or two or more types of the second onium salt compound.

R⁴ is a monovalent organic group having 1 to 40 carbon atoms. However, to the atom (typically, carbon atom) of R⁴ adjacent to the sulfur atom in SO₃⁻ in the formula (2) is bonded neither a fluorine atom nor a fluorinated hydrocarbon group.

As the monovalent organic group having 1 to 40 carbon atoms represented by R⁴, a monovalent organic group having 1 to 40 carbon atoms shown in A in the formula (1) can be suitably employed.

In the formula (2), R⁴ is preferably a monovalent organic group having 3 to 40 carbon atoms which contains at least one second cyclic structure and in which neither a fluorine atom nor a fluorinated hydrocarbon group is bonded to an atom adjacent to a sulfur atom in SO₃⁻ (typically a carbon atom). The organic group is not particularly limited, and may be either a group containing only a second cyclic structure or a group containing a second cyclic structure and a chain structure in combination. The second cyclic structure may be any of a monocyclic structure, a polycyclic structure, or a combination thereof. In addition, the second cyclic structure may be any of an alicyclic structure, an aromatic ring structure, a heterocyclic structure, or a combination thereof. In the case of a combination, the combination may be a structure in which cyclic structures may be bonded by a chain structure, or two or more cyclic structures may form a fused ring structure or a spiro ring structure. These structures are preferably contained as a minimum basic backbone of the cyclic structure. The number of the cyclic structures as the basic backbone in the organic group may be 1, or may be 2 or more. The divalent hetero atom-containing linking group may be present between carbon atoms forming the backbone of a second cyclic structure or a chain structure or at a carbon chain terminal, and a hydrogen atom on a carbon atom of a second cyclic structure or a chain structure may be substituted with another substituent.

As the alicyclic structure, a structure corresponding to the monovalent alicyclic hydrocarbon group having 3 to 20 carbon atoms in A in the formula (1) can be suitably employed.

As the aromatic cyclic structure, a structure corresponding to the monovalent aromatic hydrocarbon group having 6 to 20 carbon atoms in A in the formula (1) can be suitably employed.

As the chain structure, a structure corresponding to the monovalent chain hydrocarbon group having 1 to 20 carbon atoms in A in the formula (1) can be suitably employed.

Examples of the heterocyclic structure include an aromatic heterocyclic structure and an alicyclic heterocyclic structure. As these structures, an aromatic heterocyclic structure and an alicyclic heterocyclic structure in A in the formula (1) can be suitably employed.

As another substituent that substitutes the hydrogen atom on the carbon atom of the second cyclic structure or chain structure, the substituent that can be possessed by the organic group of A and a carboxy group can be suitably employed.

Among them, the second cyclic structure contained in R⁴ is preferably a substituted or unsubstituted alicyclic polycyclic structure having 6 to 14 carbon atoms, or an aromatic hydrocarbon ring structure or heterocyclic polycyclic structure having 6 to 12 carbon atoms.

The second cyclic structure and SO₃⁻ are bonded via a divalent linking group, and the divalent linking group is preferably a substituted or unsubstituted divalent chain hydrocarbon group having 1 to 10 carbon atoms, or a group containing a divalent heteroatom-containing linking group between carbon atoms of the chain hydrocarbon group or at a terminal of the chain hydrocarbon group.

Specific examples of the anion moiety of the second onium salt compound include, but are not limited to, the structures represented by formulas (2-1-1) to (2-1-39) below.

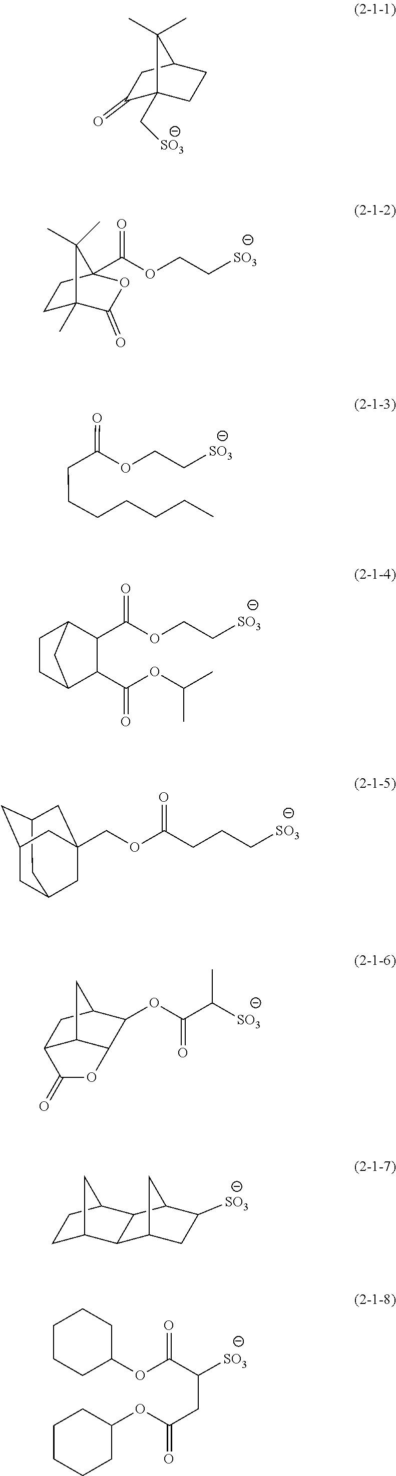

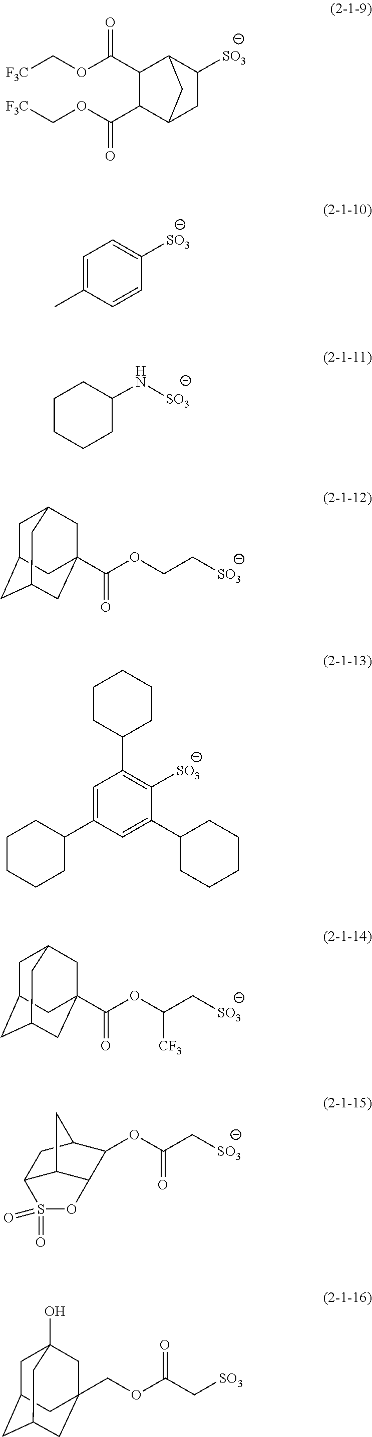

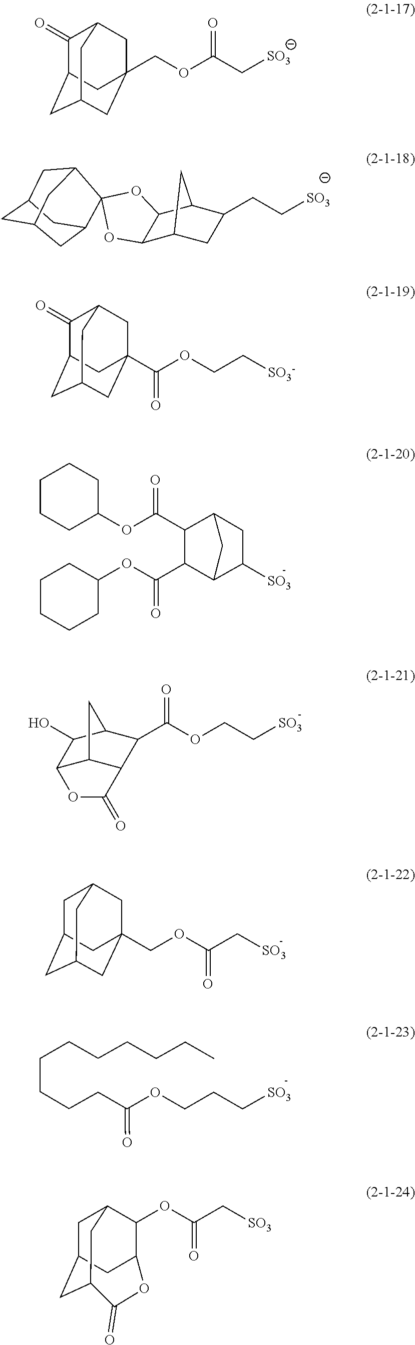

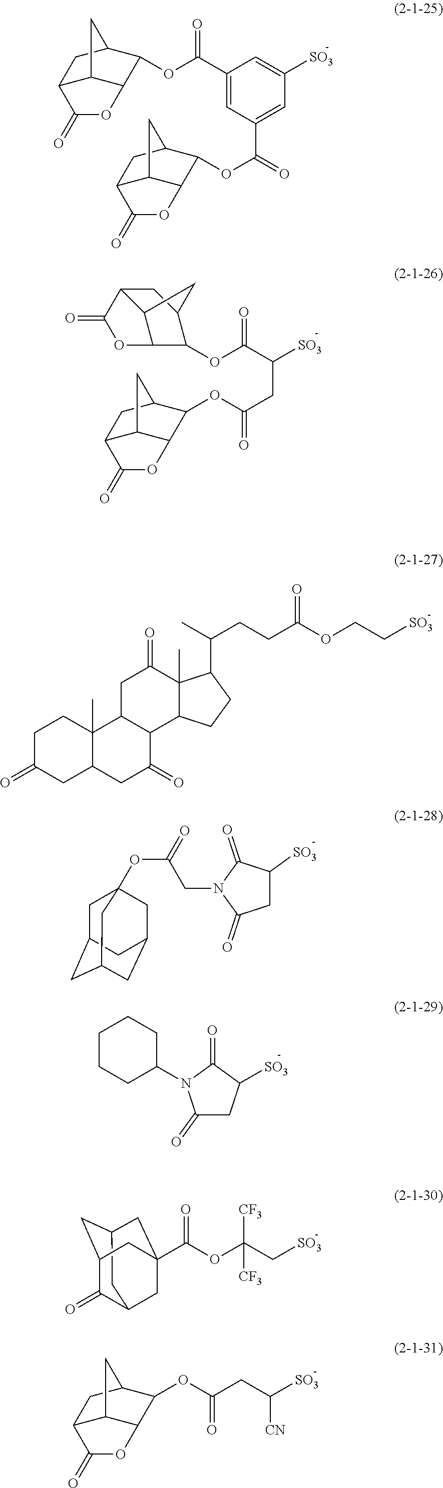

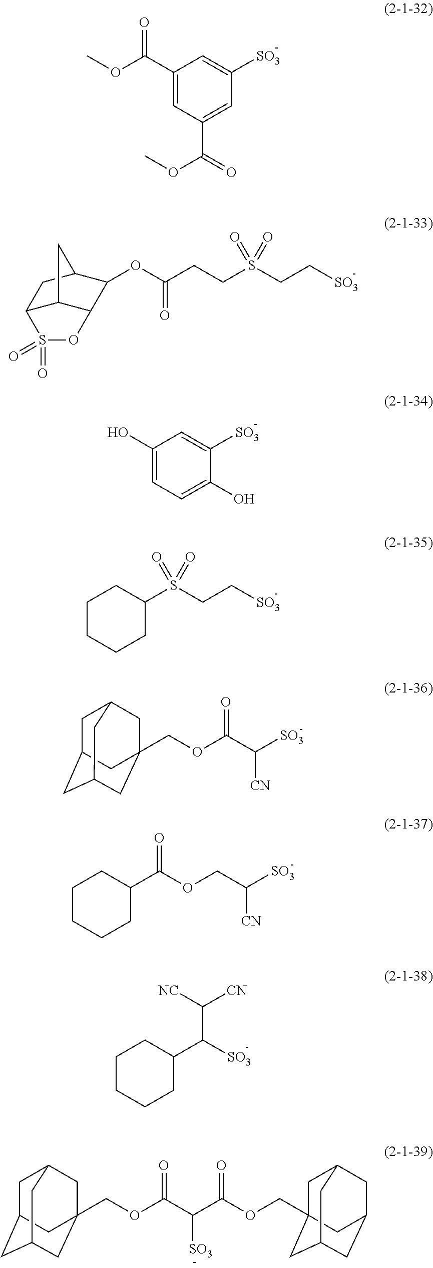

Specific examples of the organic cation of the second onium salt compound include, but are not limited to, known organic onium cations such as organic sulfonium cations, organic iodonium cations, organic ammonium cations, benzothiazolium cation, and organic phosphonium cations. Among them, the organic sulfonium cations and the organic iodonium cations are preferable. As the organic sulfonium cations and the organic iodonium cations, the structures disclosed as specific examples of the radiation-sensitive onium cation can be suitably employed.

Examples of the second onium salt compound include structures obtained by arbitrarily combining the aforementioned anion moieties and the aforementioned organic cations. Specific examples of the second onium salt compound include, but not limited thereto, the onium salt compounds represented by formulas (2-1) to (2-29) below.

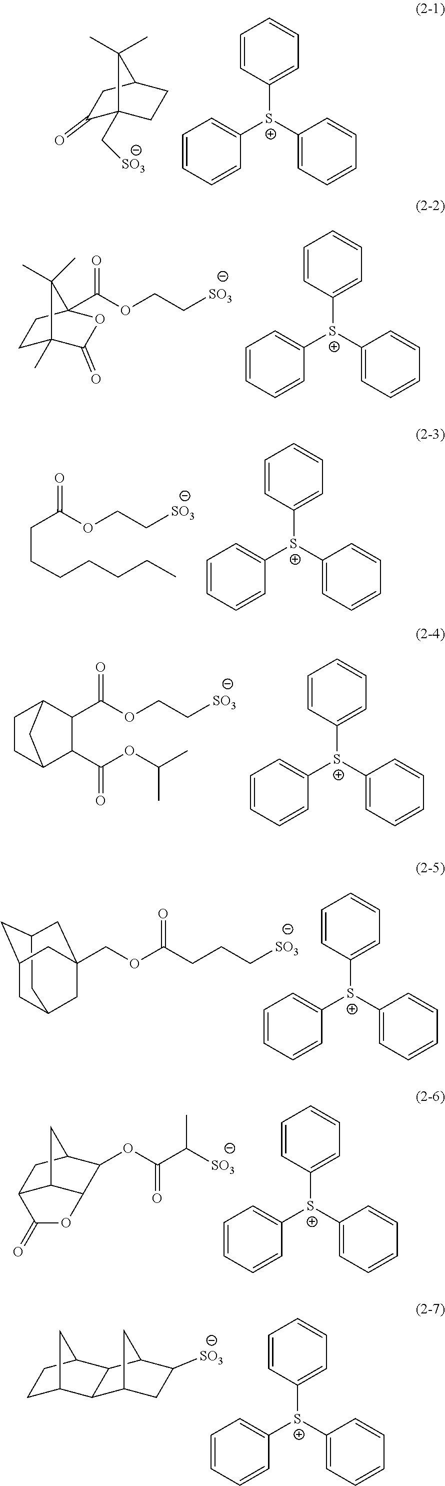

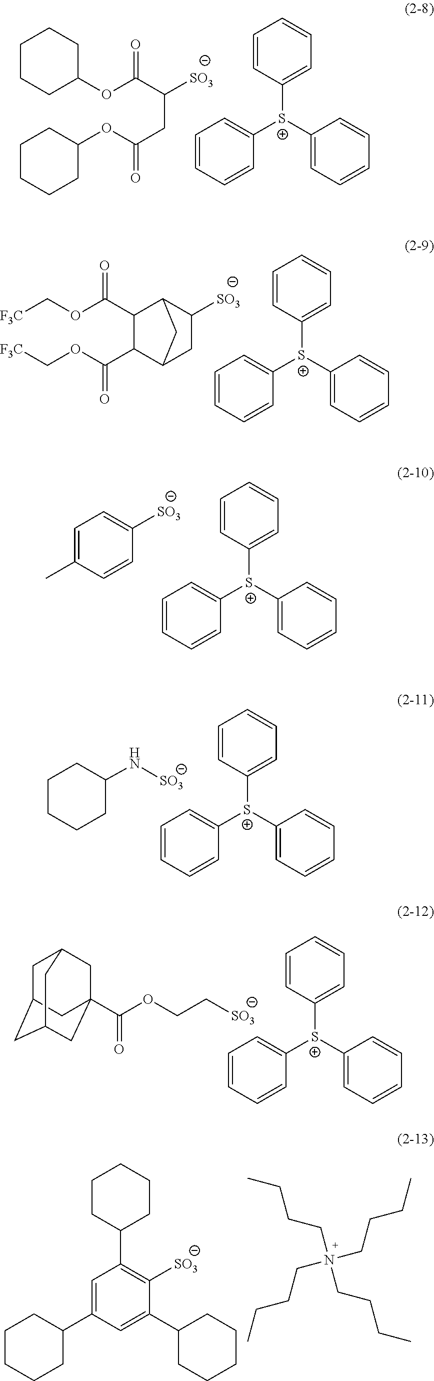

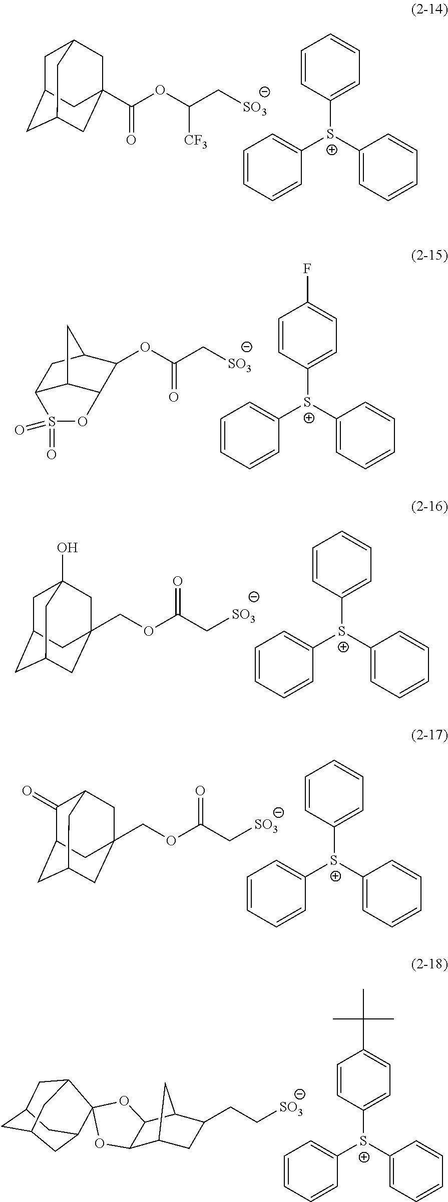

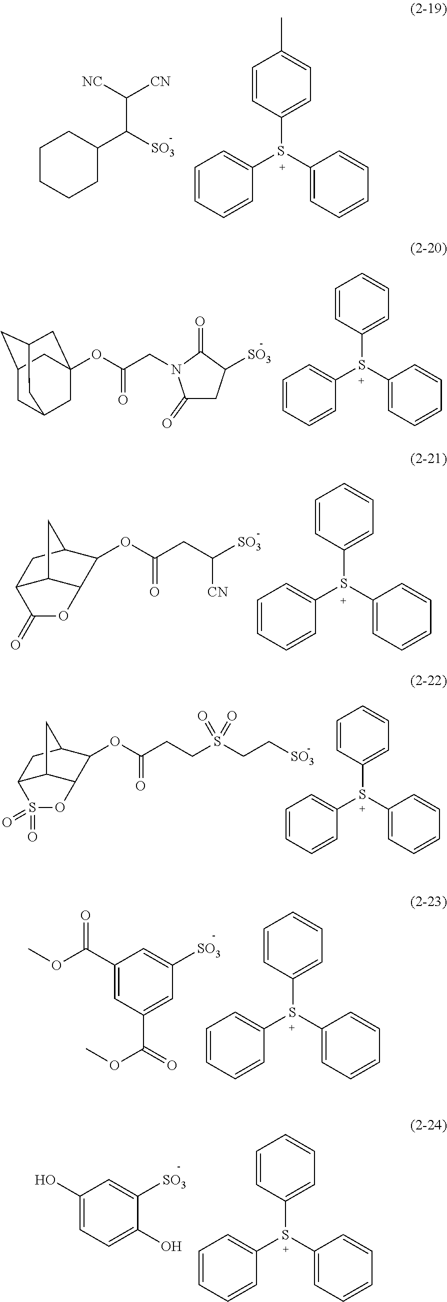

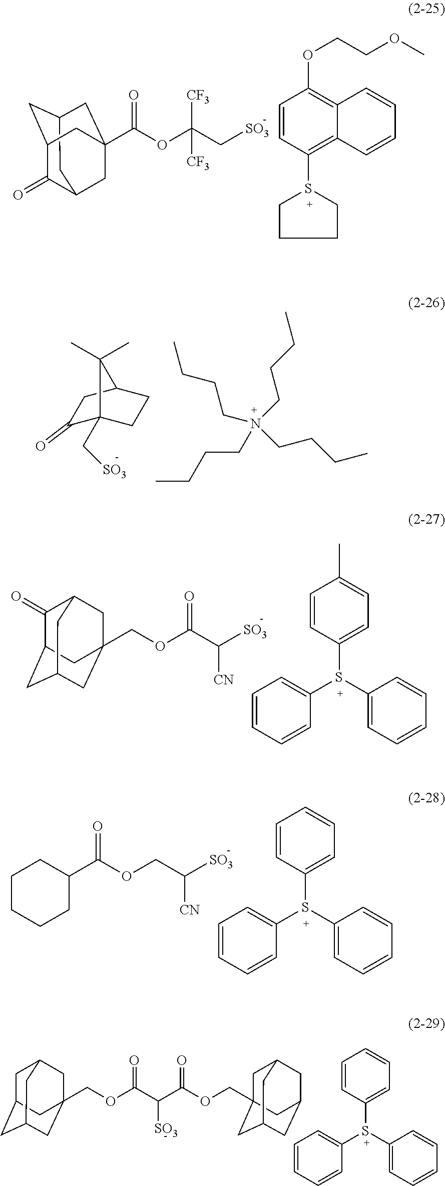

The lower limit of the content of the second onium salt compound (when plural kinds of second onium salt compounds are contained, the total content thereof) is preferably 1 part by mass, more preferably 2 parts by mass, and still more preferably 3 parts by mass based on 100 parts by mass of the polymer described later. The upper limit of the content is preferably 30 parts by mass, more preferably 20 parts by mass, and still more preferably 10 parts by mass. The content of the second onium salt compound is appropriately selected depending on the type of a polymer to be used, exposure conditions, required sensitivity, and the like. This makes it possible to exhibit superior sensitivity, LWR performance, pattern rectangularity, CDU performance, pattern circularity, MEEF, and exposure latitude when forming a resist pattern.

### (Polymer)

The polymer (base polymer) is an aggregate of polymers having a structural unit (hereinafter, also referred to as “structural unit (I)”) containing an acid-dissociable group. The “acid-dissociable group” refers to a group that substitutes for a hydrogen atom of a carboxy group, a phenolic hydroxyl group, an alcoholic hydroxyl group, a sulfo group, or the like, and is dissociated by the action of an acid. The radiation-sensitive composition is excellent in pattern-forming performance because the polymer has the structural unit (I).

In addition to the structural unit (I), the base polymer preferably has a structural unit (II) containing at least one selected from the group consisting of a lactone structure, a cyclic carbonate structure, and a sultone structure described later, and may have another structural unit other than the structural units (I) and (II). Each of the structural units will be described below.

### [Structural Unit (I)]

The structural unit (I) contains an acid-dissociable group. The structural unit (I) is not particularly limited as long as it contains an acid-dissociable group. Examples of such a structural unit (I) include a structural unit having a tertiary alkyl ester moiety, a structural unit having a structure obtained by substituting the hydrogen atom of a phenolic hydroxyl group with a tertiary alkyl group, and a structural unit having an acetal bond. From the viewpoint of improving the pattern-forming performance of the radiation-sensitive composition, a structural unit represented by the formula (3) (hereinafter also referred to as a “structural unit (I-1)”) is preferred.

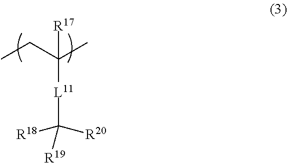

In the formula (3), R¹⁷ is a hydrogen atom, a fluorine atom, a methyl group, or a trifluoromethyl group. R¹⁸ is a monovalent hydrocarbon group having 1 to 20 carbon atoms. R¹⁹ and R²⁰ are each independently a monovalent chain hydrocarbon group having 1 to 10 carbon atoms or a monovalent alicyclic hydrocarbon group having 3 to 20 carbon atoms, or R¹⁹ and R²⁰ taken together represent a divalent alicyclic group having 3 to 20 carbon atoms together with a carbon atom to which R¹⁹ and R²⁰ are bonded. L¹¹ represents *—COO—, *-L^{11a}COO—, or *—COOL^{11a}COO—. L^{11a} is a substituted or unsubstituted alkanediyl group or arenediyl group. * is a bond to a carbon atom to which R¹⁷ is bonded.

From the viewpoint of copolymerizability of a monomer that will give the structural unit (I-1), R⁵¹ is preferably a hydrogen atom or a methyl group, more preferably a methyl group.

Examples of the alkanediyl group represented by L^{11a} include alkanediyl groups having 1 to 10 carbon atoms such as a methylene group, an ethanediyl group, a 1,3-propanediyl group, and a 2,2-propanediyl group. L^{11a} is preferably a methylene group or an ethanediyl group.

Examples of the arenediyl group represented by L^{11a} include divalent aromatic hydrocarbon groups having 6 to 20 carbon atoms such as a benzenediyl group and a naphthalenediyl group. As L^{11a}, a benzenediyl group is preferable.

Examples of the substituent that can be possessed by the arenediyl group represented by L^{11a} include a halogen atom, a hydroxy group, a carboxy group, a cyano group, a nitro group, an alkyl group, a fluorinated alkyl group, an alkoxycarbonyloxy group, an acyl group, an acyloxy group, and an alkoxy group.

Examples of the monovalent hydrocarbon group having 1 to 20 carbon atoms represented by R¹⁸ include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the chain hydrocarbon groups having 1 to 10 carbon atoms represented by R¹⁸ to R²⁰ include a linear or branched saturated hydrocarbon group having 1 to 10 carbon atoms or a linear or branched unsaturated hydrocarbon group having 1 to 10 carbon atoms.

As the alicyclic hydrocarbon groups having 3 to 20 carbon atoms represented by R¹⁸ to R²⁰, the monovalent alicyclic hydrocarbon groups having 3 to 20 carbon atoms in A of the formula (1) can be suitably employed.

As the monovalent aromatic hydrocarbon group having 6 to 20 carbon atoms represented by R¹⁸, the monovalent aromatic hydrocarbon groups having 6 to 20 carbon atoms in A in the formula (1) can be suitably employed.

R¹⁸ is preferably a linear or branched saturated hydrocarbon group having 1 to 10 carbon atoms or an alicyclic hydrocarbon group having 3 to 20 carbon atoms.

The divalent alicyclic group having 3 to 20 carbon atoms formed by the chain hydrocarbon group or the alicyclic hydrocarbon group represented by R¹⁹ and R²⁰ taken together with the carbon atom to which R⁵³ and R⁵⁴ are bonded is not particularly limited as long as it is a group obtained by removing two hydrogen atoms from the same carbon atom constituting a carbon ring of a monocyclic or polycyclic alicyclic hydrocarbon having the above-described carbon number. The divalent alicyclic group having 3 to 20 carbon atoms may either be a monocyclic hydrocarbon group or a polycyclic hydrocarbon group. The polycyclic hydrocarbon group may either be a bridged alicyclic hydrocarbon group or a condensed alicyclic hydrocarbon group and may either be a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

When the monocyclic alicyclic hydrocarbon group is a saturated hydrocarbon group, preferred examples thereof include a cyclopentanediyl group, a cyclohexanediyl group, a cycloheptanediyl group, and a cyclooctanediyl group. When the monocyclic alicyclic hydrocarbon group is an unsaturated hydrocarbon group, preferred examples thereof include a cyclopentenediyl group, a cyclohexenediyl group, a cycloheptenediyl group, a cyclooctenediyl group, and a cyclodecenediyl group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, a tricyclo[3.3.1.1^{3,7}]decane-2,2-diyl group (adamantane-2,2-diyl group), and a tricyclo[5.2.1.0^{2,6}]decane-8,8-diyl group.

Among them, R¹⁸ is preferably an alkyl group having 1 to 4 carbon atoms, and the alicyclic structure formed by R¹⁹ and R²⁰ combined together and a carbon atom to which they are bonded is preferably a polycyclic or monocyclic cycloalkane structure.

Examples of the structural unit (I-1) include structural units represented by the formulas (3-1) to (3-15) (hereinafter also referred to as “structural units (I-1-1) to (I-1-15)”).

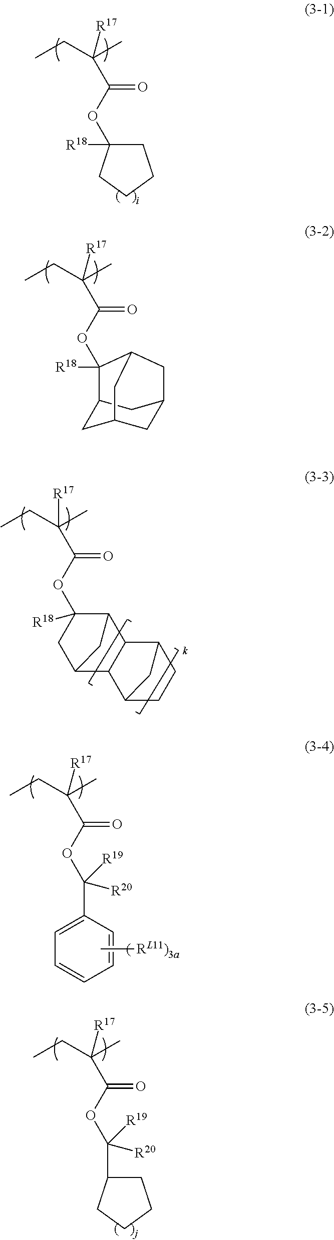

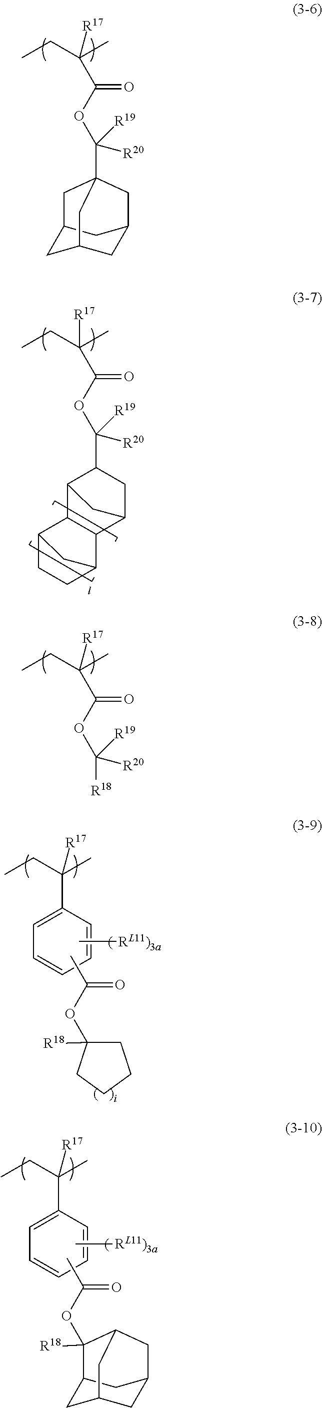

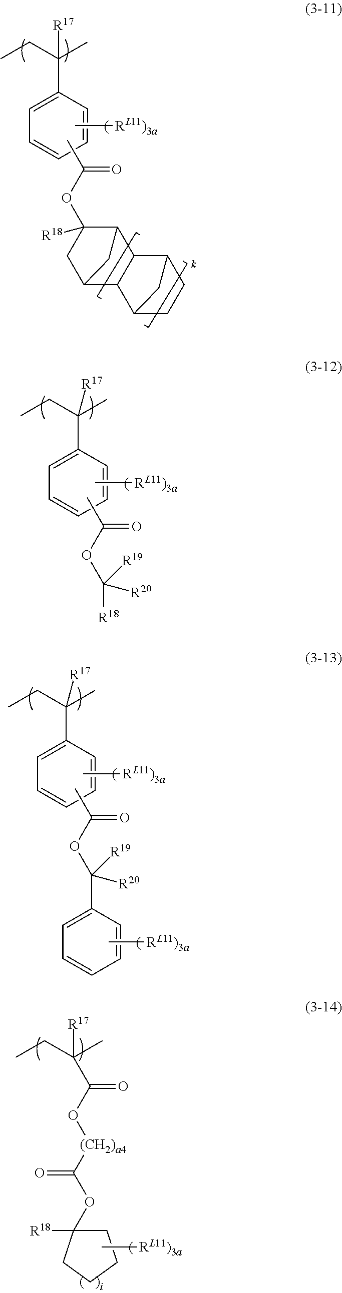

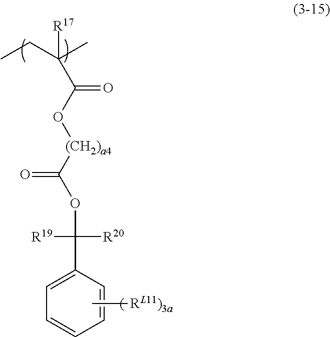

In the formulas (3-1) to (3-15), R¹⁷ to R²⁰ have the same meaning as in the formula (3). R^{L11} is a halogen atom, a hydroxy group, a carboxy group, a cyano group, a nitro group, an alkyl group, a fluorinated alkyl group, an alkoxycarbonyloxy group, an acyl group, an acyloxy group, or an alkoxy group. i and j are each independently an integer of 1 to 4. k and l are each 0 or 1. 3a's are each independently an integer of 0 to 3. When 3a is 2 or more, a plurality of R^{L11}s are the same as or different from each other. a4 is an integer of 1 to 3.

As i and j, 1 is preferable. R¹⁸ is preferably a methyl group, an ethyl group, an isopropyl group, a t-butyl group, a cyclopentyl group, an ethenyl group, a phenyl group, or an iodophenyl group. As R¹⁹ and R²⁰, a methyl group, an ethyl group, and an isopropyl group are preferable. By employing an iodine atom as R^{L11}, an iodo group can be suitably introduced into the structural unit (I).

Furthermore, the polymer may contain structural units represented by formulas (1f) to (2f) below as the structural unit (I).

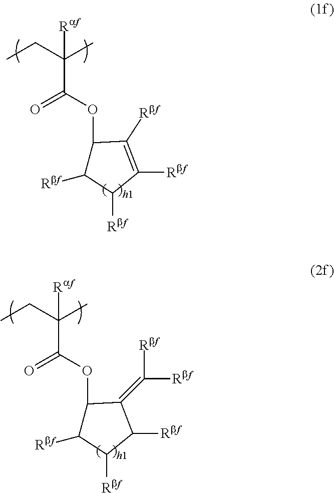

In the formulas (1f) to (2f), R^{αf}s are each independently a hydrogen atom, a fluorine atom, a methyl group, or a trifluoromethyl group. R^{βf}s are each independently a hydrogen atom or a chain alkyl group having 1 to 5 carbon atoms. h1 is an integer of 1 to 4.

As the R^{βf}, a hydrogen atom, a methyl group, or an ethyl group is preferable. h1 is preferably 1 or 2.

The base polymer may contain one type or a combination of two or more types of the structural units (I).

The lower limit of the content by percent of the structural unit (I) (a total content by percent when a plurality of types are contained) is preferably 10 mol %, more preferably 20 mol %, still more preferably 30 mol %, and particularly preferably 35 mol % based on all structural units constituting the base polymer. The upper limit of the content by percent is preferably 80 mol %, more preferably 70 mol %, still more preferably 60 mol %, and particularly preferably 55 mol %. When the content of the structural unit (I) is set to fall within the above range, the pattern-forming performance of the radiation-sensitive composition can further be improved.

### [Structural Unit (II)]

The structural unit (II) is a structural unit including at least one selected from the group consisting of a lactone structure, a cyclic carbonate structure and a sultone structure. The solubility of the base polymer into a developer can be adjusted by further introducing the structural unit (II). As a result, the radiation-sensitive composition can provide improved lithography properties such as the resolution. The adhesion between a resist pattern formed from the base polymer and a substrate can also be improved.

Examples of the structural unit (II) include structural units represented by the formulae (T-1) to (T-11).

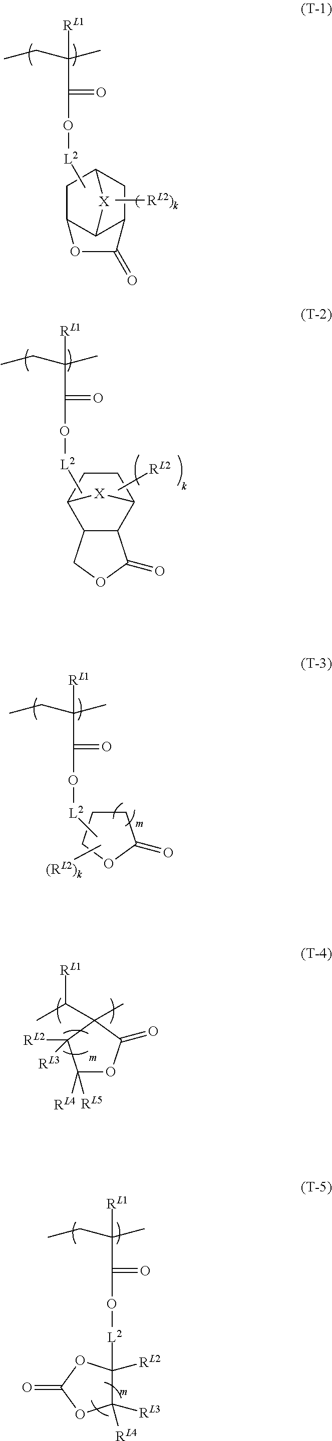

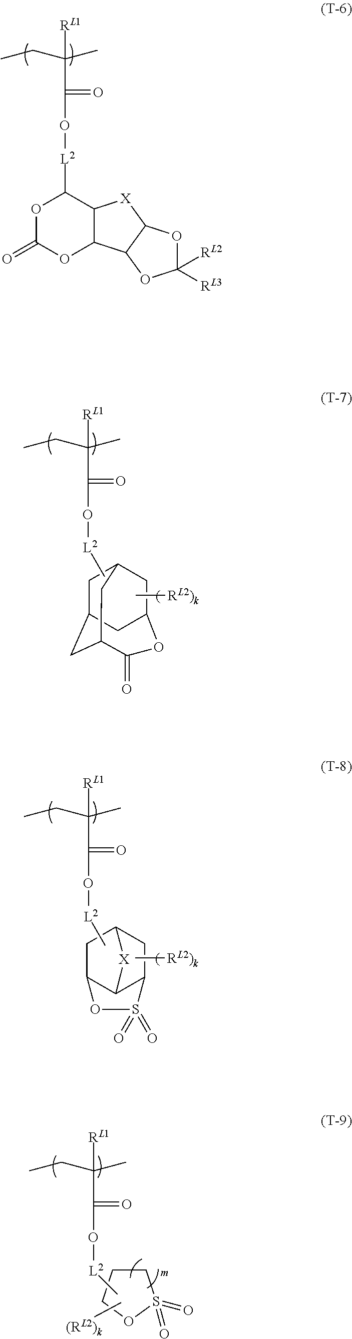

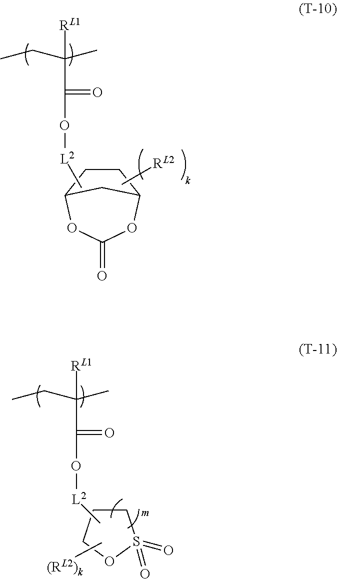

In the formulae, R^{L1} is a hydrogen atom, a fluorine atom, a methyl group, or a trifluoromethyl group; R^{L2} to R^{L5} are each independently a hydrogen atom, an alkyl group having 1 to 4 carbon atoms, a cyano group, a trifluoromethyl group, a methoxy group, a methoxycarbonyl group, a hydroxy group, a hydroxymethyl group, or a dimethylamino group; R^{L4} and R^{L5} may be a divalent alicyclic group having 3 to 8 carbon atoms, which is obtained by combining R^{L4} and R^{L5} with the carbon atom to which they are bound. L² is a single bond, or a divalent linking group; X is an oxygen atom or a methylene group; k is an integer of 0 to 3; and m is an integer of 1 to 3.

Example of the divalent alicyclic group having 3 to 8 carbon atoms, which is composed of a combination of R^{L4} and R^{L5} with the carbon atom to which they are bound, includes the divalent alicyclic group having 3 to 8 carbon atoms in the divalent alicyclic group having 3 to 20 carbon atoms, which is composed of R¹⁹ and R²⁰ in the formula (3) with the carbon atom to which they are bound. One or more hydrogen atoms on the alicyclic group may be substituted with a hydroxy group.

Examples of the divalent linking group represented by L² as described above include a divalent straight or branched chain hydrocarbon group having 1 to 10 carbon atoms; a divalent alicyclic hydrocarbon group having 4 to 12 carbon atoms; and a group composed of one or more of the hydrocarbon group thereof and at least one group of —CO—, —O—, —NH— and —S—.

Among them, the structural unit (II) is preferably a group having a lactone structure, more preferably a group having a γ-butyrolactone structure or a norbornane lactone structure, and further preferably a group derived from a γ-butyrolactone-yl-(meth)acrylate or a norbornane lactone-yl (meth)acrylate.

The lower limit of the content by percent of the structural unit (II) is preferably 15 mol %, more preferably 20 mol %, and still more preferably 25 mol % based on all structural units constituting the base polymer. The upper limit of the content by percent is preferably 80 mol %, more preferably 70 mol %, and still more preferably 65 mol %. By adjusting the content by percent of the structural unit (II) within the ranges, the radiation-sensitive composition can provide improved lithography properties such as the resolution. The adhesion between the formed resist pattern and the substrate can also be improved.

### [Structural Unit (III)]

The base polymer optionally has another structural unit in addition to the structural units (I) and (II). Another structural unit includes a structural unit (III) containing a polar group (excluding those corresponding to the structural unit (II)). When the base polymer further has a structural unit (III), solubility in the developer can be adjusted. As a result, lithographic performance such as resolution of the radiation-sensitive composition can be improved. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (III) include structural units represented by the formulas.

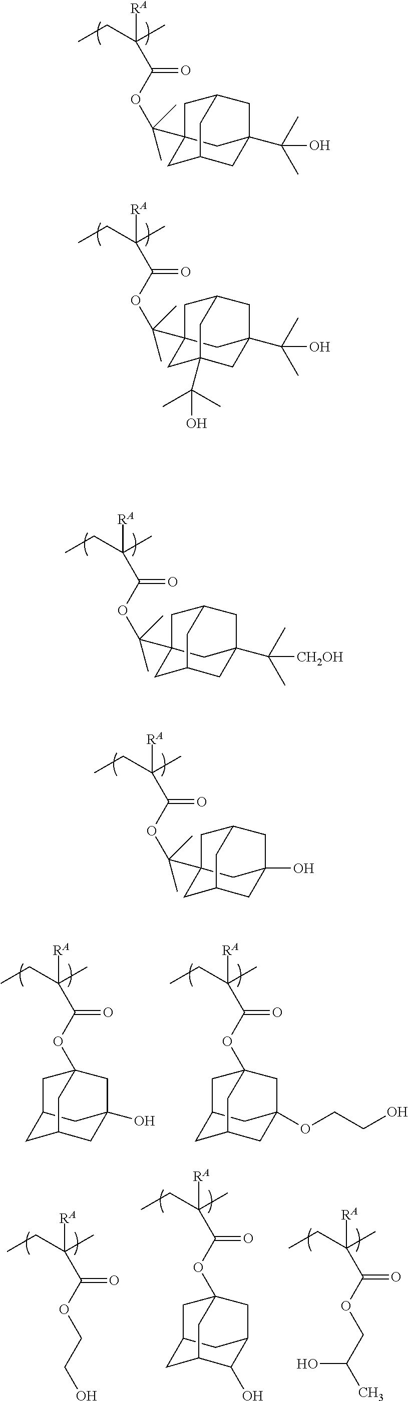

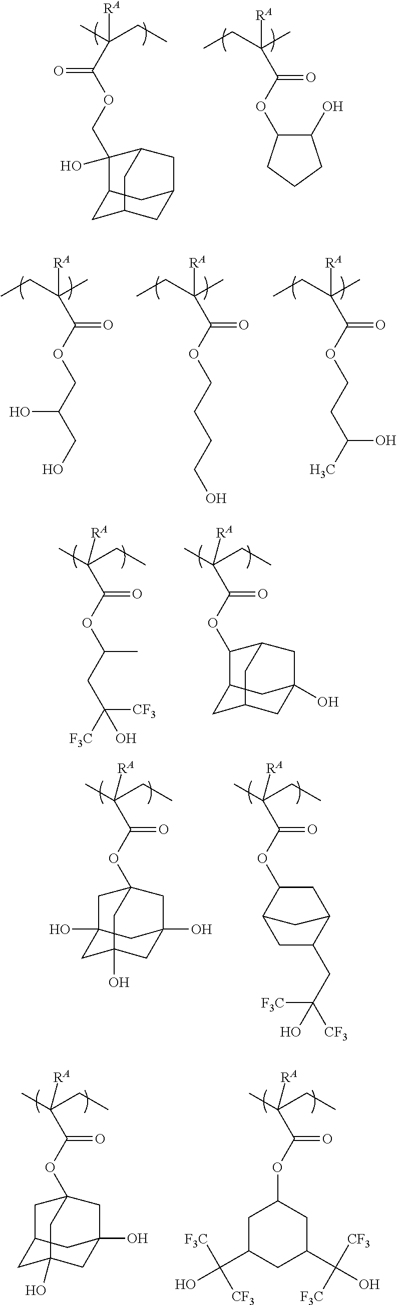

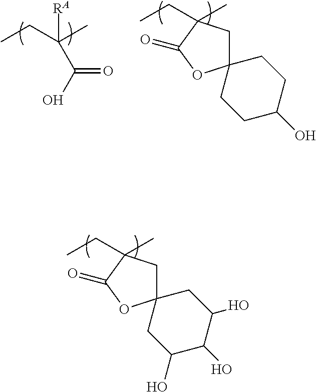

In the formulas, R^{A} is a hydrogen atom, a fluorine atom, a methyl group, or a trifluoromethyl group.

When the base polymer has the structural unit (III) having a polar group, the lower limit of the content by percent of the structural unit (III) is preferably 5 mol %, more preferably 8 mol %, and still more preferably 10 mol % based on all structural units constituting the base polymer. The upper limit of the content by percent is preferably 40 mol %, more preferably 30 mol %, and still more preferably 20 mol %. When the content of the structural unit (III) is set to fall within the above range, the radiation-sensitive composition can provide further improved lithography properties such as the resolution.

### [Structural Unit (IV)]

The base polymer optionally has, as another structural unit, a structural unit having a phenolic hydroxyl group (hereinafter also referred to as “structural unit (IV)”), in addition to the structural unit (III) having a polar group. The structural unit (IV) contributes to an improvement in etching resistance and an improvement in a difference in solubility of a developer (dissolution contrast) between an exposed part and a non-exposed part. In particular, the structural unit (IV) can be suitably applied to pattern formation using exposure with a radioactive ray having a wavelength of 50 nm or less, such as an electron beam or EUV. In this case, the polymer preferably has the structural unit (I) together with the structural unit (IV).

The structural unit containing a phenolic hydroxy group is represented by, for example, the formulas (4-1) to (4-2).

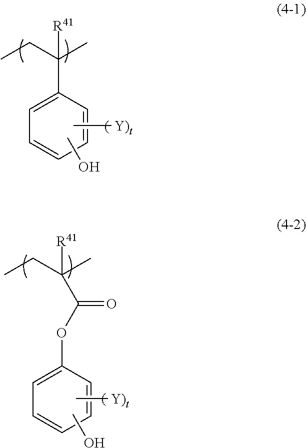

In the formulas (4-1) to (4-2), R⁴¹ is independently at each occurrence a hydrogen atom, a fluorine atom, a methyl group, or a trifluoromethyl group. Y is a halogen atom, a trifluoromethyl group, a cyano group, an alkyl or alkoxy group having 1 to 6 carbon atoms, or an acyl, acyloxy, or alkoxycarbonyl group having 2 to 7 carbon atoms. When there are a plurality of Y's, the plurality of Y's are the same or different from each other, t is an integer of 0 to 4.

When the structural unit (IV) is obtained, it is preferable to obtain the structural unit (IV) by polymerizing the corresponding monomer in a state where the phenolic hydroxy group is protected by a protecting group such as an alkali-dissociable group (e.g., an acyl group) during polymerization, and then deprotecting the polymerized product by hydrolysis. The polymerization may be carried out without protecting the phenolic hydroxyl group.

In the case of a polymer for exposure to radiation having a wavelength of 50 nm or less, the lower limit of the content by percent of the structural unit (IV) is preferably 10 mol %, and more preferably 20 mol % based on all structural units constituting the polymer. The upper limit of the content by percent is preferably 70 mol %, and more preferably 60 mol %.

### [Other Structural Unit]

The base polymer may contain a structural unit having an alicyclic structure represented by the formula (6) (hereinafter also referred to as “structural unit (VII)”) as a structural unit other than the structural units listed above.

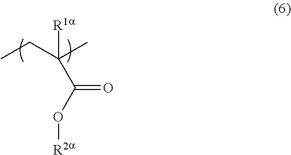

In the formula (6), R^{1α} represents a hydrogen atom, a fluorine atom, a methyl group, or a trifluoromethyl group, and R^{2α} represents a monovalent alicyclic hydrocarbon group having 3 to 20 carbon atoms.

In the formula (6), as the monovalent alicyclic hydrocarbon group having 3 to 20 carbon atoms represented by R^{2α}, the monovalent alicyclic hydrocarbon groups having 3 to 20 carbon atoms represented by A in the formula (1) can be suitably employed.

When the base polymer contains the structural unit (VII), the lower limit of the content by percent of the structural unit (VII) is preferably 2 mol %, more preferably 5 mol %, and still more preferably 8 mol % based on all structural units constituting the base polymer. The upper limit of the content by percent is preferably 30 mol %, more preferably 20 mol %, and still more preferably 15 mol %.

### (Synthesis Method of Base Polymer)

For example, the base polymer can be synthesized by performing a polymerization reaction of each monomer for providing each structural unit with a radical polymerization initiator or the like in a suitable solvent.

Examples of the radical polymerization initiator include an azo-based radical initiator, including azobisisobutyronitrile (AIBN), 2,2′-azobis(4-methoxy-2,4-dimethylvaleronitrile), 2,2′-azobis(2-cyclopropylpropanenitrile), 2,2′-azobis(2,4-dimethylvaleronitrile), and dimethyl 2,2′-azobisisobutyrate; and peroxide-based radical initiator, including benzoyl peroxide, t-butyl hydroperoxide, and cumene hydroperoxide. Among them, AIBN or dimethyl 2,2′-azobisisobutyrate is preferred. The radical initiator may be used alone, or two or more radical initiators may be used in combination.

Examples of the solvent used for the polymerization reaction include
alkanes including n-pentane, n-hexane, n-heptane, n-octane, n-nonane, and n-decane;
cycloalkanes including cyclohexane, cycloheptane, cyclooctane, decalin, and norbornane;
aromatic hydrocarbons including benzene, toluene, xylene, ethylbenzene, and cumene;
halogenated hydrocarbons including chlorobutanes, bromohexanes, dichloroethanes, hexamethylenedibromide, and chlorobenzenes;
saturated carboxylate esters, including ethyl acetate, n-butyl acetate, i-butyl acetate, and methyl propionate;
polyhydric alcohol partial ether acetate-based solvents, such as diethylene glycol mono-n-butyl ether acetate, propylene glycol monomethyl ether acetate, and dipropylene glycol monomethyl ether acetate;
ketones such as acetone, 2-butanone (methyl ethyl ketone), 4-methyl-2-pentanone, 2-heptanone, and cyclohexanone;
ethers such as tetrahydrofuran, dimethoxyethane, diethoxyethane, and 1,4-dioxane;
alcohols such as methanol, ethanol, 1-propanol, 2-propanol, 4-methyl-2-pentanol, and 1-methoxy-2-propanol; and
lactones such as γ-butyrolactone. The solvents to be used in the polymerization may be used singly, or two or more thereof may be used in combination.

The reaction temperature of the polymerization reaction is typically from 40° C. to 150° C., and preferably from 50° C. to 120° C. The reaction time is typically from 1 hour to 48 hours, and preferably from 1 hour to 24 hours.

The molecular weight of the base polymer is not particularly limited, but the lower limit of the weight average molecular weight (Mw) as determined by Gel Permeation Chromatography (GPC) relative to standard polystyrene is preferably 3,000, more preferably 4,000, and still more preferably 5,000. The upper limit of the Mw is preferably 20,000, more preferably 15,000, and still more preferably 10,000. When the Mw of the base polymer is within the above range, the resulting resist film can obtain good heat resistance and developability.

For the base polymer, the ratio of Mw to the number average molecular weight (Mn) as determined by GPC relative to standard polystyrene (Mw/Mn) is typically 1 or more and 5 or less, preferably 1 or more and 3 or less, and more preferably 1 or more and 2 or less.

The Mw and Mn of the polymer in the specification are amounts measured by using Gel Permeation Chromatography (GPC) with the condition as described below.
GPC column: two G2000HXL, one G3000HXL, and one G4000HXL (all manufactured from Tosoh Corporation)
Column temperature: 40° C.
Eluting solvent: tetrahydrofuran
Flow rate: 1.0 mL/min
Sample concentration: 1.0% by mass
Sample injection amount: 100 μL
Detector: Differential Refractometer
Reference material: monodisperse polystyrene

The content by percent of the base polymer is preferably 60% by mass or more, more preferably 65% by mass or more, and still more preferably 70% by mass or more based on the total solid content of the radiation-sensitive composition.

### (Another Polymer)

The radiation-sensitive composition according to the present embodiment may contain, as another polymer, a polymer having higher content by mass of fluorine atoms than the above-described base polymer (hereinafter, also referred to as a “high fluorine-content polymer”). When the radiation-sensitive composition contains the high fluorine-content polymer, the high fluorine-content polymer can be localized in the surface layer of a resist film compared to the base polymer, which as a result makes it possible to enhance the water repellency of the surface of the resist film during immersion exposure or to perform surface modification of the resist film during EUV exposure or control of the distribution of the composition in the film. The radiation-sensitive composition may contain one or more high fluorine-content polymers.

The high fluorine-content polymer preferably has, for example, a structural unit represented by the formula (5) (hereinafter, also referred to as “structural unit (V)”).

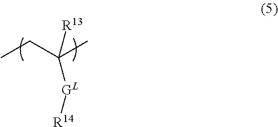

In the formula (5), R¹³ is a hydrogen atom, a methyl group, or a trifluoromethyl group; G^{L} is a single bond, an alkanediyl group having 1 to 5 carbon atoms, an oxygen atom, a sulfur atom, —COO—, —SO₂ONH—, —CONH—, —OCONH—, or a combination thereof; and R¹⁴ is a monovalent fluorinated chain hydrocarbon group having 1 to 20 carbon atoms, or a monovalent fluorinated alicyclic hydrocarbon group having 3 to 20 carbon atoms.

As R¹³ as described above, in terms of the copolymerizability of monomers resulting in the structural unit (V), a hydrogen atom or a methyl group is preferred, and a methyl group is more preferred.

As G^{L} as described above, a single bond, and —COO— are preferable, and —COO— is more preferable from the viewpoint of the copolymerizability of a monomer that gives the structural unit (V).

Example of the monovalent fluorinated chain hydrocarbon group having 1 to 20 carbon atoms represented by R¹⁴ as described above includes a group in which a part of or all of hydrogen atoms in the straight or branched chain alkyl group having 1 to 20 carbon atoms is/are substituted with a fluorine atom.

Example of the monovalent fluorinated alicyclic hydrocarbon group having 3 to 20 carbon atoms represented by R¹⁴ as described above includes a group in which a part of or all of hydrogen atoms in the monocyclic or polycyclic hydrocarbon group having 3 to 20 carbon atoms is/are substituted with a fluorine atom.

The R¹⁴ as described above is preferably a fluorinated chain hydrocarbon group, more preferably a fluorinated alkyl group, and further preferably 2,2,2-trifluoroethyl group, 2,2,3,3,3-pentafluoropropyl group, 1,1,1,3,3,3-hexafluoropropyl group and 5,5,5-trifluoro-1,1-diethylpentyl group.

When the high fluorine-content polymer has the structural unit (V), the lower limit of the content ratio of the structural unit (V) is preferably 50 mol %, more preferably 60 mol %, and still more preferably 70 mol % with respect to all structural units constituting the high fluorine-content polymer. The upper limit of the content ratio is preferably 95 mol %, more preferably 90 mol %, and still more preferably 85 mol %. When the content ratio of the structural unit (V) is set to fall within the above range, the content by mass of fluorine atoms of the high fluorine-content polymer can more appropriately be adjusted to further promote the localization of the high fluorine-content polymer in the surface layer of a resist film and, as a result, the water repellency of the surface of the resist film during immersion exposure can be increased, and the surface modification of the resist film during EUV exposure and the control of distribution of the composition in the film can be performed at a sufficient level.

The high fluorine-content polymer may have a fluorine atom-containing structural unit represented by the formula (f-2) (hereinafter, also referred to as a “structural unit (VI)”) in addition to or in place of the structural unit (V). When the high fluorine-content polymer has the structural unit (VI), solubility in an alkaline developing solution is improved, and therefore generation of development defects can be prevented.

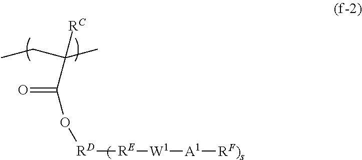

The structural unit (VI) is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{C} in the formula (f-2) is a hydrogen atom, a fluorine atom, a methyl group, or a trifluoromethyl group; R^{D} is a single bond, a hydrocarbon group having 1 to 20 carbon atoms with the valency of (s+1), a structure in which an oxygen atom, a sulfur atom, —NR^{dd}—, a carbonyl group, —COO—, —OCO—, or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having 1 to 10 carbon atoms; and s is an integer of 1 to 3.

When the structural unit (VI) has the alkali soluble group (x), R^{F} is a hydrogen atom; A¹ is an oxygen atom, —COO—* or —SO₂O—*; * refers to a bond to R^{F}; W¹ is a single bond, a hydrocarbon group having 1 to 20 carbon atoms, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{E} is a single bond, or a divalent organic group having 1 to 20 carbon atoms. When s is 2 or 3, a plurality of R^{E}, W¹, A¹ and R^{F} may be each identical or different. The affinity of the high fluorine-content polymer into the alkaline developing solution can be improved by including the structural unit (VI) having the alkali soluble group (x), and thereby prevent from generating the development defect. As the structural unit (VI) having the alkali soluble group (x), particularly preferred is a structural unit in which A¹ is an oxygen atom and W¹ is a 1,1,1,3,3,3-hexafluoro-2,2-methanediyl group.

When the structural unit (VI) has the alkali-dissociable group (y), R^{F} is a monovalent organic group having 1 to 30 carbon atoms; A¹ is an oxygen atom, —NR^{aa}—, —COO—*, —OCO—*, or —SO₂O—*; R^{aa} is a hydrogen atom, or a monovalent hydrocarbon group having 1 to 10 carbon atoms; * refers to a bond to R^{F}; W¹ is a single bond, or a divalent fluorinated hydrocarbon group having 1 to 20 carbon atoms; R^{E} is a single bond, or a divalent organic group having 1 to 20 carbon atoms. When A¹ is —COO—*, —OCO—* or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; R^{D} is a structure in which a carbonyl group is connected at the terminal on R^{E} side of the hydrocarbon group having 1 to 20 carbon atoms; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit (VI) having the alkali-dissociable group (y). As a result, the affinity of the high fluorine-content polymer into the alkaline developing solution can be significantly improved, and thereby prevent from generating the development defect more efficiently. As the structural unit (VI) having the alkali-dissociable group (y), particularly preferred is a structural unit in which A¹ is —COO—*, and R^{F} or W¹, or both is/are a group having a fluorine atom.

In terms of the copolymerizability of monomers resulting in the structural unit (VI), R^{C} is preferably a hydrogen atom or a methyl group, and more preferably a methyl group.

When R^{E} is a divalent organic group, R^{E} is preferably a group having a lactone structure, more preferably a group having a polycyclic lactone structure, and further preferably a group having a norbornane lactone structure.

When the high fluorine-content polymer has the structural unit (VI), the lower limit of the content ratio of the structural unit (VI) is preferably 40 mol %, more preferably 50 mol %, and still more preferably 55 mol % based on all structural units constituting the high fluorine-content polymer. The upper limit of the content ratio is preferably 90 mol %, more preferably 85 mol %, and still more preferably 80 mol %. When the content ratio of the structural unit (VI) is set to fall within the above range, the water repellency and surface modification properties of the resist film can be improved, and the solubility in an alkaline developer can be improved to efficiently suppress the occurrence of development defects.

### [Other Structural Unit]

The high fluorine-content polymer may contain the structural unit (I), the structural unit (III), and the structural unit (VII) in the base polymer, as structural units other than the structural units listed above.

When the high fluorine-content polymer has the structural unit (I), the lower limit of the content ratio of the structural unit (I) is preferably 2 mol %, more preferably 5 mol %, and still more preferably 8 mol % based on all structural units constituting the high fluorine-content polymer. The upper limit of the content ratio is preferably 40 mol %, more preferably 30 mol %, and still more preferably 15 mol %.

When the high fluorine-content polymer has the structural unit (III), the lower limit of the content ratio of the structural unit (III) is preferably 5 mol %, more preferably 10 mol %, and still more preferably 15 mol % based on all structural units constituting the high fluorine-content polymer. The upper limit of the content ratio is preferably 40 mol %, more preferably 30 mol %, and still more preferably 25 mol %.

When the high fluorine-content polymer contains the structural unit (VII), the lower limit of the content by percent of the structural unit (VII) is preferably 10 mol %, more preferably 20 mol %, and still more preferably 30 mol % based on all structural units constituting the high fluorine-content polymer. The upper limit of the content by percent is preferably 60 mol %, more preferably 50 mol %, and still more preferably 45 mol %.

The lower limit of the Mw of the high fluorine-content polymer is preferably 2,000, more preferably 4,000, and still more preferably 6,000. The upper limit of the Mw is preferably 20,000, more preferably 15,000, still more preferably 10,000.

The lower limit of the Mw/Mn of the high fluorine-content polymer is usually 1, and more preferably 1.1. In addition, the upper limit of the Mw/Mn is usually 5, preferably 3, and more preferably 2.

When the radiation-sensitive composition contains the high-fluorine-content polymer, the content of the high fluorine-containing polymer is preferably 0.1 parts by mass or more, more preferably 0.5 part by mass or more, still more preferably 1 parts by mass or more, and particularly preferably 1.5 parts by mass or more based on 100 parts by mass of the base polymer. The content of the high fluorine-containing polymer is preferably 15 parts by mass or less, more preferably 10 parts by mass or less, still more preferably 8 parts by mass or less, and particularly preferably 5 parts by mass or less.

### (Method for Synthesizing High Fluorine-Content Polymer)

The high fluorine-content polymer can be synthesized by a method similar to the above-described method for synthesizing a base polymer.

### (Solvent)

The radiation-sensitive composition according to the present embodiment contains a solvent. The solvent is not particularly limited as long as it can dissolve or disperse at least the first onium salt compound, the second onium salt compound, the base polymer, and optional components or the like contained as necessary.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
a monoalcohol-based solvent having 1 to 18 carbon atoms, including iso-propanol, 4-methyl-2-pentanol, n-hexanol, 2-ethylhexanol, furfuryl alcohol, cyclohexanol, 3,3,5-trimethylcyclohexanol, and diacetone alcohol;
a polyhydric alcohol having 2 to 18 carbon atoms, including ethylene glycol, 1,2-propylene glycol, 2-methyl-2,4-pentanediol, 2,5-hexanediol, diethylene glycol, dipropylene glycol, triethylene glycol, and tripropylene glycol; and
a polyhydric alcohol partial ether-based solvents obtained by etherifying a part of hydroxy groups of the polyhydric alcohol-based solvents such as 3-methoxybutanol and 1-methoxy-2-propanol (propylene glycol monomethyl ether).

In the present embodiment, the alcohol-based solvents also include alcohol acid ester-based solvents such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate.

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and
2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N,N-dimethylformamide, N,N-diethylformamide, acetamide, N-methylacetamide, N,N-dimethylacetamide, and N-methylpropionamide.

Examples of the ester-based solvent include:
a monocarboxylate ester-based solvent, including n-butyl acetate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including γ-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among these, an alcohol-based solvent, an ester-based solvent, and an ether-based solvent are preferable, an alcohol acid ester-based solvent, a polyhydric alcohol partial ether-based solvent, a polyhydric alcohol partial ether acetate-based solvent, a lactone-based solvent, a monocarboxylic acid ester-based solvent, and a ketone-based solvent are more preferable, and propylene glycol monomethyl ether, propylene glycol monomethyl ether acetate, γ-butyrolactone, ethyl lactate, and cyclohexanone are still more preferable. The radiation-sensitive composition may contain one solvent, or two or more solvents.

### (Other Optional Components)

The radiation-sensitive composition may contain other optional components other than the above-descried components. Examples of other optional components include a known radiation-sensitive acid generator other than the first onium salt compound, a cross-linking agent, a localization enhancing agent, a surfactant, an alicyclic backbone-containing compound, and a sensitizer. These other optional components may be used singly or in combination of two or more of them.

### <Method for Preparing Radiation-Sensitive Composition>

The radiation-sensitive composition can be prepared by, for example, mixing the first onium salt compound, the second onium salt compound, the polymer, and, as necessary, optional components such as the high fluorine-content polymer and the like, as well as the solvent in a prescribed ratio. The radiation-sensitive composition is preferably filtered through, for example, a filter having a pore diameter of about 0.05 μm to 0.40 μm after mixing. The solid matter concentration of the radiation-sensitive composition is usually 0.1 mass % to 50 mass %, preferably 0.5 mass % to 30 mass %, more preferably 1 mass % to 20 mass %.

### <Method for Forming Pattern>

A pattern forming method according to an embodiment of the present disclosure includes:
a step (1) of applying the radiation-sensitive composition directly or indirectly to a substrate to form a resist film (hereinafter, also referred to as a “resist film forming step”);
a step (2) of exposing the resist film (hereinafter, also referred to as an “exposure step”); and
a step (3) of developing the exposed resist film (hereinafter, also referred to as a “developing step”).

In accordance with this method for forming a resist pattern, a high-quality resist pattern can be formed because of the use of the radiation-sensitive composition described above capable of forming a resist film superior in sensitivity, LWR performance, pattern rectangularity, CDU performance, and pattern circularity, MEEF, and Exposure latitude. Hereinbelow, each of the steps will be described.

### [Resist Film Forming Step]

In this step (the above mentioned step (1)), a resist film is formed with the radiation-sensitive composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 150° C., and preferably from 80° C. to 140° C. The duration of PB is typically from 5 seconds to 600 seconds, and preferably from 10 seconds to 300 seconds.

The lower limit of the thickness of the resist film to be formed is preferably 10 nm, more preferably 15 nm, and still more preferably 20 nm. The upper limit of the film thickness is preferably 500 nm, more preferably 400 nm, and still more preferably 300 nm. In particular, when a thick resist film is exposed to ArF excimer laser light in an exposure step described later, the lower limit of the film thickness may be 100 nm, may be 150 nm, or may be 200 nm.

When the immersion exposure is carried out, irrespective of presence of a water repellent polymer additive such as the high fluorine-content polymer in the radiation-sensitive composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

When the next step, the exposure step, is performed with radiation having a wavelength of 50 nm or less, it is preferable to use a polymer having the structural unit (I) and the structural unit (IV) as the base polymer in the composition.

### [Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and γ ray; an electron beam; and a charged particle radiation such as a ray. Among them, far ultraviolet ray, an electron beam, or EUV is preferred. ArF excimer laser light (wavelength is 193 nm), KrF excimer laser light (wavelength is 248 nm), an electron beam, or EUV is more preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the polymer by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

### [Developing Step]

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive composition. Among them, an ether-based solvent, an ester-based solvent or a ketone-based solvent is preferred. As the ether-based solvent, a glycol ether-based solvent is preferable, and ethylene glycol monomethyl ether and propylene glycol monomethyl ether are more preferable. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably 80% by mass or more, more preferably 90% by mass or more, further preferably 95% by mass or more, and particularly preferably 99% by mass or more. Examples of the ingredient other than the organic solvent in the developer include water and silicone oil.

As described above, the developer may be either an alkaline developer or an organic solvent developer. The developer can be appropriately selected depending on whether the desired positive pattern or negative pattern is desired.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### EXAMPLES

Hereinafter, the present invention will be specifically described with reference to Examples, but the present invention is not limited to these Examples. Methods for measuring various physical property values are shown below.

### [Weight-Average Molecular Weight (Mw) and Number-Average Molecular Weight (Mn)]

The Mw and Mn of a polymer were measured under the conditions described above. A degree of dispersion (Mw/Mn) was calculated from results of the measured Mw and Mn.

### [¹³C-NMR Analysis]

¹³C-NMR analysis of the polymer was performed using a nuclear magnetic resonance apparatus (“JNM-Delta 400” manufactured by JEOL Ltd.).

### <Synthesis of Polymer>

Monomers used for synthesis of polymers in Examples and Comparative Examples are shown below. In the following synthesis examples, unless otherwise specified, “parts by mass” means a value taken when the total mass of the monomers used is 100 parts by mass, and “mol %” means a value taken when the total number of moles of the monomers used is 100 mol %.

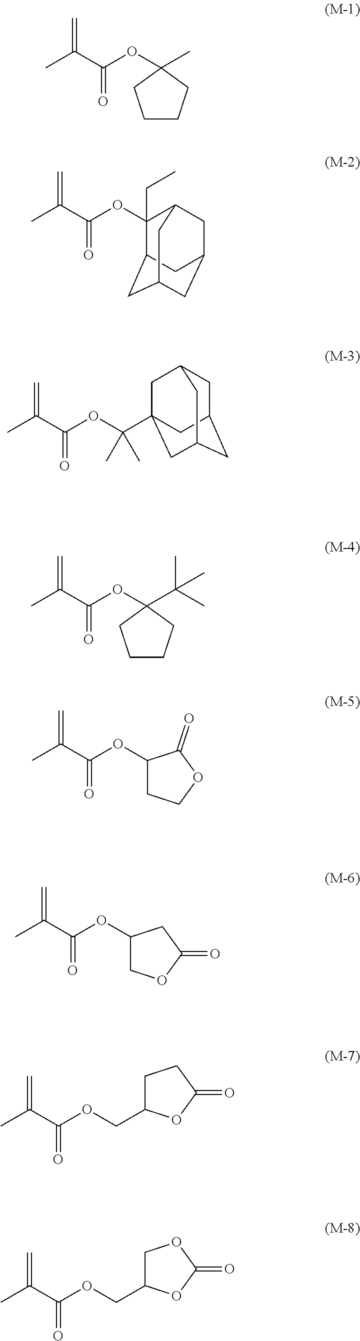

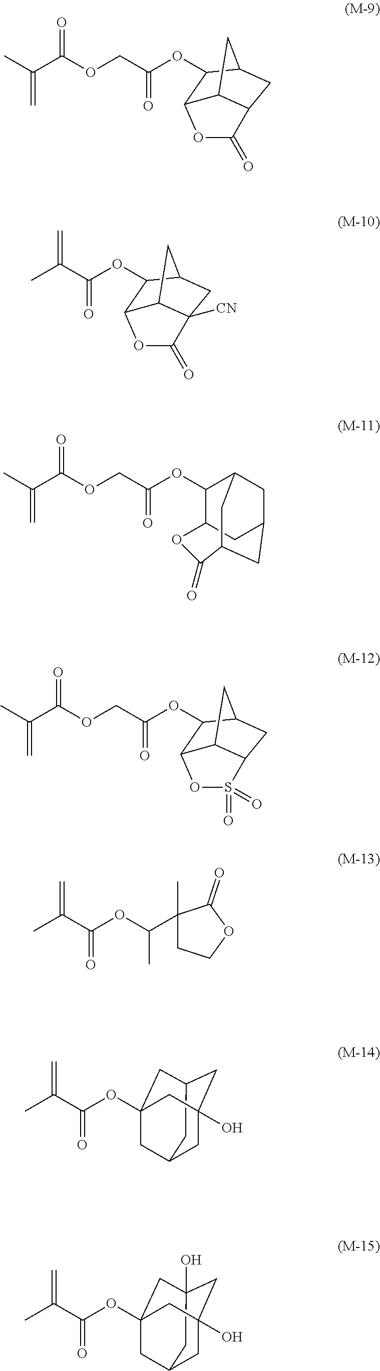

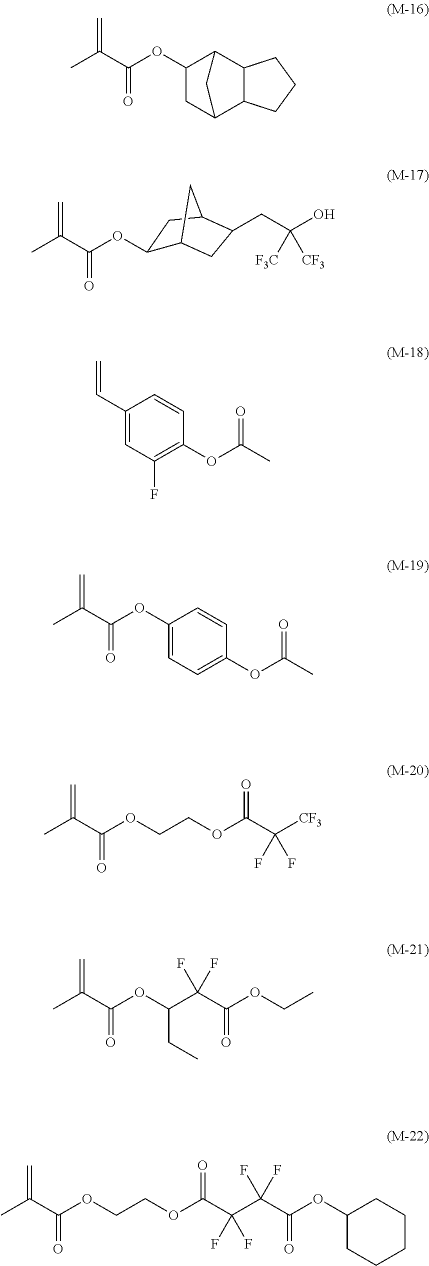

### Synthesis Example 1

### (Synthesis of Polymer (A-1))

A monomer (M-1), a monomer (M-2), a monomer (M-5), a monomer (M-10), and a monomer (M-14) were dissolved at a molar ratio of 40/10/20/20/10 (mol %) in 2-butanone (200 parts by mass), and AIBN (azobisisobutyronitrile) (5 mol % based on 100 mol % in total of the monomers used) was added thereto as an initiator to prepare a monomer solution. 2-butanone (100 parts by mass) was placed in a reaction vessel, and the reaction vessel was purged with nitrogen for 30 minutes. Then, the temperature inside the reaction vessel was adjusted to 80° C., and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30° C. or lower. The polymerization solution cooled was poured into methanol (2,000 parts by mass), and a precipitated white powder was collected by filtration. The white powder separated by filtration was washed with methanol twice, then separated by filtration, and dried at 50° C. for 24 hours to obtain a white powdery polymer (A-1) (yield: 85%). The polymer (A-1) had an Mw of 7,100 and an Mw/Mn of 1.61. As a result of ¹³C-NMR analysis, the contents by percent of the structural units derived from (M-1), (M-2), (M-5), (M-10), and (M-14) were 40.3 mol %, 9.2 mol %, 20.5 mol %, 19.8 mol %, and 10.2 mol %, respectively.

### Synthesis Examples 2 to 11 and 101 to 103

### (Synthesis of Polymers (A-2) to (A-11) and (A-101) to (A-103))

Polymers (A-2) to (A-11) and (A-101) to (A-103) were synthesized in the same manner as in Synthesis Example 1 except that monomers of types and blending ratios shown in the following Table 1 were used. The content by percent (mol %) of each of the structural units and physical property values (Mw and Mw/Mn) of the resulting polymers are also shown in Table 1. In Table 1, “-” indicates that the corresponding monomer was not used (the same applies to Tables below).

TABLE 1

| | | Monomer that gives | | | Monomer that gives | | | Monomer that gives structural | | | | |
|---|---|---|---|---|---|---|---|---|---|---|---|---|
| | | structural unit (I) | | | structural unit (II) | | | unit (III) and the like | | | | |
| | | | | Content | | | Content | | | Content | | |
| | | | | ratio of | | | ratio of | | | ratio of | | |
| | | | Blending | structural | | Blending | structural | | Blending | structural | | |
| Synthesis | Polymer | | ratio | unit | | ratio | unit | | ratio | unit | | |
| Examples | [A] | Type | (mol %) | (mol %) | Type | (mol %) | (mol %) | Type | (mol %) | (mol %) | Mw | Mw/Mn |
| Synthesis | A-1 | M-1 | 40 | 40.3 | M-5 | 20 | 20.5 | M-14 | 10 | 10.2 | 7100 | 1.61 |
| Example 1 | | M-2 | 10 | 9.2 | M-10 | 20 | 19.8 | | | | | |
| Synthesis | A-2 | M-1 | 30 | 30.2 | M-9 | 50 | 50.6 | — | — | — | 7700 | 1.51 |
| Example 2 | | M-2 | 20 | 19.2 | | | | | | | | |
| Synthesis | A-3 | M-1 | 30 | 31.0 | M-11 | 50 | 49.4 | — | — | — | 7200 | 1.59 |
| Example 3 | | M-3 | 20 | 19.6 | | | | | | | | |
| Synthesis | A-4 | M-1 | 40 | 40.5 | M-12 | 50 | 49.2 | — | — | — | 6800 | 1.61 |
| Example 4 | | M-3 | 10 | 10.3 | | | | | | | | |
| Synthesis | A-5 | M-1 | 40 | 40.6 | M-13 | 50 | 51.3 | — | — | — | 6900 | 1.44 |
| Example 5 | | M-4 | 10 | 8.1 | | | | | | | | |
| Synthesis | A-6 | M-1 | 40 | 40.9 | M-6 | 20 | 20.5 | M-16 | 10 | 10.0 | 7500 | 1.51 |
| Example 6 | | M-4 | 10 | 8.3 | M-9 | 20 | 20.3 | | | | | |
| Synthesis | A-7 | M-1 | 50 | 50.2 | M-10 | 30 | 29.6 | M-14 | 20 | 20.2 | 7200 | 1.55 |
| Example 7 | | | | | | | | | | | | |
| Synthesis | A-8 | M-1 | 40 | 40.0 | M-7 | 20 | 20.5 | M-15 | 10 | 9.2 | 7100 | 1.62 |
| Example 8 | | M-3 | 10 | 10.1 | M-11 | 20 | 20.2 | | | | | |
| Synthesis | A-9 | M-1 | 50 | 50.3 | M-8 | 50 | 49.7 | — | — | — | 7000 | 1.51 |
| Example 9 | | | | | | | | | | | | |
| Synthesis | A-10 | M-1 | 40 | 40.2 | M-9 | 60 | 59.8 | — | — | — | 6700 | 1.50 |
| Example 10 | | | | | | | | | | | | |
| Synthesis | A-11 | M-2 | 40 | 39.4 | M-10 | 60 | 60.6 | — | — | — | 7500 | 1.49 |
| Example 11 | | | | | | | | | | | | |
| Synthesis | A-101 | M-4 | 30 | 29.8 | M-5 | 30 | 30.4 | M-15 | 5 | 4.7 | 4900 | 1.43 |
| Example 101 | | M-2 | 10 | 9.8 | M-11 | 25 | 25.3 | | | | | |
| Synthesis | A-102 | M-4 | 50 | 49.9 | M-6 | 20 | 20.5 | M-14 | 5 | 4.6 | 10800 | 1.55 |
| Example 102 | | M-2 | 10 | 9.7 | M-12 | 15 | 15.3 | | | | | |
| Synthesis | A-103 | M-4 | 30 | 30.3 | M-5 | 25 | 24.7 | M-14 | 5 | 4.8 | 13300 | 1.67 |
| Example 103 | | M-3 | 20 | 20.0 | M-12 | 20 | 20.2 | | | | | |

### (Synthesis of Polymer (A-12))

Monomers (M-1) and (M-18) were dissolved at a molar ratio of 50/50 (mol %) in 1-methoxy-2 propanol (200 parts by mass), and AIBN (5 mol %) was added thereto as an initiator to prepare a monomer solution. 1-methoxy-2-propanol (100 parts by mass) was placed in a reaction vessel, and the reaction vessel was purged with nitrogen for 30 minutes. Then, the temperature inside the reaction vessel was adjusted to 80° C., and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30° C. or lower. The cooled polymerization solution was poured into hexane (2,000 parts by mass), and a precipitated white powder was collected by filtration. The white powder separated by filtration was washed with hexane twice, then separated by filtration, and dissolved in 1-methoxy-2-propanol (300 parts by mass). Next, methanol (500 parts by mass), triethylamine (50 parts by mass) and ultrapure water (10 parts by mass) were added, and a hydrolysis reaction was performed at 70° C. for 6 hours with stirring. After the completion of the reaction, the remaining solvent was distilled off. The resulting solid was dissolved in acetone (100 parts by mass), and the solution was added dropwise to water (500 parts by mass) to solidify a polymer. The resulting solid was separated by filtration, and dried at 50° C. for 13 hours to obtain a white powdery polymer (A-12) (yield: 81%). The polymer (A-12) had an Mw of 5,500 and an Mw/Mn of 1.62. As a result of ¹³C-NMR analysis, the contents by percent of the structural units derived from (M-1) and (M-18) were respectively 50.2 mol % and 49.8 mol %.

### Synthesis Examples 13 to 15

### (Synthesis of Polymers (A-13) to (A-15))

Polymers (A-13) to (A-15) were synthesized in the same manner as in Synthesis Example 12 except that monomers of types and blending ratios shown in the following Table 2 were used. For the monomer that gives the structural unit (IV), in the polymer, the disappearance of the peak of the carbonyl group on the acetyl group was confirmed by measurement of ¹³C-NMR, and substantially all the alkali-dissociable groups were hydrolyzed to phenolic hydroxyl groups. The content ratio (mol %) and physical property values (Mw and Mw/Mn) of each of the structural units of the resulting polymers are also shown in the following Table 2.

TABLE 2

| | | Monomer that gives | | | Monomer that gives | | | Monomer that gives | | | | |
|---|---|---|---|---|---|---|---|---|---|---|---|---|
| | | structural unit (I) | | | structural unit (III) | | | structural unit (IV) | | | | |
| | | | | Content | | | Content | | | Content | | |
| | | | | ratio of | | | ratio of | | | ratio of | | |
| | | | Blending | structural | | Blending | structural | | Blending | structural | | |
| Synthesis | Polymer | | ratio | unit | | ratio | unit | | ratio | unit | | |
| Examples | [A] | Type | (mol %) | (mol %) | Type | (mol %) | (mol %) | Type | (mol %) | (mol %) | Mw | Mw/Mn |
| Synthesis | A-12 | M-1 | 50 | 50.2 | — | — | — | M-18 | 50 | 49.8 | 5500 | 1.62 |
| Example 12 | | | | | | | | | | | | |
| Synthesis | A-13 | M-3 | 50 | 46.6 | M-14 | 10 | 11.1 | M-19 | 40 | 42.3 | 5600 | 1.55 |
| Example 13 | | | | | | | | | | | | |
| Synthesis | A-14 | M-2 | 50 | 48.1 | M-17 | 20 | 21.3 | M-18 | 30 | 30.6 | 5100 | 1.59 |
| Example 14 | | | | | | | | | | | | |
| Synthesis | A-15 | M-4 | 55 | 53.2 | M-17 | 15 | 15.2 | M-19 | 30 | 31.6 | 6100 | 1.50 |
| Example 15 | | | | | | | | | | | | |

### Synthesis Example 16

### [Synthesis of High Fluorine-Containing Polymer (F-1)]

Monomers (M-1) and (M-20) were dissolved at a molar ratio of 20/80 (mol %) in 2-butanone (200 parts by mass), and AIBN (4 mol %) was added thereto as an initiator to prepare a monomer solution. 2-butanone (100 parts by mass) was placed in a reaction vessel, and the reaction vessel was purged with nitrogen for 30 minutes. Then, the temperature inside the reaction vessel was adjusted to 80° C., and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30° C. or lower. The solvent was replaced with acetonitrile (400 parts by mass). Hexane (100 parts by mass) was then added, followed by stirring, and an acetonitrile layer was collected. The operation was repeated three times. By replacing the solvent with propylene glycol monomethyl ether acetate, a solution of a high fluorine-containing polymer (F-1) was obtained (yield: 75%). The high fluorine-content polymer (F-1) had an Mw of 6,200 and an Mw/Mn of 1.77. As a result of ¹³C-NMR analysis, the contents by percent of the structural units derived from (M-1) and (M-20) were 19.5 mol % and 80.5 mol %, respectively.

### Synthesis Examples 17 to 20

### (Synthesis of High Fluorine-Containing Polymers (F-2) to (F-5))

High fluorine-containing polymers (F-2) to (F-5) were synthesized in the same manner as in Synthesis Example 16 except that monomers of types and blending ratios shown in Table 3 were used. The content by percent (mol %) of each of the structural units and physical property values (Mw and Mw/Mn) of the resulting high fluorine-containing polymers are also shown in Table 3.

TABLE 3

| | | Monomer that gives | | | Monomer that gives | | | |
|---|---|---|---|---|---|---|---|---|
| | | structural unit (V) or (VI) | | | structural unit (I) | | | |
| | High | | | Content | | | Content | |
| | fluorine- | | | ratio of | | | ratio of | Monomer that |
| | content | | Blending | structural | | Blending | structural | gives structural |
| Synthesis | polymer | | ratio | unit | | ratio | unit | unit (III) |
| Examples | [F] | Type | (mol %) | (mol %) | Type | (mol %) | (mol %) | Type |
| Synthesis | F-1 | M-20 | 80 | 80.5 | M-1 | 20 | 19.5 | — |
| Example 16 | | | | | | | | |
| Synthesis | F-2 | M-21 | 80 | 80.9 | M-4 | 20 | 19.1 | — |
| Example 17 | | | | | | | | |
| Synthesis | F-3 | M-22 | 60 | 62.3 | — | — | — | — |
| Example 18 | | | | | | | | |
| Synthesis | F-4 | M-22 | 60 | 60.2 | M-2 | 20 | 19.4 | M-14 |
| Example 19 | | | | | | | | |
| Synthesis | F-5 | M-20 | 60 | 60.0 | M-3 | 10 | 10.1 | M-17 |
| Example 20 | | | | | | | | |

| | Monomer that gives | | Monomer that gives | | | | |
|---|---|---|---|---|---|---|---|
| | structural unit (III) | | structural unit (VII) | | | | |
| | | Content | | | Content | | |
| | | ratio of | | | ratio of | | |
| | Blending | structural | | Blending | structural | | |
| Synthesis | ratio | unit | | ratio | unit | | |
| Examples | (mol %) | (mol %) | Type | (mol %) | (mol %) | Mw | Mw/Mn |
| Synthesis | — | — | — | — | — | 6200 | 1.77 |
| Example 16 | | | | | | | |
| Synthesis | — | — | — | — | — | 7100 | 1.82 |
| Example 17 | | | | | | | |
| Synthesis | — | — | M-16 | 40 | 37.7 | 6900 | 1.91 |
| Example 18 | | | | | | | |
| Synthesis | 20 | 20.4 | — | — | — | 7300 | 1.88 |
| Example 19 | | | | | | | |
| Synthesis | 30 | 29.9 | — | — | — | 6700 | 1.87 |
| Example 20 | | | | | | | |

### Synthesis of First Onium Salt Compound B

### Synthesis Example 21

### (Synthesis of First Onium Salt Compound (B-1))

A first onium salt compound (B-1) as a radiation-sensitive acid generator was synthesized according to the following synthesis scheme.

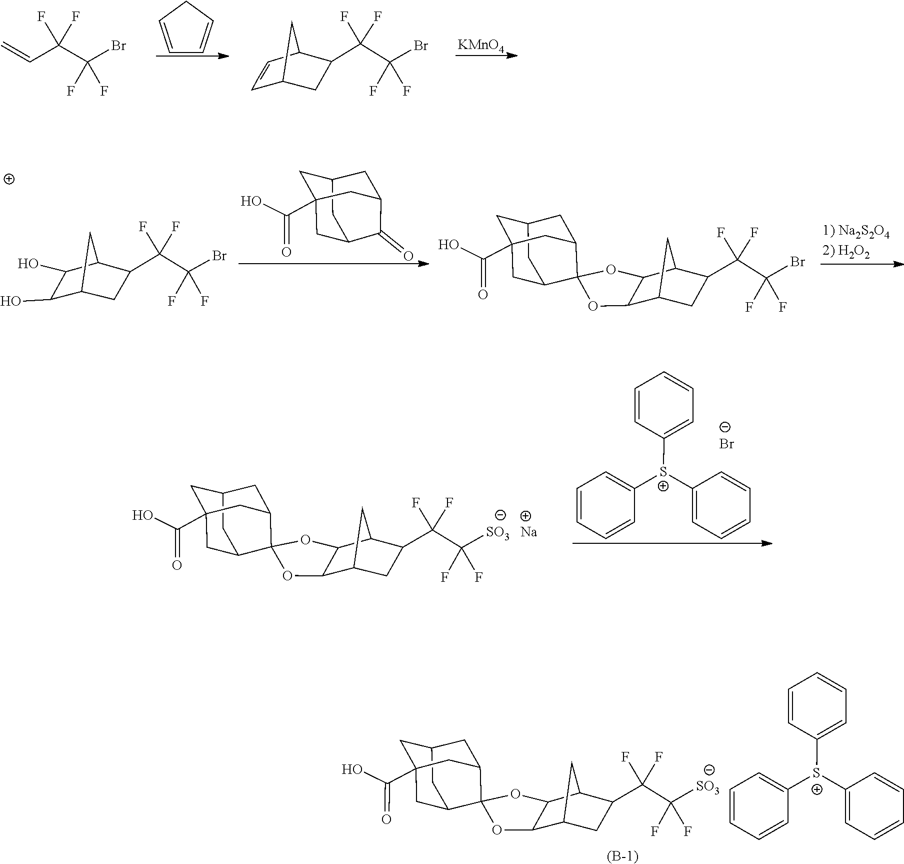

In a reaction vessel, 20.0 mmol of cyclopentadiene and 50 g of dichloromethane were added to 20.0 mmol of 4-bromo-3,3,4,4-tetrafluoro-1-butene, and the mixture was stirred at room temperature for 3 hours. Thereafter, water was added to dilute the mixture, followed by addition of dichloromethane and extraction, and then the organic layer was separated. The resulting organic layer was washed with a saturated aqueous sodium chloride solution and then with water. After drying over sodium sulfate, the solvent was distilled off, and the residue was purified by column chromatography, affording an olefin form in a good yield.

To the olefin form were added 40.0 mmol of potassium permanganate and 50 g of acetonitrile, and the mixture was stirred at 50° C. for 10 hours. Thereafter, a saturated aqueous sodium thiosulfate solution was added to stop the reaction, followed by addition of ethyl acetate and extraction, and then the organic layer was separated. The resulting organic layer was washed with a saturated aqueous sodium chloride solution and then with water. After drying over sodium sulfate, the solvent was distilled off, and the residue was purified by column chromatography, affording a diol form in a good yield.

To the diol form were added 20.0 mmol of 2-adamantanone-5-carboxylic acid, 2.00 mmol of sulfuric acid, and 50 g of dichloromethane, and the mixture stirred at room temperature for 24 hours. Thereafter, water was added to dilute the mixture, followed by addition of ethyl acetate and extraction, and then the organic layer was separated. The resulting organic layer was washed with a saturated aqueous sodium chloride solution and then with water. After drying over sodium sulfate, a solvent was distilled off, and the residue was purified by column chromatography, affording an acetal form in a good yield.

A mixed liquid of acetonitrile and water (1:1 (mass ratio)) was added to the acetal form to form a 1 M solution. Then, 40.0 mmol of sodium dithionite and 60.0 mmol of sodium hydrogen carbonate were added, and the mixture was reacted at 70° C. for 4 hours. After extraction with acetonitrile and distillation of the solvent, a mixed liquid of acetonitrile and water (3:1 (mass ratio)) was added to form a 0.5 M solution. 60.0 mmol of hydrogen peroxide water and 2.00 mmol of sodium tungstate were added, and the mixture was heated and stirred at 50° C. for 12 hours. The mixture was extracted with acetonitrile, and the solvent was distilled off, affording a sodium sulfonate salt compound. 20.0 mmol of triphenylsulfonium bromide was added to the sodium sulfonate salt compound, and a mixed liquid of water and dichloromethane (1:3 (mass ratio)) was added to form a 0.5 M solution. The solution was vigorously stirred at room temperature for 3 hours. Thereafter, dichloromethane was added thereto, followed by extraction, and then the organic layer was separated. The resulting organic layer was dried over sodium sulfate, the solvent was then distilled off, and the residue was purified by column chromatography, affording a first onium salt compound (B-1) represented by the formula (B-1) in a good yield.

### Synthesis Examples 22 to 23

### (Synthesis of First Onium Salt Compounds (B-2) to (B-3))

First onium salt compounds represented by formulas (B-2) to (B-3) below were synthesized in the same manner as in Synthesis Example 21 except that the raw materials and the precursor were appropriately changed.

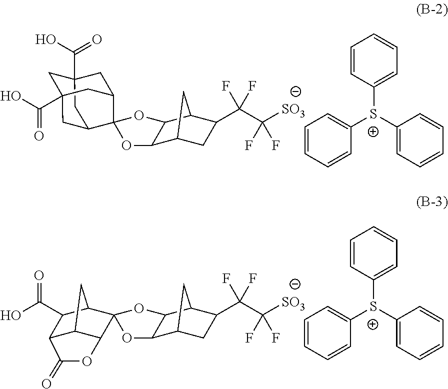

### Synthesis Example 24

### (Synthesis of First Onium Salt Compound (B-4))

A first onium salt compound (B-4) was synthesized in accordance with the synthesis scheme below.

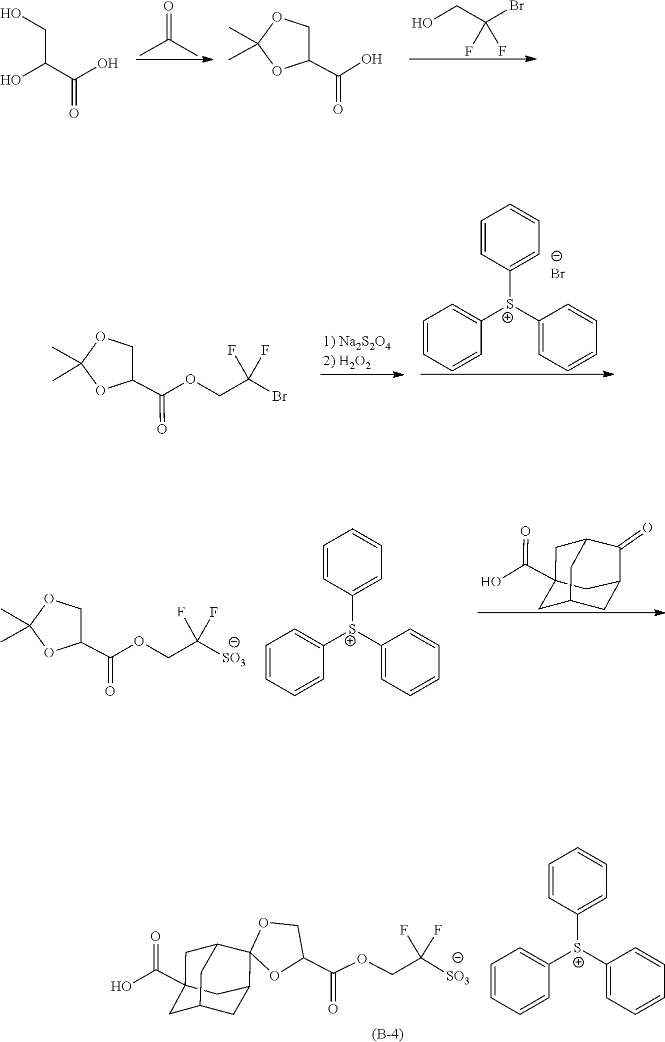

20.0 mmol of glyceric acid, 2.00 mmol of sulfuric acid, and 50 g of acetone were added to a reaction vessel, followed by stirring at room temperature for 2 hours. Thereafter, water was added to dilute the mixture, followed by addition of ethyl acetate and extraction, and then the organic layer was separated. The resulting organic layer was washed with a saturated aqueous sodium chloride solution and then with water. After drying over sodium sulfate, a solvent was distilled off, and purification was performed by column chromatography to obtain an acetal form in good yield.

To the acetal form were added 20.0 mmol of 2-bromo-2,2-difluoroethan-1-ol, 30.0 mmol of dicyclohexylcarbodiimide and 50 g of dichloromethane, and the mixture was stirred at room temperature for 4 hours. Thereafter, water was added to dilute the mixture, followed by addition of dichloromethane and extraction, and then the organic layer was separated. The resulting organic layer was washed with a saturated aqueous sodium chloride solution and then with water. After drying over sodium sulfate, the solvent was distilled off, and the residue was purified by column chromatography, affording an ester form in good yield.

A mixed liquid of acetonitrile and water (1:1 (mass ratio)) was added to the ester form to form a 1 M solution. Then, 40.0 mmol of sodium dithionite and 60.0 mmol of sodium hydrogen carbonate were added, and the mixture was reacted at 70° C. for 4 hours. After extraction with acetonitrile and distillation of the solvent, a mixed liquid of acetonitrile and water (3:1 (mass ratio)) was added to form a 0.5 M solution. 60.0 mmol of hydrogen peroxide water and 2.00 mmol of sodium tungstate were added, and the mixture was heated and stirred at 50° C. for 12 hours. The mixture was extracted with acetonitrile, and the solvent was distilled off, affording a sodium sulfonate salt compound. 20.0 mmol of triphenylsulfonium bromide was added to the sodium sulfonate salt compound, and a mixed liquid of water and dichloromethane (1:3 (mass ratio)) was added to form a 0.5 M solution. The solution was vigorously stirred at room temperature for 3 hours. Thereafter, dichloromethane was added thereto, followed by extraction, and then the organic layer was separated. After drying the resulting organic layer over sodium sulfate, the solvent was distilled off, and purification was performed by column chromatography, affording an onium salt form in good yield.

20.0 mmol of 2-adamantanone-5-carboxylic acid, 2.00 mmol of sulfuric acid and 50 g of dichloroethane were added to the onium salt form, followed by stirring at 70° C. for 20 hours. Thereafter, water was added to dilute the mixture, followed by addition of dichloromethane and extraction, and then the organic layer was separated. The resulting organic layer was washed with a saturated aqueous sodium chloride solution and then with water. After drying over sodium sulfate, a solvent was distilled off, and purification was performed by column chromatography to obtain a first onium salt compound (B-4) represented by the formula (B-4) in a good yield.

### Synthesis Examples 25 to 26

### (Synthesis of First Onium Salt Compounds (B-5) to (B-6))

First onium salt compounds represented by formulas (B-5) to (B-6) below were synthesized in the same manner as in Synthesis Example 25 except that the raw materials and the precursor were appropriately changed.

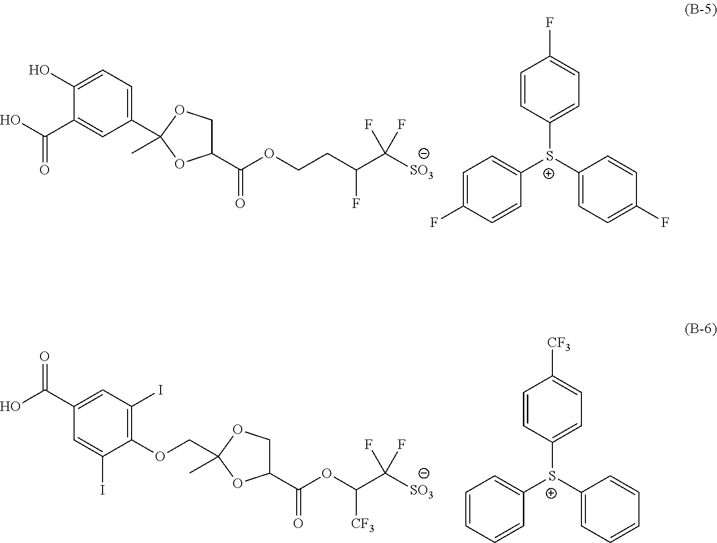

### Synthesis Example 27

### (Synthesis of First Onium Salt Compound (B-7))

A first onium salt compound (B-7) was synthesized in accordance with the synthesis scheme below.

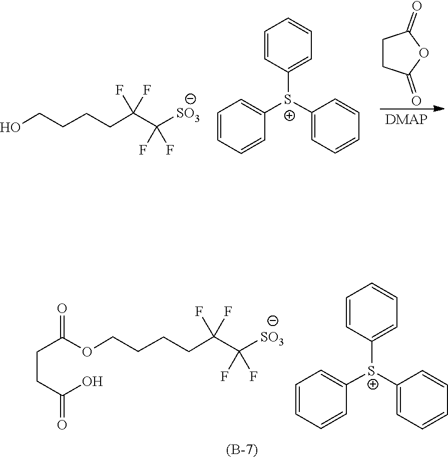

20.0 mmol of triphenylsulfonium 1,1,2,2-tetrafluoro-6-hydroxy-1-hexanesulfonate, 20.0 mmol of succinic anhydride, 5.0 mmol of 4-dimethylaminopyridine and 50 g of dichloromethane were added to a reaction vessel, and the mixture was reacted at room temperature for 12 hours. Thereafter, a 1 M aqueous hydrochloric acid solution was added to stop the reaction, followed by addition of dichloromethane for extraction, and then the organic layer was separated. After drying over sodium sulfate, a solvent was distilled off, and purification was performed by column chromatography to obtain a first onium salt compound (B-7) represented by the formula (B-7) in a good yield.

### Synthesis Examples 28 to 29

### (Synthesis of First Onium Salt Compounds (B-8) to (B-9))

First onium salt compounds represented by formulas (B-8) to (B-9) below were synthesized in the same manner as in Synthesis Example 27 except that the raw materials and the precursor were appropriately changed.

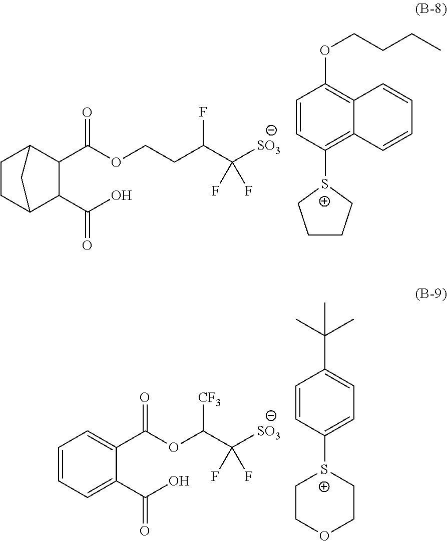

### Synthesis Example 301

### (Synthesis of First Onium Salt Compound (B-10))

A first onium salt compound (B-10) was synthesized in accordance with the synthesis scheme below.

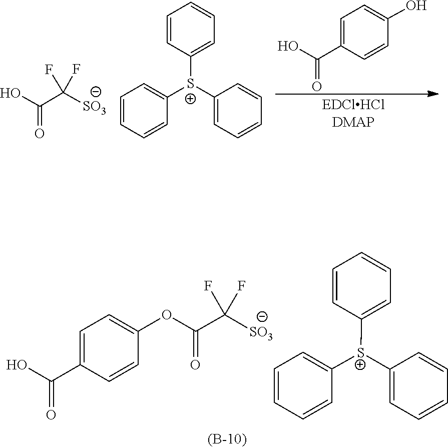

20.0 mmol of triphenylsulfonium 1,1-difluoro-carboxysulfonate, 20.0 mmol of 4-hydroxybenzoic acid, 25.0 mmol of 1-(3-dimethylaminopropyl)-3-ethylcarbodiimide hydrochloride, 5.0 mmol of 4-dimethylaminopyridine and 50 g of dichloromethane were added to a reaction vessel, and the mixture was reacted at room temperature for 12 hours. Thereafter, a 1 M aqueous hydrochloric acid solution was added to stop the reaction, followed by addition of dichloromethane for extraction, and then the organic layer was separated. After drying over sodium sulfate, a solvent was distilled off, and purification was performed by column chromatography to obtain a first onium salt compound (B-10) represented by the formula (B-10) in a good yield.

### Synthesis Examples 31 to 32

### (Synthesis of First Onium Salt Compounds (B-11) to (B-15))

First onium salt compounds represented by formulas (B-11) to (B-15) below were synthesized in the same manner as in Synthesis Example 30 except that the raw materials and the precursor were appropriately changed.

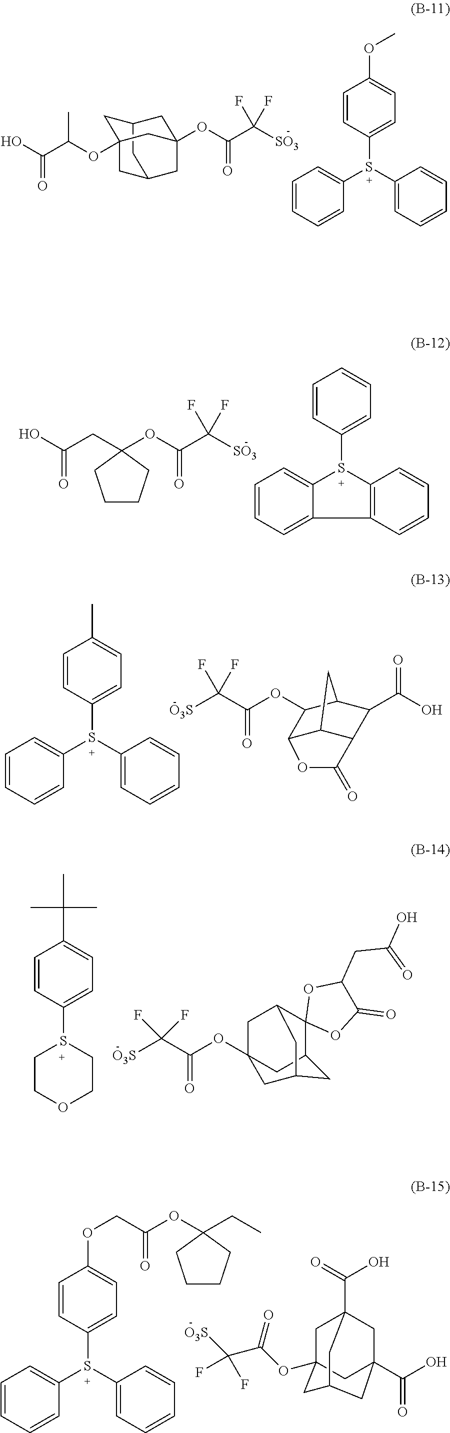

### Synthesis Example 33

### (Synthesis of First Onium Salt Compound (B-16))

A first onium salt compound (B-16) was synthesized in accordance with the synthesis scheme below.

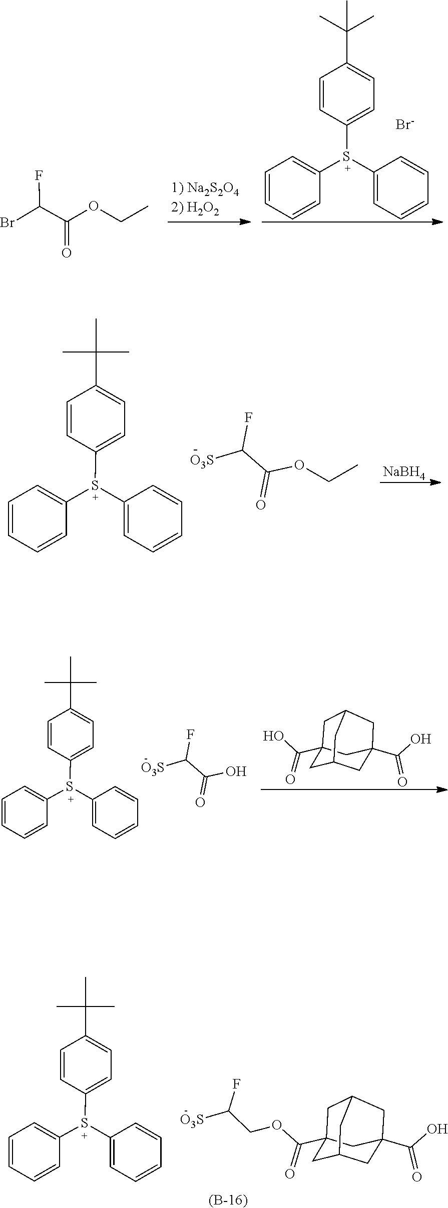

A mixed liquid of acetonitrile and water (1:1 (mass ratio)) was added to a reaction vessel to form a 1 M solution. Then, 40.0 mmol of sodium dithionite and 60.0 mmol of sodium hydrogen carbonate were added, and the mixture was reacted at 70° C. for 4 hours. After extraction with acetonitrile and distillation of the solvent, a mixed liquid of acetonitrile and water (3:1 (mass ratio)) was added to form a 0.5 M solution. 60.0 mmol of hydrogen peroxide water and 2.00 mmol of sodium tungstate were added, and the mixture was heated and stirred at 50° C. for 12 hours. The mixture was extracted with acetonitrile, and the solvent was distilled off, affording a sodium sulfonate salt compound. To the sodium sulfonate salt compound was added 20.0 mmol of (4-(tert-butyl)phenyl)diphenylsulfonium bromide, and a mixed liquid of water and dichloromethane (1:3 (mass ratio)) was added thereto, forming a 0.5 M solution. The mixture was vigorously stirred at room temperature for 3 hours, and then extracted by adding dichloromethane, to separate an organic layer. After drying the resulting organic layer over sodium sulfate, the solvent was distilled off, and purification was performed by column chromatography, affording an onium salt ester form in a good yield.

To the onium salt ester form were added 40.0 mmol of sodium borohydride and 50 g of tetrahydrofuran, followed by stirring at room temperature for 10 hours. Thereafter, 1 M hydrochloric acid was added to stop the reaction, followed by addition of dichloromethane for extraction, and then the organic layer was separated. The resulting organic layer was washed with a saturated aqueous sodium chloride solution and then with water. After drying over sodium sulfate, a solvent was distilled off, and the residue was purified by column chromatography, affording an onium salt alcohol form in a good yield.

1,3-adamantane dicarboxylic acid, 25.0 mmol of 1-(3-dimethylaminopropyl)-3-ethylcarbodiimide hydrochloride, 5.0 mmol of 4-dimethylaminopyridine, and 50 g of dichloromethane were added to the onium salt alcohol form, and the mixture was reacted at room temperature for 12 hours. Thereafter, a 1 M aqueous hydrochloric acid solution was added to stop the reaction, followed by addition of dichloromethane for extraction, and then the organic layer was separated. After drying over sodium sulfate, a solvent was distilled off, and purification was performed by column chromatography to obtain a first onium salt compound (B-16) represented by the formula (B-16) in a good yield.

### Synthesis Examples 34 to 35

### (Synthesis of First Onium Salt Compounds (B-17) to (B-18))

First onium salt compounds represented by formulas (B-17) to (B-18) below were synthesized in the same manner as in Synthesis Example 33 except that the raw materials and the precursor were appropriately changed.

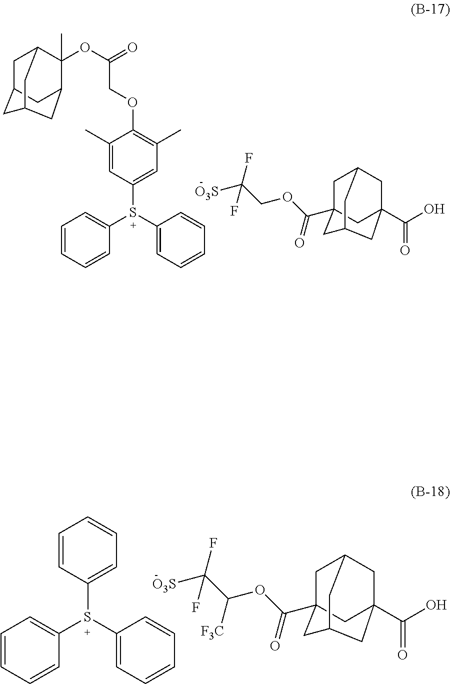

[Radiation-Sensitive Acid Generators Other than First Onium Salt Compounds (B-1) to (B-18)]

b-1 to b-7: Compounds represented by formulas (b-1) to (b-7) below.

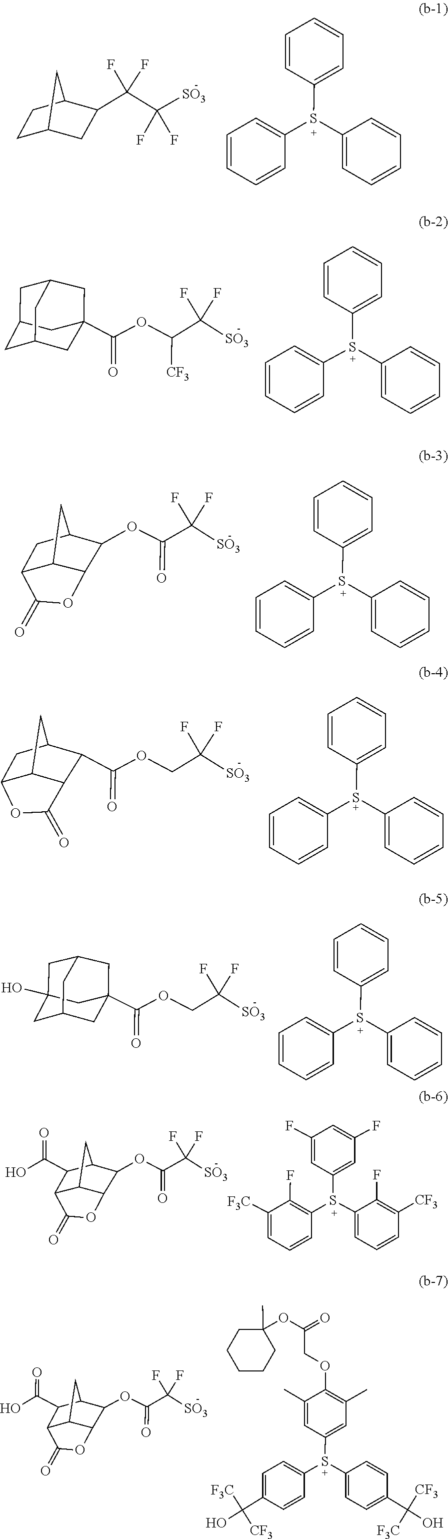

### [[C] Second Onium Salt Compounds as Radiation-Sensitive Acid Generators]

C-1 to C-9: Second onium salt compounds represented by formulas (C-1) to (C-9) below were used as radiation-sensitive acid generators.

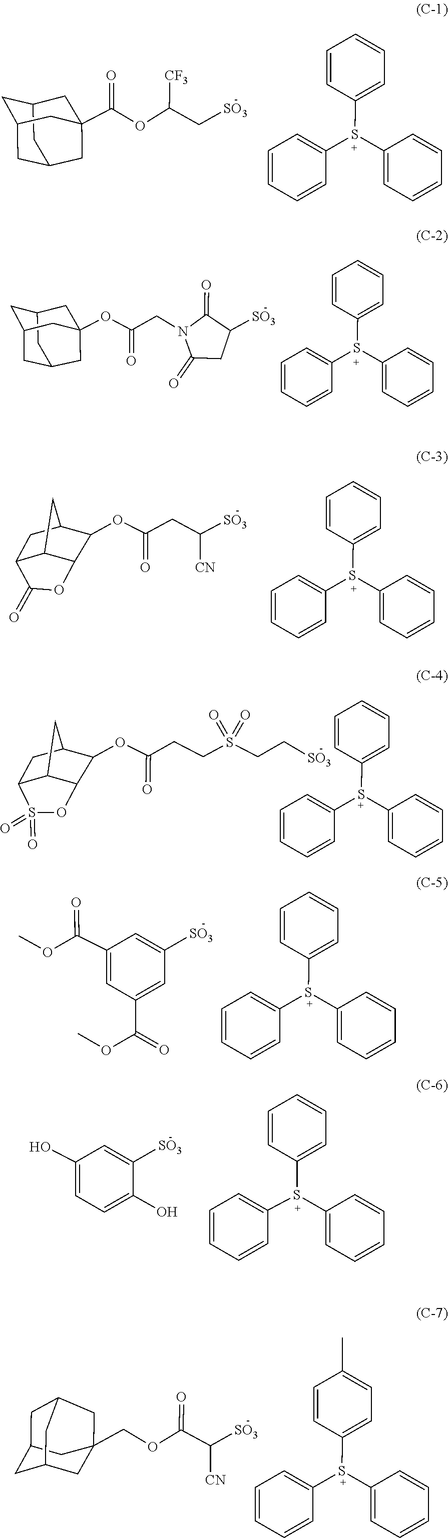

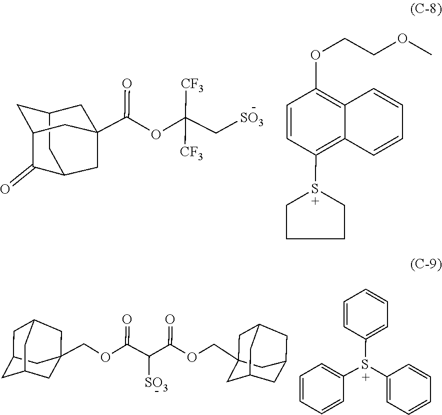

### [[D] Second Onium Salt Compounds as Acid Diffusion Controlling Agents]

D-1 to D-11: Second onium salt compounds represented by formulas (D-1) to (D-11) below were used as the acid diffusion controlling agents.

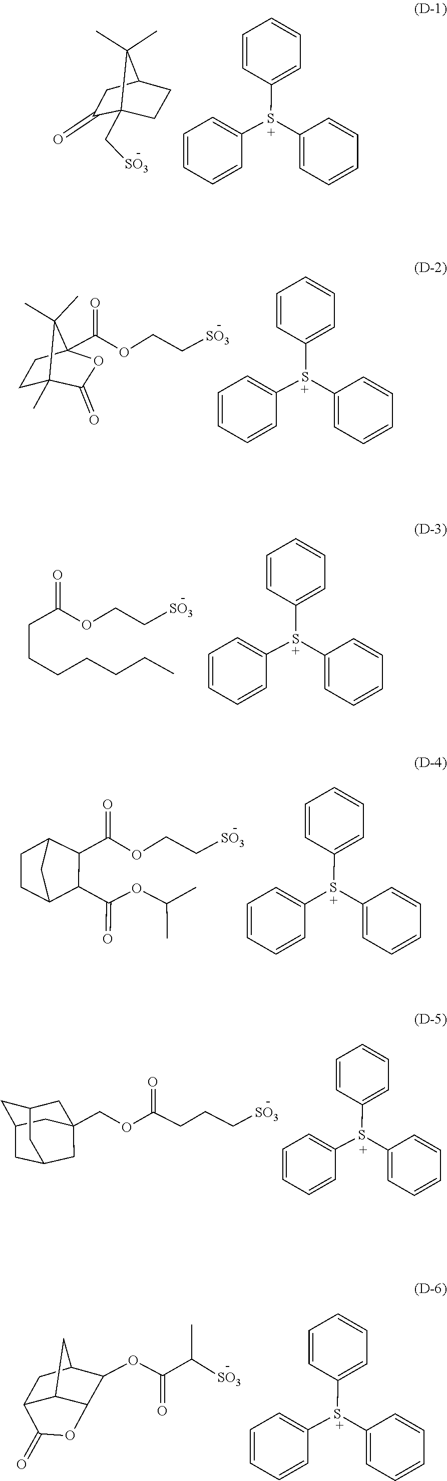

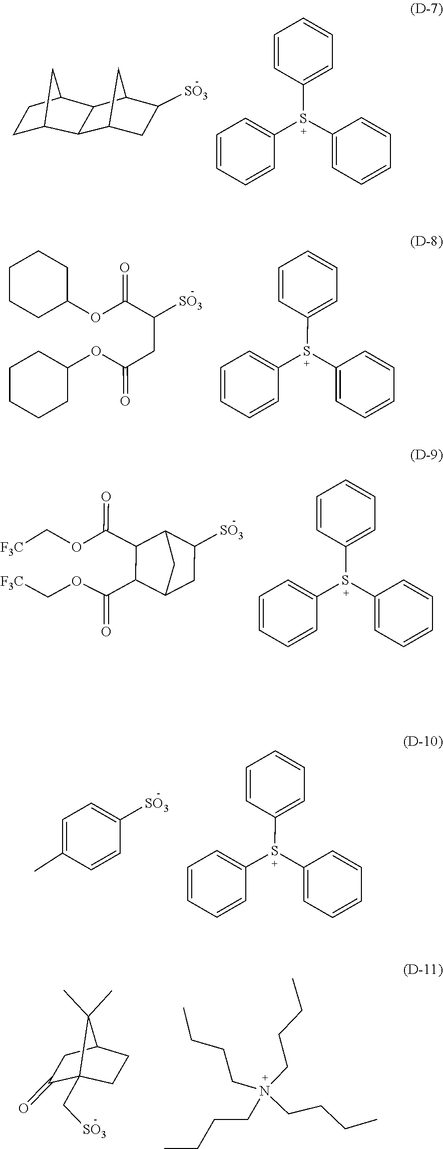

[Acid Diffusion Controlling Agents Other than Second Onium Salt Compounds (D-1) to (D-10)]

d-1 to d-3: Compounds represented by formulas (d-1) to (d-3) below.

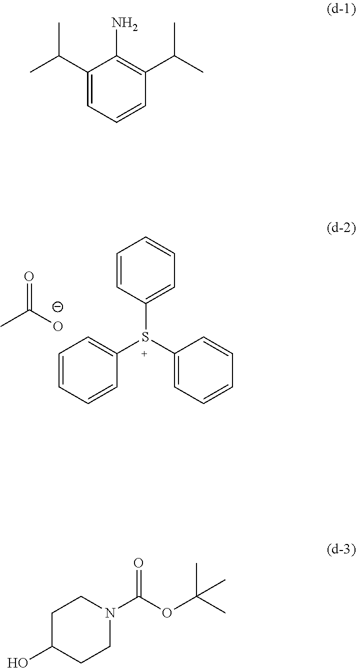

### [[E] Solvent]

E-1: Propylene glycol monomethyl ether acetate
E-2: Cyclohexanone
E-3: γ-Butyrolactone
E-4: Ethyl lactate
E-5: Propylene glycol monomethyl ether
E-6: Methyl 2-hydroxyisobutyrate

### [Preparation of Positive Radiation-Sensitive Composition for ArF Immersion Exposure]

### Example 1

100 parts by mass of (A-1) as the polymer [A], 5.0 parts by mass (solid content) of (F-1) as the high fluorine-content polymer [F], 10.0 parts by mass of (B-1) as the first onium salt compound [B], 4.0 parts by mass of (D-1) as the second onium salt compound [D], and 3,400 parts by mass of a mixed solvent of (E-1)/(E-2)/(E-3) as the solvent [E] were mixed, and the mixture was filtered through a membrane filter having a pore size of 0.2 μm to prepare a radiation-sensitive composition (J-1).

### Examples 2 to 40 and Comparative Examples 1 to 6

Radiation-sensitive compositions (J-2) to (J-40) and (CJ-1) to (CJ-6) were prepared in the same manner as in Example 1 except that the components of the types and the contents shown in Table 4 below were used.

TABLE 4

| | | | | High fluorine- | | First onium salt | |
|---|---|---|---|---|---|---|---|
| | | Polymer [A] | | content polymer [F] | | compound [B] | |
| | Radiation- | | Content | | Content | | Content |
| | sensitive | | (parts by | | (parts by | | (parts by |
| | composition | Type | mass) | Type | mass) | Type | mass) |
| Example 1 | J-1 | A-1 | 100 | F-1 | 5.0 | B-1 | 10.0 |
| Example 2 | J-2 | A-2 | 100 | F-1 | 5.0 | B-1 | 10.0 |
| Example 3 | J-3 | A-3 | 100 | F-1 | 5.0 | B-1 | 10.0 |
| Example 4 | J-4 | A-4 | 100 | F-1 | 5.0 | B-1 | 10.0 |
| Example 5 | J-5 | A-5 | 100 | F-1 | 5.0 | B-1 | 10.0 |
| Example 6 | J-6 | A-6 | 100 | F-1 | 5.0 | B-1 | 10.0 |
| Example 7 | J-7 | A-7 | 100 | F-1 | 5.0 | B-1 | 10.0 |
| Example 8 | J-8 | A-8 | 100 | F-1 | 5.0 | B-1 | 10.0 |
| Example 9 | J-9 | A-9 | 100 | F-1 | 5.0 | B-1 | 10.0 |
| Example 10 | J-10 | A-10 | 100 | F-1 | 5.0 | B-1 | 10.0 |
| Example 11 | J-11 | A-11 | 100 | F-1 | 5.0 | B-1 | 10.0 |
| Example 12 | J-12 | A-1 | 100 | F-2 | 5.0 | B-1 | 10.0 |
| Example 13 | J-13 | A-1 | 100 | F-3 | 5.0 | B-1 | 10.0 |
| Example 14 | J-14 | A-1 | 100 | F-4 | 5.0 | B-1 | 10.0 |
| Example 15 | J-15 | A-1 | 100 | F-1 | 5.0 | B-2 | 10.0 |
| Example 16 | J-16 | A-1 | 100 | F-1 | 5.0 | B-3 | 10.0 |
| Example 17 | J-17 | A-1 | 100 | F-1 | 5.0 | B-4 | 10.0 |
| Example 18 | J-18 | A-1 | 100 | F-1 | 5.0 | B-5 | 10.0 |
| Example 19 | J-19 | A-1 | 100 | F-1 | 5.0 | B-6 | 10.0 |
| Example 20 | J-20 | A-1 | 100 | F-1 | 5.0 | B-7 | 10.0 |
| Example 21 | J-21 | A-1 | 100 | F-1 | 5.0 | B-8 | 10.0 |
| Example 22 | J-22 | A-1 | 100 | F-1 | 5.0 | B-9 | 10.0 |
| Example 23 | J-23 | A-1 | 100 | F-1 | 5.0 | B-10 | 10.0 |
| Example 24 | J-24 | A-1 | 100 | F-1 | 5.0 | B-11 | 10.0 |
| Example 25 | J-25 | A-1 | 100 | F-1 | 5.0 | B-12 | 10.0 |
| Example 26 | J-26 | A-1 | 100 | F-1 | 5.0 | B-1 | 5.0 |
| Example 27 | J-27 | A-1 | 100 | F-1 | 5.0 | B-1 | 5.0 |
| Example 28 | J-28 | A-1 | 100 | F-1 | 5.0 | B-1 | 5.0 |
| Example 29 | J-29 | A-1 | 100 | F-1 | 5.0 | B-1 | 5.0 |
| Example 30 | J-30 | A-1 | 100 | F-1 | 5.0 | B-1 | 5.0 |
| Example 31 | J-31 | A-1 | 100 | F-1 | 5.0 | B-1 | 5.0 |
| Example 32 | J-32 | A-1 | 100 | F-1 | 5.0 | B-1 | 10.0 |
| Example 33 | J-33 | A-1 | 100 | F-1 | 5.0 | B-1 | 10.0 |
| Example 34 | J-34 | A-1 | 100 | F-1 | 5.0 | B-1 | 10.0 |
| Example 35 | J-35 | A-1 | 100 | F-1 | 5.0 | B-1 | 10.0 |
| Example 36 | J-36 | A-1 | 100 | F-1 | 5.0 | B-1 | 10.0 |
| Example 37 | J-37 | A-1 | 100 | F-1 | 5.0 | B-1 | 10.0 |
| Example 38 | J-38 | A-1 | 100 | F-1 | 5.0 | B-1 | 10.0 |
| Example 39 | J-39 | A-1 | 100 | F-1 | 5.0 | B-1 | 10.0 |
| Example 40 | J-40 | A-1 | 100 | F-1 | 5.0 | B-1 | 10.0 |
| Example 101 | J-101 | A-101 | 100 | F-1 | 5.0 | B-1 | 10.0 |
| Example 102 | J-102 | A-102 | 100 | F-1 | 5.0 | B-1 | 10.0 |
| Example 103 | J-103 | A-103 | 100 | F-1 | 5.0 | B-1 | 10.0 |
| Example 104 | J-104 | A-1 | 100 | F-1 | 5.0 | B-13 | 10.0 |
| Example 105 | J-105 | A-1 | 100 | F-1 | 5.0 | B-14 | 10.0 |
| Example 106 | J-106 | A-1 | 100 | F-1 | 5.0 | B-15 | 10.0 |
| Example 107 | J-107 | A-1 | 100 | F-1 | 5.0 | B-16 | 10.0 |
| Example 108 | J-108 | A-1 | 100 | F-1 | 5.0 | B-17 | 10.0 |
| Example 109 | J-109 | A-1 | 100 | F-1 | 5.0 | B-18 | 10.0 |
| Example 110 | J-110 | A-1 | 100 | F-1 | 5.0 | B-1 | 10.0 |
| Example 111 | J-111 | A-1 | 100 | F-1 | 5.0 | B-1 | 10.0 |
| Example 112 | J-112 | A-1 | 100 | F-1 | 5.0 | B-1 | 10.0 |
| Example 113 | J-113 | A-1 | 100 | F-1 | 5.0 | B-1 | 10.0 |
| Example 114 | J-114 | A-1 | 100 | F-1 | 5.0 | B-1 | 10.0 |
| Example 115 | J-115 | A-1 | 100 | F-1 | 5.0 | B-1 | 10.0 |
| Comparative | CJ-1 | A-1 | 100 | F-1 | 5.0 | b-1 | 10.0 |
| Example 1 | | | | | | | |
| Comparative | CJ-2 | A-1 | 100 | F-1 | 5.0 | b-2 | 10.0 |
| Example 2 | | | | | | | |
| Comparative | CJ-3 | A-1 | 100 | F-1 | 5.0 | b-3 | 10.0 |
| Example 3 | | | | | | | |
| Comparative | CJ-4 | A-1 | 100 | F-1 | 5.0 | B-1 | 10.0 |
| Example 4 | | | | | | | |
| Comparative | CJ-5 | A-1 | 100 | F-1 | 5.0 | B-1 | 10.0 |
| Example 5 | | | | | | | |
| Comparative | CJ-6 | A-1 | 100 | F-1 | 5.0 | B-1 | 10.0 |
| Example 6 | | | | | | | |
| Comparative | CJ-11 | A-1 | 100 | F-1 | 5.0 | b-4 | 10.0 |
| Example 11 | | | | | | | |
| Comparative | CJ-12 | A-1 | 100 | F-1 | 5.0 | b-4/B-7 | 5.0/5.0 |
| Example 12 | | | | | | | |
| Comparative | CJ-13 | A-1 | 100 | F-1 | 5.0 | b-5 | 10.0 |
| Example 13 | | | | | | | |
| Comparative | CJ-14 | A-1 | 100 | F-1 | 5.0 | b-6 | 10.0 |
| Example 14 | | | | | | | |
| Comparative | CJ-15 | A-1 | 100 | F-1 | 5.0 | b-7 | 10.0 |
| Example 15 | | | | | | | |

| | Second onium salt | | | | | |
|---|---|---|---|---|---|---|
| | compound [C] | | Second onium salt | | | |
| | (Radiation- | | compound [D] | | | |
| | sensitive | | (Acid diffusion | | | |
| | acid generator) | | controlling agent) | | Solvent [E] | |
| | | Content | | Content | | Content |
| | | (parts by | | (parts by | | (parts by |
| | Type | mass) | Type | mass) | Type | mass) |
| Example 1 | — | — | D-1 | 4.0 | E-1/E-2/E-3 | 2240/960/200 |
| Example 2 | — | — | D-1 | 4.0 | E-1/E-2/E-3 | 2240/960/200 |
| Example 3 | — | — | D-1 | 4.0 | E-1/E-2/E-3 | 2240/960/200 |
| Example 4 | — | — | D-1 | 4.0 | E-1/E-2/E-3 | 2240/960/200 |
| Example 5 | — | — | D-1 | 4.0 | E-1/E-2/E-3 | 2240/960/200 |
| Example 6 | — | — | D-1 | 4.0 | E-1/E-2/E-3 | 2240/960/200 |
| Example 7 | — | — | D-1 | 4.0 | E-1/E-2/E-3 | 2240/960/200 |
| Example 8 | — | — | D-1 | 4.0 | E-1/E-2/E-3 | 2240/960/200 |
| Example 9 | — | — | D-1 | 4.0 | E-1/E-2/E-3 | 2240/960/200 |
| Example 10 | — | — | D-1 | 4.0 | E-1/E-2/E-3 | 2240/960/200 |
| Example 11 | — | — | D-1 | 4.0 | E-1/E-2/E-3 | 2240/960/200 |
| Example 12 | — | — | D-1 | 4.0 | E-1/E-2/E-3 | 2240/960/200 |
| Example 13 | — | — | D-1 | 4.0 | E-1/E-2/E-3 | 2240/960/200 |
| Example 14 | — | — | D-1 | 4.0 | E-1/E-2/E-3 | 2240/960/200 |
| Example 15 | — | — | D-1 | 4.0 | E-1/E-2/E-3 | 2240/960/200 |
| Example 16 | — | — | D-1 | 4.0 | E-1/E-2/E-3 | 2240/960/200 |
| Example 17 | — | — | D-1 | 4.0 | E-1/E-2/E-3 | 2240/960/200 |
| Example 18 | — | — | D-1 | 4.0 | E-1/E-2/E-3 | 2240/960/200 |
| Example 19 | — | — | D-1 | 4.0 | E-1/E-2/E-3 | 2240/960/200 |
| Example 20 | — | — | D-1 | 4.0 | E-1/E-2/E-3 | 2240/960/200 |
| Example 21 | — | — | D-1 | 4.0 | E-1/E-2/E-3 | 2240/960/200 |
| Example 22 | — | — | D-1 | 4.0 | E-1/E-2/E-3 | 2240/960/200 |
| Example 23 | — | — | D-1 | 4.0 | E-1/E-2/E-3 | 2240/960/200 |
| Example 24 | — | — | D-1 | 4.0 | E-1/E-2/E-3 | 2240/960/200 |
| Example 25 | — | — | D-1 | 4.0 | E-1/E-2/E-3 | 2240/960/200 |
| Example 26 | C-1 | 5.0 | D-1 | 4.0 | E-1/E-2/E-3 | 2240/960/200 |
| Example 27 | C-2 | 5.0 | D-1 | 4.0 | E-1/E-2/E-3 | 2240/960/200 |
| Example 28 | C-3 | 5.0 | D-1 | 4.0 | E-1/E-2/E-3 | 2240/960/200 |
| Example 29 | C-4 | 5.0 | D-1 | 4.0 | E-1/E-2/E-3 | 2240/960/200 |
| Example 30 | C-5 | 5.0 | D-1 | 4.0 | E-1/E-2/E-3 | 2240/960/200 |
| Example 31 | C-6 | 5.0 | D-1 | 4.0 | E-1/E-2/E-3 | 2240/960/200 |
| Example 32 | — | — | D-2 | 4.0 | E-1/E-2/E-3 | 2240/960/200 |
| Example 33 | — | — | D-3 | 4.0 | E-1/E-2/E-3 | 2240/960/200 |
| Example 34 | — | — | D-4 | 4.0 | E-1/E-2/E-3 | 2240/960/200 |
| Example 35 | — | — | D-5 | 4.0 | E-1/E-2/E-3 | 2240/960/200 |
| Example 36 | — | — | D-6 | 4.0 | E-1/E-2/E-3 | 2240/960/200 |
| Example 37 | — | — | D-7 | 4.0 | E-1/E-2/E-3 | 2240/960/200 |
| Example 38 | — | — | D-8 | 4.0 | E-1/E-2/E-3 | 2240/960/200 |
| Example 39 | — | — | D-9 | 4.0 | E-1/E-2/E-3 | 2240/960/200 |
| Example 40 | — | — | D-10 | 4.0 | E-1/E-2/E-3 | 2240/960/200 |
| Example 101 | — | — | D-1 | 4.0 | E-1/E-2/E-3 | 2240/960/200 |
| Example 102 | — | — | D-1 | 4.0 | E-1/E-2/E-3 | 2240/960/200 |
| Example 103 | — | — | D-1 | 4.0 | E-1/E-2/E-3 | 2240/960/200 |
| Example 104 | — | — | D-1 | 4.0 | E-1/E-2/E-3 | 2240/960/200 |
| Example 105 | — | — | D-1 | 4.0 | E-1/E-2/E-3 | 2240/960/200 |
| Example 106 | — | — | D-1 | 4.0 | E-1/E-2/E-3 | 2240/960/200 |
| Example 107 | — | — | D-1 | 4.0 | E-1/E-2/E-3 | 2240/960/200 |
| Example 108 | — | — | D-1 | 4.0 | E-1/E-2/E-3 | 2240/960/200 |
| Example 109 | — | — | D-1 | 4.0 | E-1/E-2/E-3 | 2240/960/200 |
| Example 110 | C-7 | 5.0 | D-1 | 4.0 | E-1/E-2/E-3 | 2240/960/200 |
| Example 111 | C-8 | 5.0 | D-1 | 4.0 | E-1/E-2/E-3 | 2240/960/200 |
| Example 112 | C-9 | 5.0 | D-1 | 4.0 | E-1/E-2/E-3 | 2240/960/200 |
| Example 113 | — | — | D-11 | 4.0 | E-1/E-2/E-3 | 2240/960/200 |
| Example 114 | — | — | D-1 | 4.0 | E-1/E-5/E-3 | 2000/1500/30 |
| Example 115 | — | — | D-1 | 4.0 | E-1/E-5/E-6 | 2000/1500/30 |
| Comparative | — | — | D-1 | 4.0 | E-1/E-2/E-3 | 2240/960/200 |
| Example 1 | | | | | | |
| Comparative | — | — | D-1 | 4.0 | E-1/E-2/E-3 | 2240/960/200 |
| Example 2 | | | | | | |
| Comparative | — | — | D-1 | 4.0 | E-1/E-2/E-3 | 2240/960/200 |
| Example 3 | | | | | | |
| Comparative | — | — | d-1 | 4.0 | E-1/E-2/E-3 | 2240/960/200 |
| Example 4 | | | | | | |
| Comparative | — | — | d-2 | 4.0 | E-1/E-2/E-3 | 2240/960/200 |
| Example 5 | | | | | | |
| Comparative | — | — | d-3 | 4.0 | E-1/E-2/E-3 | 2240/960/200 |
| Example 6 | | | | | | |
| Comparative | — | — | D-1 | 4.0 | E-1/E-2/E-3 | 2240/960/200 |
| Example 11 | | | | | | |
| Comparative | — | — | D-1 | 4.0 | E-1/E-2/E-3 | 2240/960/200 |
| Example 12 | | | | | | |
| Comparative | — | — | D-1 | 4.0 | E-1/E-2/E-3 | 2240/960/200 |
| Example 13 | | | | | | |
| Comparative | — | — | D-1 | 4.0 | E-1/E-2/E-3 | 2240/960/200 |
| Example 14 | | | | | | |
| Comparative | — | — | D-1 | 4.0 | E-1/E-2/E-3 | 2240/960/200 |
| Example 15 | | | | | | |

### <Formation of Resist Pattern Using Positive Radiation-Sensitive Composition for ArF Immersion Exposure>

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205° C. for 60 seconds to form an underlayer antireflection film having an average thickness of 100 nm. The positive radiation-sensitive composition for ArF immersion exposure prepared above was applied onto the underlayer antireflection film with use of the spin coater, followed by performing PB (pre-baking) at 100° C. for 60 seconds. Thereafter, cooling was performed at 23° C. for 30 seconds to form a resist film having an average thickness of 90 nm. Next, the resist film was exposed through a 60 nm line-and-space mask pattern using an ArF excimer laser immersion exposure apparatus (“TWINSCAN XT-1900i” manufactured by ASML) with NA of 1.35 under an optical condition of Dipole (σ=0.9/0.7). After the exposure, PEB (post exposure baking) was performed at 100° C. for 60 seconds. Thereafter, the resist film was developed with an alkali with use of a 2.38% by mass aqueous TMAH solution as an alkaline developer, followed by washing with water and further drying to form a positive resist pattern (60 nm line-and-space pattern).

### Evaluation

The resist pattern formed using the positive radiation-sensitive composition for ArF immersion exposure was evaluated on sensitivity, LWR performance, pattern rectangularity, MEEF and EL in accordance with the following methods. The results are shown in the following Table 5. A scanning electron microscope (“CG-5000” manufactured by Hitachi High-Tech Corporation) was used for measuring the length of the resist pattern. The results are shown in the following Table 5.

### [Sensitivity]

An exposure dose at which a 60 nm line-and-space pattern was formed in the aforementioned resist pattern formation using each of the positive radiation-sensitive compositions for ArF immersion exposure was defined as an optimum exposure dose, and this optimum exposure dose was defined as sensitivity (mJ/cm²). The sensitivity was evaluated to be “good” in a case of being 15 mJ/cm² or more and 30 mJ/cm² or less, and “poor” in a case of less than 15 mJ/cm² or exceeding 30 mJ/cm².

### [LWR Performance]

A 60 nm line-and-space resist pattern was formed by irradiation with the optimum exposure dose obtained in the evaluation of the sensitivity. The formed resist pattern was observed from above the pattern with use of the scanning electron microscope. The variation in the line width was measured at a total of 500 points. The 3 sigma value was obtained from the distribution of the measurement values, and defined as LWR performance (nm). The smaller the value of the LWR is, the smaller the roughness of the line is, which is better. The LWR performance was evaluated to be “good” in a case of being 3.0 nm or less, and “poor” in a case of exceeding 3.0 nm.

### [Pattern Rectangularity]

The 60 nm line-and-space resist pattern formed by irradiation with the optimum exposure amount obtained in the evaluation of the sensitivity was observed using the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1.00 or more and 1.05 or less, “B” (good) when the ratio was more than 1.05 and 1.10 or less, and “C” (poor) when the ratio was more than 1.10.

### [MEEF]

In the resist pattern to be resolved by irradiation in the optimum exposure amount, the slope of the straight line when the line width of the resist pattern formed using mask patterns having line widths of 63 nm, 66 nm, 69 nm, 72 nm, and 75 nm was plotted on the vertical axis, and the size of the mask patterns was plotted on the horizontal axis was calculated and used as MEEF. MEEF indicates better mask reproducibility as the value is closer to 1. In a case of being 2 or less, MEEF was evaluated as “good”, and in a case of being more than 2, the MEEF performance was evaluated as “poor”.

### [EL (Exposure Latitude)]

In the range of the exposure dose including the optimum exposure dose, resist patterns were formed by changing the exposure dose every 1 mJ/cm², and the line width of each resist pattern was measured using the scanning electron microscope. From the obtained relationship between the line width and the exposure dose, the exposure dose E(66) at which the line width was 66 nm and the exposure dose E(54) at which the line width was 54 nm were determined, and the exposure latitude (%) was calculated from the equation: exposure latitude (EL)=(E(54)−E(66))×100/(optimum exposure dose). The larger the value of the exposure latitude, the smaller the fluctuation in dimension among the patterns obtained when the exposure dose fluctuates, and the higher the yield at the time of manufacturing a device. When being 10% or more, the EL was evaluated as “good”, and when being less than 10%, the EL was evaluated as “poor”.

TABLE 5

| | Radiation-sensitive | Sensitivity | LWR | Pattern | | EL |
|---|---|---|---|---|---|---|
| | composition | (mJ/cm²) | (nm) | rectangularity | MEEF | (%) |
| Example 1 | J-1 | 20 | 2.0 | A | 1.26 | 16.6 |
| Example 2 | J-2 | 22 | 1.8 | A | 1.42 | 16.1 |
| Example 3 | J-3 | 24 | 2.1 | A | 1.14 | 15.1 |
| Example 4 | J-4 | 23 | 2.2 | A | 1.11 | 13.0 |
| Example 5 | J-5 | 22 | 2.0 | A | 1.53 | 14.3 |
| Example 6 | J-6 | 25 | 2.2 | A | 1.58 | 16.2 |
| Example 7 | J-7 | 21 | 2.5 | A | 1.56 | 14.9 |
| Example 8 | J-8 | 24 | 2.4 | A | 1.45 | 14.6 |
| Example 9 | J-9 | 26 | 2.4 | A | 1.47 | 17.6 |
| Example 10 | J-10 | 23 | 2.3 | A | 1.13 | 13.3 |
| Example 11 | J-11 | 20 | 2.7 | A | 1.39 | 17.1 |
| Example 12 | J-12 | 22 | 2.7 | A | 1.30 | 16.5 |
| Example 13 | J-13 | 21 | 2.1 | A | 1.31 | 15.2 |
| Example 14 | J-14 | 20 | 2.0 | A | 1.39 | 14.8 |
| Example 15 | J-15 | 18 | 1.7 | A | 1.53 | 17.9 |
| Example 16 | J-16 | 19 | 1.9 | A | 1.15 | 14.5 |
| Example 17 | J-17 | 27 | 2.0 | A | 1.57 | 15.4 |
| Example 18 | J-18 | 25 | 2.2 | A | 1.32 | 15.7 |
| Example 19 | J-19 | 26 | 2.1 | A | 1.17 | 14.0 |
| Example 20 | J-20 | 28 | 2.8 | A | 1.87 | 11.3 |
| Example 21 | J-21 | 24 | 2.4 | A | 1.21 | 17.2 |
| Example 22 | J-22 | 25 | 2.3 | A | 1.57 | 14.5 |
| Example 23 | J-23 | 23 | 2.2 | A | 1.31 | 15.9 |
| Example 24 | J-24 | 29 | 2.9 | A | 1.89 | 11.9 |
| Example 25 | J-25 | 29 | 2.8 | A | 1.82 | 12.0 |
| Example 26 | J-26 | 28 | 2.6 | A | 1.24 | 17.2 |
| Example 27 | J-27 | 26 | 2.4 | A | 1.50 | 16.6 |
| Example 28 | J-28 | 24 | 2.8 | A | 1.41 | 13.1 |
| Example 29 | J-29 | 28 | 2.4 | A | 1.27 | 15.7 |
| Example 30 | J-30 | 27 | 2.3 | A | 1.88 | 10.8 |
| Example 31 | J-31 | 25 | 2.5 | A | 1.89 | 11.0 |
| Example 32 | J-32 | 22 | 2.3 | A | 1.43 | 13.8 |
| Example 33 | J-33 | 21 | 1.9 | A | 1.33 | 14.1 |
| Example 34 | J-34 | 22 | 2.8 | A | 1.14 | 13.0 |
| Example 35 | J-35 | 23 | 2.1 | A | 1.27 | 13.9 |
| Example 36 | J-36 | 20 | 2.2 | A | 1.46 | 16.3 |
| Example 37 | J-37 | 24 | 2.0 | A | 1.10 | 17.7 |
| Example 38 | J-38 | 23 | 2.6 | A | 1.31 | 14.9 |
| Example 39 | J-39 | 22 | 2.4 | A | 1.14 | 15.3 |
| Example 40 | J-40 | 18 | 2.8 | A | 1.40 | 14.2 |
| Example 101 | J-101 | 24 | 2.4 | A | 1.54 | 13.8 |
| Example 102 | J-102 | 25 | 2.3 | A | 1.41 | 14.8 |
| Example 103 | J-103 | 23 | 2.7 | A | 1.31 | 14.4 |
| Example 104 | J-104 | 22 | 2.7 | A | 1.19 | 14.4 |
| Example 105 | J-105 | 29 | 2.8 | A | 1.78 | 10.9 |
| Example 106 | J-106 | 28 | 2.9 | A | 1.82 | 11.1 |
| Example 107 | J-107 | 26 | 1.7 | A | 1.25 | 17.2 |
| Example 108 | J-108 | 24 | 2.4 | A | 1.16 | 17.7 |
| Example 109 | J-109 | 26 | 2.0 | A | 1.42 | 14.2 |
| Example 110 | J-110 | 23 | 2.6 | A | 1.45 | 17.6 |
| Example 111 | J-111 | 20 | 2.4 | A | 1.47 | 13.6 |
| Example 112 | J-112 | 22 | 2.8 | A | 1.24 | 14.5 |
| Example 113 | J-113 | 29 | 2.8 | A | 1.77 | 10.7 |
| Example 114 | J-114 | 24 | 2.0 | A | 1.25 | 15.7 |
| Example 115 | J-115 | 23 | 2.6 | A | 1.26 | 15.6 |
| Comparative | CJ-1 | 34 | 3.6 | C | 2.63 | 4.3 |
| Example 1 | | | | | | |
| Comparative | CJ-2 | 35 | 3.4 | C | 2.52 | 3.9 |
| Example 2 | | | | | | |
| Comparative | CJ-3 | 33 | 3.8 | C | 2.48 | 4.9 |
| Example 3 | | | | | | |
| Comparative | CJ-4 | 38 | 3.7 | C | 2.24 | 8.7 |
| Example 4 | | | | | | |
| Comparative | CJ-5 | 36 | 3.6 | C | 2.19 | 7.6 |
| Example 5 | | | | | | |
| Comparative | CJ-6 | 40 | 3.9 | C | 2.20 | 7.4 |
| Example 6 | | | | | | |
| Comparative | CJ-11 | 38 | 4.0 | C | 2.44 | 4.2 |
| Example 11 | | | | | | |
| Comparative | CJ-12 | 32 | 3.3 | C | 2.22 | 8.9 |
| Example 12 | | | | | | |
| Comparative | CJ-13 | 40 | 4.1 | B | 2.48 | 4.8 |
| Example 13 | | | | | | |
| Comparative | CJ-14 | 42 | 3.2 | C | 2.20 | 8.3 |
| Example 14 | | | | | | |
| Comparative | CJ-15 | 39 | 3.3 | B | 2.19 | 8.5 |
| Example 15 | | | | | | |

As is apparent from the results in Table 5, the radiation-sensitive compositions of Examples were good in sensitivity, LWR performance, pattern rectangularity, MEEF, and exposure latitude when used for ArF immersion exposure, whereas the radiation-sensitive compositions of Comparative Examples were inferior in each characteristic to Examples. Therefore, when the radiation-sensitive compositions of Examples are used for ArF immersion exposure, a resist pattern having good LWR performance, pattern rectangularity, MEEF, and exposure latitude with optimum sensitivity can be formed.

### [Preparation of Positive Radiation-Sensitive Composition for ArF-Dry Exposure]

### Example 41

100 parts by mass of (A-1) as the polymer [A], 6.0 parts by mass of (B-1) as the first onium salt compound [B], 3.0 parts by mass of (D-1) as the second onium salt compound [D], and 3,230 parts by mass of a mixed solvent of (E-1)/(E-2)/(E-3) as the solvent [E] were mixed, and the mixture was filtered through a membrane filter having a pore size of 0.2 μm to prepare a radiation-sensitive composition (J-41).

### Examples 42 to 53 and Comparative Examples 7 to 8

Radiation-sensitive compositions (J-42) to (J-53) and (CJ-7) to (CJ-8) were prepared in the same manner as in Example 41 except that the components of the types and contents shown in the following Table 6 were used.

TABLE 6

| | | | | | | Second onium salt | | | | | |
|---|---|---|---|---|---|---|---|---|---|---|---|
| | | | | | | compound [C] | | Second onium salt | | | |
| | | | | | | (Radiation- | | compound [D] | | | |
| | | | | First onium salt | | sensitive | | (Acid diffusion | | | |
| | | Polymer [A] | | compound [B] | | acid generator) | | controlling agent) | | Solvent [E] | |
| | Radiation- | | Content | | Content | | Content | | Content | | Content |
| | sensitive | | (parts by | | (parts by | | (parts by | | (parts by | | (parts by |
| | composition | Type | mass) | Type | mass) | Type | mass) | Type | mass) | Type | mass) |
| Example 41 | J-41 | A-1 | 100 | B-1 | 6.0 | — | — | D-1 | 3.0 | E-1/E-2/E-3 | 2240/960/30 |
| Example 42 | J-42 | A-6 | 100 | B-1 | 6.0 | — | — | D-1 | 3.0 | E-1/E-2/E-3 | 2240/960/30 |
| Example 43 | J-43 | A-7 | 100 | B-1 | 6.0 | — | — | D-1 | 3.0 | E-1/E-2/E-3 | 2240/960/30 |
| Example 44 | J-44 | A-8 | 100 | B-1 | 6.0 | — | — | D-1 | 3.0 | E-1/E-2/E-3 | 2240/960/30 |
| Example 45 | J-45 | A-1 | 100 | B-4 | 6.0 | — | — | D-1 | 3.0 | E-1/E-2/E-3 | 2240/960/30 |
| Example 46 | J-46 | A-1 | 100 | B-7 | 6.0 | — | — | D-1 | 3.0 | E-1/E-2/E-3 | 2240/960/30 |
| Example 47 | J-47 | A-1 | 100 | B-10 | 6.0 | — | — | D-1 | 3.0 | E-1/E-2/E-3 | 2240/960/30 |
| Example 48 | J-48 | A-1 | 100 | B-1 | 3.0 | C-1 | 3.0 | D-1 | 3.0 | E-1/E-2/E-3 | 2240/960/30 |
| Example 49 | J-49 | A-1 | 100 | B-1 | 3.0 | C-2 | 3.0 | D-1 | 3.0 | E-1/E-2/E-3 | 2240/960/30 |
| Example 50 | J-50 | A-1 | 100 | B-1 | 3.0 | C-3 | 3.0 | D-1 | 3.0 | E-1/E-2/E-3 | 2240/960/30 |
| Example 51 | J-51 | A-1 | 100 | B-1 | 6.0 | — | — | D-5 | 3.0 | E-1/E-2/E-3 | 2240/960/30 |
| Example 52 | J-52 | A-1 | 100 | B-1 | 6.0 | — | — | D-8 | 3.0 | E-1/E-2/E-3 | 2240/960/30 |
| Example 53 | J-53 | A-1 | 100 | B-1 | 6.0 | — | — | D-10 | 3.0 | E-1/E-2/E-3 | 2240/960/30 |
| Comparative | CJ-7 | A-1 | 100 | b-1 | 6.0 | — | — | D-1 | 3.0 | E-1/E-2/E-3 | 2240/960/30 |
| Example 7 | | | | | | | | | | | |
| Comparative | CJ-8 | A-1 | 100 | B-1 | 6.0 | — | — | d-1 | 3.0 | E-1/E-2/E-3 | 2240/960/30 |
| Example 8 | | | | | | | | | | | |

### <Formation of Resist Pattern Using Positive Radiation-Sensitive Composition for ArF-Dry Exposure>

Onto the surface of an 8-inch silicon wafer, an underlayer antireflection film forming composition (“ARC29” manufactured by Brewer Science Incorporated.) was applied with use of a spin coater (“CLEAN TRACK ACT8” manufactured by Tokyo Electron Limited.). The wafer was then heated at 205° C. for 60 seconds to form an underlayer antireflection film having an average thickness of 77 nm. The positive radiation-sensitive composition for ArF-Dry exposure prepared above was applied onto the underlayer antireflection film with use of the spin coater, followed by performing PB (pre-baking) at 100° C. for 60 seconds. Thereafter, cooling was performed at 23° C. for 30 seconds to form a resist film having an average thickness of 250 nm. Next, a resist pattern having a line-and-space of 90 nm in line width was formed on this resist film using an ArF excimer laser exposure apparatus (“S306C” manufactured by Nikon Corporation) at NA=0.75 under an optical condition of Annular (σ=0.8/0.6). After the exposure, PEB (post exposure baking) was performed at 100° C. for 60 seconds. Thereafter, the resist film was developed with an alkali with use of a 2.38% by mass aqueous TMAH solution as an alkaline developer, followed by washing with water and further drying to form a positive resist pattern (90 nm line-and-space resist pattern).

### Evaluation

The resist pattern formed using the positive radiation-sensitive composition for ArF-Dry exposure was evaluated on sensitivity, LWR performance, and pattern rectangularity in accordance with the following methods. The results are shown in the following Table 7. A scanning electron microscope (“S-9380” manufactured by Hitachi High-Tech Corporation) was used for measuring the length of the resist pattern.

### [Sensitivity]

An exposure dose at which a 90 nm line-and-space pattern was formed in the aforementioned resist pattern formation using each of the positive radiation-sensitive compositions for ArF-Dry exposure was defined as an optimum exposure dose, and this optimum exposure dose was defined as sensitivity (mJ/cm²). In a case of being 15 mJ/cm² or more and 30 mJ/cm² or less, the sensitivity was evaluated as “good”, and in a case of being less than 15 mJ/cm² or more than 30 mJ/cm², the sensitivity was evaluated as “poor”.

### [LWR Performance]

A 90 nm line-and-space resist pattern was formed by irradiation with the optimum exposure dose obtained in the evaluation of the sensitivity. The formed resist pattern was observed from above the pattern with use of the scanning electron microscope. The variation in line width was measured at 500 points in total, the value of 3σ was obtained from the distribution of the measured values, and the value of 3σ was defined as LWR (nm). A smaller value of LWR indicates smaller roughness of the line and better performance. The LWR performance was evaluated as “good” when the LWR was 4.0 nm or less, and was evaluated as “poor” when the LWR exceeded 4.0 nm.

### [Pattern Rectangularity]

The 90 nm line-and-space resist pattern formed by irradiation with the optimum exposure amount determined in the evaluation of the sensitivity was observed using the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1.00 or more and 1.05 or less, “B” (good) when the ratio was more than 1.05 and 1.10 or less, and “C” (poor) when the ratio was more than 1.10.

TABLE 7

| | Radiation- | Sensi- | | Pattern |
|---|---|---|---|---|
| | sensitive | tivity | LWR | rectan- |
| | composition | (mJ/cm²) | (nm) | gularity |
| Example 41 | J-41 | 18 | 3.0 | A |
| Example 42 | J-42 | 20 | 3.2 | A |
| Example 43 | J-43 | 23 | 2.8 | A |
| Example 44 | J-44 | 21 | 3.1 | A |
| Example 45 | J-45 | 26 | 3.2 | A |
| Example 46 | J-46 | 19 | 3.7 | A |
| Example 47 | J-47 | 21 | 3.1 | A |
| Example 48 | J-48 | 27 | 3.3 | A |
| Example 49 | J-49 | 28 | 3.6 | A |
| Example 50 | J-50 | 24 | 3.4 | A |
| Example 51 | J-51 | 22 | 3.6 | A |
| Example 52 | J-52 | 19 | 3.5 | A |
| Example 53 | J-53 | 17 | 3.8 | A |
| Comparative | CJ-7 | 34 | 4.6 | C |
| Example 7 | | | | |
| Comparative | CJ-8 | 38 | 4.4 | C |
| Example 8 | | | | |

As is apparent from the results in Table 7, the radiation-sensitive compositions of Examples were good in sensitivity, LWR performance, and pattern rectangularity when used for ArF-Dry exposure, whereas the radiation-sensitive compositions of Comparative Examples were inferior in each characteristic to Examples. Therefore, when the radiation-sensitive compositions of Examples are used for ArF-Dry exposure, a resist pattern having good LWR performance and pattern rectangularity with optimum sensitivity can be formed.

### [Preparation of Positive Radiation-Sensitive Composition for Extreme Ultraviolet (EUV) Exposure]

### Example 54

100 parts by mass of (A-12) as the polymer [A], 3.0 parts by mass (solid content) of (F-5) as the high fluorine-content polymer [F], 20.0 parts by mass of (B-1) as the first onium salt compound [B], 10.0 parts by mass of (D-1) as the second onium salt compound [D], and 6,110 parts by mass of a mixed solvent of (E-1)/(E-4) as the solvent [E] were mixed, and the mixture was filtered through a membrane filter having a pore size of 0.2 μm to prepare a radiation-sensitive composition (J-54).

### Examples 55 to 66 and Comparative Examples 9 to 10

Radiation-sensitive compositions (J-55) to (J-66) and (CJ-9) to (CJ-10) were prepared in the same manner as in Example 54 except that the components of the types and contents shown in the following Table 8 were used.

TABLE 8

| | | | | | | | | Second onium | | | | | |
|---|---|---|---|---|---|---|---|---|---|---|---|---|---|
| | | | | | | | | salt compound [C] | | Second onium | | | |
| | | | | | | | | (Radiation- | | salt compound [D] | | | |
| | | | | High fluorine- | | First onium salt | | sensitive | | (Acid diffusion | | | |
| | Radiation- | Polymer [A] | | content polymer [F] | | compound [B] | | acid generator) | | controlling agent) | | Solvent [E] | |
| | sensitive | | Content | | Content | | Content | | Content | | Content | | Content |
| | compo- | | (parts by | | (parts by | | (parts by | | (parts by | | (parts by | | (parts by |
| | sition | Type | mass) | Type | mass) | Type | mass) | Type | mass) | Type | mass) | Type | mass) |
| Example 54 | J-54 | A-12 | 100 | F-5 | 3.0 | B-1 | 20.0 | — | — | D-1 | 10.0 | E-1/E-4 | 4280/1830 |
| Example 55 | J-55 | A-13 | 100 | F-5 | 3.0 | B-1 | 20.0 | — | — | D-1 | 10.0 | E-1/E-4 | 4280/1830 |
| Example 56 | J-56 | A-14 | 100 | F-5 | 3.0 | B-1 | 20.0 | — | — | D-1 | 10.0 | E-1/E-4 | 4280/1830 |
| Example 57 | J-57 | A-15 | 100 | F-5 | 3.0 | B-1 | 20.0 | — | — | D-1 | 10.0 | E-1/E-4 | 4280/1830 |
| Example 58 | J-58 | A-12 | 100 | F-5 | 3.0 | B-4 | 20.0 | — | — | D-1 | 10.0 | E-1/E-4 | 4280/1830 |
| Example 59 | J-59 | A-12 | 100 | F-5 | 3.0 | B-7 | 20.0 | — | — | D-1 | 10.0 | E-1/E-4 | 4280/1830 |
| Example 60 | J-60 | A-12 | 100 | F-5 | 3.0 | B-10 | 20.0 | — | — | D-1 | 10.0 | E-1/E-4 | 4280/1830 |
| Example 61 | J-61 | A-12 | 100 | F-5 | 3.0 | B-1 | 10.0 | C-1 | 10.0 | D-1 | 10.0 | E-1/E-4 | 4280/1830 |
| Example 62 | J-62 | A-12 | 100 | F-5 | 3.0 | B-1 | 10.0 | C-2 | 10.0 | D-1 | 10.0 | E-1/E-4 | 4280/1830 |
| Example 63 | J-63 | A-12 | 100 | F-5 | 3.0 | B-1 | 10.0 | C-3 | 10.0 | D-1 | 10.0 | E-1/E-4 | 4280/1830 |
| Example 64 | J-64 | A-12 | 100 | F-5 | 3.0 | B-1 | 20.0 | — | — | D-5 | 10.0 | E-1/E-4 | 4280/1830 |
| Example 65 | J-65 | A-12 | 100 | F-5 | 3.0 | B-1 | 20.0 | — | — | D-8 | 10.0 | E-1/E-4 | 4280/1830 |
| Example 66 | J-66 | A-12 | 100 | F-5 | 3.0 | B-1 | 20.0 | — | — | D-10 | 10.0 | E-1/E-4 | 4280/1830 |
| Comparative | CJ-9 | A-12 | 100 | F-5 | 3.0 | b-1 | 20.0 | — | — | D-1 | 10.0 | E-1/E-4 | 4280/1830 |
| Example 9 | | | | | | | | | | | | | |
| Comparative | CJ-10 | A-12 | 100 | F-5 | 3.0 | B-1 | 20.0 | — | — | d-1 | 10.0 | E-1/E-4 | 4280/1830 |
| Example 10 | | | | | | | | | | | | | |

### <Formation of Resist Pattern Using Positive Radiation-Sensitive Composition for EUV Exposure>

Onto the surface of a 12-inch silicon wafer, an underlayer antireflection film forming composition (“ARC66” manufactured by Brewer Science Incorporated.) was applied with use of a spin coater (“CLEAN4 TRACK ACT12” manufactured by Tokyo Electron Limited.). The wafer was then heated at 205° C. for 60 seconds to form an underlayer antireflection film having an average thickness of 105 nm. The positive radiation-sensitive composition for EUV exposure prepared above was applied onto the underlayer antireflection film with use of the spin coater, followed by performing PB at 130° C. for 60 seconds. Thereafter, cooling was performed at 23° C. for 30 seconds to form a resist film having an average thickness of 55 nm. Next, the resist film was exposed by an EUV exposure apparatus (“NXE3300”, manufactured by ASML) with NA of 0.33 under a lighting condition of Conventional s=0.89 and with a mask of imecDEFECT32FFR02. After exposing, PEB was performed at 120° C. for 60 seconds. Thereafter, the resist film was developed with an alkali with use of a 2.38% by mass aqueous TMAH solution as an alkaline developer, followed by washing with water and further drying to form a positive resist pattern (25 nm line-and-space pattern).

### Evaluation

The resist pattern formed using the positive radiation-sensitive composition for EUV exposure was evaluated on sensitivity, LWR performance, pattern rectangularity in accordance with the following methods. The results are shown in the following Table 9. A scanning electron microscope (“CG-5000” manufactured by Hitachi High-Tech Corporation) was used for measuring the length of the resist pattern.

### [Sensitivity]

An exposure dose at which a 25 nm line-and-space pattern was formed in the aforementioned resist pattern formation using the positive radiation-sensitive composition for EUV exposure was defined as an optimum exposure dose, and this optimum exposure dose was defined as sensitivity (mJ/cm²). The sensitivity was evaluated to be “good” in a case of being 25 mJ/cm² or more and 40 mJ/cm² or less, and “poor” in a case of less than 25 mJ/cm² or exceeding 40 mJ/cm².

### [LWR Performance]

A resist pattern was formed by adjusting a mask size so as to form a 25 nm line-and-space pattern by irradiation with the optimum exposure dose obtained in the evaluation of the sensitivity. The formed resist pattern was observed from above the pattern with use of the scanning electron microscope. The variation in the line width was measured at a total of 500 points. The 3 sigma value was obtained from the distribution of the measurement values, and defined as LWR (nm). The smaller the value of the LWR is, the smaller the wobble of the line is, which is better. The LWR performance was evaluated to be “good” in a case of being 4.0 nm or less, and “poor” in a case of exceeding 4.0 nm.

### [Pattern Rectangularity]

The 25 nm line-and-space resist pattern formed by irradiation with the optimum exposure dose determined in the evaluation of the sensitivity was observed with use of the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1.00 or more and 1.05 or less, “B” (good) when the ratio was more than 1.05 and 1.10 or less, and “C” (poor) when the ratio was more than 1.10.

TABLE 9

| | Radiation- | Sensi- | | Pattern |
|---|---|---|---|---|
| | sensitive | tivity | LWR | rectan- |
| | composition | (mJ/cm²) | (nm) | gularity |
| Example 54 | J-54 | 27 | 2.9 | A |
| Example 55 | J-55 | 29 | 3.1 | A |
| Example 56 | J-56 | 32 | 2.7 | A |
| Example 57 | J-57 | 30 | 3.0 | A |
| Example 58 | J-58 | 35 | 3.1 | A |
| Example 59 | J-59 | 28 | 3.6 | A |
| Example 60 | J-60 | 30 | 3.0 | A |
| Example 61 | J-61 | 36 | 3.2 | A |
| Example 62 | J-62 | 37 | 3.5 | A |
| Example 63 | J-63 | 33 | 3.3 | A |
| Example 64 | J-64 | 31 | 3.5 | A |
| Example 65 | J-65 | 28 | 3.4 | A |
| Example 66 | J-66 | 26 | 3.7 | A |
| Comparative | CJ-9 | 43 | 4.5 | C |
| Example 9 | | | | |
| Comparative | CJ-10 | 47 | 4.3 | C |
| Example 10 | | | | |

As is apparent from the results in Table 9, the radiation-sensitive compositions of Examples were good in sensitivity, LWR performance, and pattern rectangularity when used for EUV exposure, whereas the radiation-sensitive compositions of Comparative Examples were inferior in the characteristics to those of Examples. Therefore, when the radiation-sensitive compositions of Examples are used for EUV exposure, a resist pattern having good LWR performance and pattern rectangularity with optimum sensitivity can be formed.

[Preparation of Negative Radiation-Sensitive Composition for ArF Exposure, and Formation and Evaluation of Resist Pattern Using this Composition]

### Example 67

100 parts by mass of (A-1) as the polymer [A], 2.0 parts by mass (solid content) of (F-4) as the high fluorine-content polymer [F], 12.0 parts by mass of (B-13) as the first onium salt compound [B], 10.0 parts by mass of (D-1) as the second onium salt compound [D], and 3,230 parts by mass of a mixed solvent of (E-1)/(E-5)/(E-3) (2240/960/30 parts by mass) as the solvent [E] were mixed, and the mixture was filtered through a membrane filter having a pore size of 0.2 μm to prepare a radiation-sensitive composition (J-67).

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205° C. for 60 seconds to form an underlayer antireflection film having an average thickness of 100 nm. The negative radiation-sensitive composition for ArF exposure (J-66) prepared above was applied onto the underlayer antireflection film with use of the spin coater, followed by performing PB (pre-baking) at 100° C. for 60 seconds. Thereafter, cooling was performed at 23° C. for 30 seconds to form a resist film having an average thickness of 90 nm. Next, this resist film was exposed through a mask pattern having a hole of 50 nm and a pitch of 100 nm using an ArF excimer laser immersion exposure apparatus (“TWINSCAN XT-1900i” manufactured by ASML) with NA of 1.35 under an optical condition of Annular (σ=0.8/0.6). After the exposure, PEB (post exposure baking) was performed at 100° C. for 60 seconds. Thereafter, the resist film was developed with an organic solvent using n-butyl acetate as an organic solvent developer, and dried to form a negative resist pattern (contact hole pattern with hole of 50 nm and pitch of 100 nm).

### Examples 116 to 129 and Comparative Examples 16 to 17

Radiation-sensitive compositions (J-116) to (J-129) and (CJ-16) to (CJ-17) were prepared in the same manner as in Example 67 except that the components of the types and contents shown in the following Table 8 were used.

TABLE 10

| | | | | High fluorine- | | First onium salt | |
|---|---|---|---|---|---|---|---|
| | | Polymer [A] | | content polymer [F] | | compound [B] | |
| | Radiation- | | Content | | Content | | Content |
| | sensitive | | (parts by | | (parts by | | (parts by |
| | composition | Type | mass) | Type | mass) | Type | mass) |
| Example 67 | J-67 | A-1 | 100 | F-4 | 2.0 | B-13 | 12.0 |
| Example | J-116 | A-8 | 100 | F-4 | 2.0 | B-13 | 12.0 |
| 116 | | | | | | | |
| Example | J-117 | A-102 | 100 | F-4 | 2.0 | B-13 | 12.0 |
| 117 | | | | | | | |
| Example | J-118 | A-8 | 100 | F-4 | 2.0 | B-1 | 12.0 |
| 118 | | | | | | | |
| Example | J-119 | A-8 | 100 | F-4 | 2.0 | B-8 | 12.0 |
| 119 | | | | | | | |
| Example | J-120 | A-8 | 100 | F-4 | 2.0 | B-9 | 12.0 |
| 120 | | | | | | | |
| Example | J-121 | A-8 | 100 | F-4 | 2.0 | B-17 | 12.0 |
| 121 | | | | | | | |
| Example | J-122 | A-8 | 100 | F-4 | 2.0 | B-18 | 12.0 |
| 122 | | | | | | | |
| Example | J-123 | A-8 | 100 | F-4 | 2.0 | B-13 | 12.0 |
| 123 | | | | | | | |
| Example | J-124 | A-8 | 100 | F-4 | 2.0 | B-13 | 12.0 |
| 124 | | | | | | | |
| Example | J-125 | A-8 | 100 | F-4 | 2.0 | B-13 | 12.0 |
| 125 | | | | | | | |
| Example | J-126 | A-8 | 100 | F-4 | 2.0 | B-13 | 12.0 |
| 126 | | | | | | | |
| Example | J-127 | A-8 | 100 | F-4 | 2.0 | B-13 | 12.0 |
| 127 | | | | | | | |
| Example | J-128 | A-8 | 100 | F-4 | 2.0 | B-13/B-16 | 6.0/6.0 |
| 128 | | | | | | | |
| Example | J-129 | A-8 | 100 | F-4 | 2.0 | B-4/B-18 | 6.0/6.0 |
| 129 | | | | | | | |
| Comparative | CJ-16 | A-8 | 100 | F-4 | 2.0 | B-13 | 10.0 |
| Example 16 | | | | | | | |
| Comparative | CJ-17 | A-8 | 100 | F-4 | 2.0 | b-3 | 10.0 |
| Example 17 | | | | | | | |

| | Second onium | | | | | |
|---|---|---|---|---|---|---|
| | salt compound [C] | | Second onium | | | |
| | (Radiation- | | salt compound [D] | | | |
| | sensitive | | (Acid diffusion | | | |
| | acid generator) | | controlling agent) | | Solvent [E] | |
| | | Content | | Content | | Content |
| | | (parts by | | (parts by | | (parts by |
| | Type | mass) | Type | mass) | Type | mass) |
| Example 67 | — | — | D-1 | 10.0 | E-1/E-5/E-3 | 2240/960/30 |
| Example | — | — | D-1 | 10.0 | E-1/E-5/E-3 | 2240/960/30 |
| 116 | | | | | | |
| Example | — | — | D-1 | 10.0 | E-1/E-5/E-3 | 2240/960/30 |
| 117 | | | | | | |
| Example | — | — | D-1 | 10.0 | E-1/E-5/E-3 | 2240/960/30 |
| 118 | | | | | | |
| Example | — | — | D-1 | 10.0 | E-1/E-5/E-3 | 2240/960/30 |
| 119 | | | | | | |
| Example | — | — | D-1 | 10.0 | E-1/E-5/E-3 | 2240/960/30 |
| 120 | | | | | | |
| Example | — | — | D-1 | 10.0 | E-1/E-5/E-3 | 2240/960/30 |
| 121 | | | | | | |
| Example | — | — | D-1 | 10.0 | E-1/E-5/E-3 | 2240/960/30 |
| 122 | | | | | | |
| Example | C-1 | 2.0 | D-1 | 10.0 | E-1/E-5/E-3 | 2240/960/30 |
| 123 | | | | | | |
| Example | C-2 | 2.0 | D-1 | 10.0 | E-1/E-5/E-3 | 2240/960/30 |
| 124 | | | | | | |
| Example | C-8 | 2.0 | D-1 | 10.0 | E-1/E-5/E-3 | 2240/960/30 |
| 125 | | | | | | |
| Example | — | — | D-2 | 10.0 | E-1/E-5/E-3 | 2240/960/30 |
| 126 | | | | | | |
| Example | — | — | D-9 | 10.0 | E-1/E-5/E-3 | 2240/960/30 |
| 127 | | | | | | |
| Example | — | — | D-1 | 10.0 | E-1/E-5/E-3 | 2240/960/30 |
| 128 | | | | | | |
| Example | — | — | D-1 | 10.0 | E-1/E-5/E-3 | 2240/960/30 |
| 129 | | | | | | |
| Comparative | — | — | d-1 | 4.0 | E-1/E-5/E-3 | 2240/960/30 |
| Example 16 | | | | | | |
| Comparative | — | — | D-1 | 4.0 | E-1/E-5/E-3 | 2240/960/30 |
| Example 17 | | | | | | |

The resist pattern using the negative radiation-sensitive composition for ArF exposure was evaluated on sensitivity in the same manner as in the evaluation of the resist pattern using the positive radiation-sensitive composition for ArF immersion exposure. In addition, CDU performance and pattern circularity were evaluated in accordance with the following methods.

### [Sensitivity]

An exposure dose at which a contact hole pattern with a 50 nm hole and a 100 nm pitch was formed in the resist pattern formation using the negative radiation-sensitive compositions for ArF exposure was defined as an optimum exposure dose, and this optimum exposure dose was defined as sensitivity (mJ/cm²). In a case of being 30 mJ/cm² or more and 45 mJ/cm² or less, the sensitivity was evaluated as “good”, and in a case of being less than 30 mJ/cm² or more than 45 mJ/cm², the sensitivity was evaluated as “poor”.

### [CDU Performance]

Contact holes with a 50 nm hole and a 100 nm pitch were formed by irradiation with an optimum exposure dose determined in the evaluation of sensitivity. The formed resist pattern was observed from above the pattern with use of the scanning electron microscope. The variation of the diameters of the contact holes was measured at 500 points in total. The 3 sigma value was determined from the distribution of the measurement values, and defined as CDU (nm). The smaller the value of the CDU is, the smaller the roughness of the contact holes is, which is better. When the value was less than 3.5 nm, the CDU performance was evaluated to be “good”, and when the value was 3.5 nm or more, the CDU performance was evaluated to be “poor”.

### [Pattern Circularity]

The contact holes with a 50 nm hole and a 100 nm pitch formed by irradiation with the optimum exposure dose determined in the evaluation of sensitivity were observed in plan view using the scanning electron microscope, and the size in the longitudinal direction and the size in the lateral direction were measured. When the ratio of the size in the longitudinal direction to the size in the lateral direction was 0.95 or more and less than 1.05, the pattern circularity was evaluated as “A” (extremely good), when the ratio was 0.90 or more and less than 0.95, or 1.05 or more and less than 1.10, the pattern circularity was evaluated as “B” (good), and when the ratio was less than 0.90, or 1.10 or more, the pattern circularity was evaluated as “C” (poor).

TABLE 11

| | Radiation- | Sensi- | | |
|---|---|---|---|---|
| | sensitive | tivity | CDU | Pattern |
| | composition | (mJ/cm²) | (nm) | circularity |
| Example 67 | J-67 | 39 | 2.9 | A |
| Example 116 | J-116 | 37 | 2.8 | A |
| Example 117 | J-117 | 40 | 2.7 | A |
| Example 118 | J-118 | 35 | 3.0 | A |
| Example 119 | J-119 | 35 | 2.9 | A |
| Example 120 | J-120 | 39 | 3.1 | A |
| Example 121 | J-121 | 36 | 2.6 | A |
| Example 122 | J-122 | 36 | 3.1 | A |
| Example 123 | J-123 | 38 | 2.5 | A |
| Example 124 | J-124 | 34 | 2.8 | A |
| Example 125 | J-125 | 38 | 2.9 | A |
| Example 126 | J-126 | 36 | 3.0 | A |
| Example 127 | J-127 | 40 | 2.6 | A |
| Example 128 | J-128 | 37 | 2.7 | A |
| Example 129 | J-129 | 35 | 2.7 | A |
| Comparative | CJ-16 | 50 | 4.2 | C |
| Example 16 | | | | |
| Comparative | CJ-17 | 51 | 4.3 | C |
| Example 17 | | | | |

As is apparent from the results in Table 11, the radiation-sensitive compositions of Examples were good in sensitivity, CDU performance, and pattern circularity even when a negative resist pattern was formed by ArF exposure, whereas the radiation-sensitive compositions of Comparative Examples were inferior in the characteristics to those of Examples. Therefore, when a negative resist pattern is formed by ArF exposure of the radiation-sensitive compositions of Examples, a resist pattern having good CDU performance and pattern circularity with optimum sensitivity can be formed.

[Preparation of Negative Radiation-Sensitive Composition for EUV Exposure, and Formation and Evaluation of Resist Pattern Using this Composition]

### Example 68

100 parts by mass of (A-15) as the polymer [A], 5.0 parts by mass (solid content) of (F-5) as the high fluorine-content polymer [F], 30.0 parts by mass of (B-1) as the first onium salt compound [B], 10.0 parts by mass of (D-1) as the second onium salt compound [D], and 6,110 parts by mass of a mixed solvent of (E-1)/(E-4) (4280/1830 parts by mass) as the solvent [E] were mixed, and the mixture was filtered through a membrane filter having a pore size of 0.2 μm to prepare a radiation-sensitive composition (J-68).

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205° C. for 60 seconds to form an underlayer antireflection film having an average thickness of 105 nm. The negative radiation-sensitive composition for EUV exposure (J-68) prepared above was applied onto the underlayer antireflection film with use of the spin coater, followed by performing PB at 130° C. for 60 seconds. Thereafter, cooling was performed at 23° C. for 30 seconds to form a resist film having an average thickness of 55 nm. Next, the resist film was exposed by an EUV exposure apparatus (“NXE3300”, manufactured by ASML) with NA of 0.33 under a lighting condition of Conventional s=0.89 and with a mask of imecDEFECT32FFR15. After exposing, PEB was performed at 120° C. for 60 seconds. Thereafter, the resist film was developed with an organic solvent using n-butyl acetate as an organic solvent developer, and dried to form a negative resist pattern (contact hole pattern with hole of 20 nm and pitch of 40 nm).

The resist pattern formed using the negative radiation-sensitive composition for EUV exposure was evaluated in the same manner as the resist pattern formed using the negative radiation-sensitive composition for ArF exposure. As a result, the radiation-sensitive composition of Example 68 had good sensitivity, CDU performance, and pattern circularity even when a negative resist pattern was formed by EUV exposure.

According to the radiation-sensitive composition and the method for forming a resist pattern described above, a resist pattern having good sensitivity to exposure light and being superior in LWR performance, pattern rectangularity, CDU performance, pattern circularity, MEEF, and exposure latitude can be formed. Therefore, these can be suitably used for a machining process and the like of a semiconductor device in which micronization is expected to further progress in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
a first onium salt compound represented by formula (1);
a second onium salt compound represented by formula (2);
a polymer comprising a structural unit which comprises an acid-dissociable group; and
a solvent, 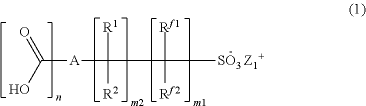
wherein in the formula (1),
A is a (1+n)-valent organic group having 1 to 40 carbon atoms;
R^{f1} and R^{f2} are each independently a hydrogen atom, a monovalent organic group having 1 to 20 carbon atoms, a fluorine atom, or a monovalent fluorinated hydrocarbon group;
when there is a plurality of R^{f1}s and R^{f2}s, the plurality of R^{f1}s and R^{f2}s are the same or different from each other, provided that at least one of R^{f1} and R^{f2} is a fluorine atom or a monovalent fluorinated hydrocarbon group;
R¹ and R² are each independently a hydrogen atom, a fluorine atom or a monovalent organic group having 1 to 20 carbon atoms; when there are a plurality of R¹s and R²s, the plurality of R¹s and R²s are the same or different from each other;
m1 is an integer of 1 to 4;
m2 is an integer of 0 to 4;
n is an integer of 1 to 3; and
Z₁⁺ represents a monovalent radiation-sensitive onium cation, provided that a fluorine atom number in Z₁⁺ is 8 or less; 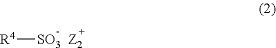
wherein in the formula (2),
R⁴ is a monovalent organic group having 1 to 40 carbon atoms in which neither a fluorine atom nor a fluorinated hydrocarbon group is bonded to an atom adjacent to a sulfur atom in SO₃⁻; and
Z₂⁺ represents a monovalent organic cation.

2. The radiation-sensitive composition according to claim 1, wherein in the formula (1), the group represented by A comprises at least one structure selected from the group consisting of a first cyclic structure, an ester bond, and an ether bond.

3. The radiation-sensitive composition according to claim 2, wherein the first cyclic structure is at least one selected from the group consisting of an alicyclic hydrocarbon structure, an aromatic hydrocarbon structure, a lactone structure, a cyclic acetal structure, and a cyclic ether structure.

4. The radiation-sensitive composition according to claim 1, wherein in the formula (1), n is 1.

5. The radiation-sensitive composition according to claim 1, wherein in the formula (2), R⁴ is a monovalent organic group having 3 to 40 carbon atoms which comprises at least one second cyclic structure and in which neither a fluorine atom nor a fluorinated hydrocarbon group is bonded to an atom adjacent to a sulfur atom in SO₃⁻.

6. The radiation-sensitive composition according to claim 5, wherein in the formula (2), the second cyclic structure and SO₃⁻ are bonded via a divalent linking group, and the divalent linking group is a substituted or unsubstituted divalent chain hydrocarbon group having 1 to 10 carbon atoms, or a group in which a divalent heteroatom-containing linking group is included between carbon atoms of a divalent chain hydrocarbon group having 1 to 10 carbon atoms or at a terminal of the divalent chain hydrocarbon group.

7. The radiation-sensitive composition according to claim 1, wherein the monovalent radiation-sensitive onium cations represented by Z₁⁺ and the monovalent organic cation represented by Z₂⁺ are each independently a sulfonium cation or an iodonium cation.

8. The radiation-sensitive composition according to claim 1, wherein a content of the first onium salt compound in the radiation-sensitive composition is 1 part by mass or more and 40 parts by mass or less based on 100 parts by mass of the polymer.

9. The radiation-sensitive composition according to claim 1, wherein a content of the second onium salt compound in the radiation-sensitive composition is 1 part by mass or more and 30 parts by mass or less based on 100 parts by mass of the polymer.

10. The radiation-sensitive composition according to claim 1, wherein the structural unit which comprises an acid-dissociable group is represented by formula (3), 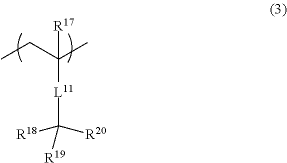
wherein in the formula (3),
R¹⁷ is a hydrogen atom, a fluorine atom, a methyl group, or a trifluoromethyl group;
R¹⁸ is a monovalent hydrocarbon group having 1 to 20 carbon atoms;
R¹⁹ and R²⁰ each independently are a monovalent chain hydrocarbon group having 1 to 10 carbon atoms or a monovalent alicyclic hydrocarbon group having 3 to 20 carbon atoms, or R¹⁹ and R²⁰ taken together are a divalent alicyclic group having 3 to 20 carbon atoms together with a carbon atom to which R¹⁹ and R²⁰ are bonded; L¹¹ represents *—COO—, *-L^{11a}COO—, or *—COOL^{11a}COO—; L^{11a} is a substituted or unsubstituted alkanediyl group or arenediyl group; and * is a bond to a carbon atom bonded to R¹⁷.

11. A method for forming a pattern, comprising:
applying the radiation-sensitive composition according to claim 1 directly or indirectly to a substrate to form a resist film;
exposing the resist film to light; and
developing the exposed resist film with a developer.

12. The method for forming a pattern according to claim 11, wherein exposing comprises exposing the resist film to an ArF excimer laser.
